(19) United States
(12) Patent Application Publication
(10) Pub. No.: US 2025/0341024 A1
(43) Pub. Date: Nov. 6, 2025

(54) Method for Producing at Least One Crack-Free SiC Piece

(71) Applicant: Zadient Technologies SAS, Sainte-Hélène-du Lac (FR)

(72) Inventors: Kagan Ceran, Saint Baldoph (FR); Friedrich Schaaf, Halle (DE)

(21) Appl. No.: 18/866,045

(22) PCT Filed: May 17, 2023
(86) PCT No.: PCT/EP2023/063308

§ 371 Date: Nov. 14, 2024

(30) Foreign Application Priority Data
May 18, 2022 (EP) 22173970.9
Mar. 28, 2023 (WO) PCT/EP2023/057972

(51) Int. Cl. C30B 29/60; C01B 32/963; C30B 28/14; C30B 29/36

(52) U.S. Cl. CPC C30B 29/605; C01B 32/963; C30B 28/14; C30B 29/36

(57) ABSTRACT

A SiC carrier wafer has a diameter of at least 7.5 cm and a height between 200 μm and 500 μm. The wafer includes an inner section and an outer section. The outer section surrounds the inner section and the inner section includes a part of a SiC growth substrate. The inner section is formed by a crystal structure that is predominantly formed by a 3C crystal structure. The outer section is formed by a crystal structure predominantly formed by a 3C crystal structure and includes crystallites extending in length direction of the individual crystallite of more than 5 μm. A bow of the wafer is less than 50 μm and a warp of the wafer is less than 50 μm. The crystal structure of the inner section and the crystal structure of the outer section are Nitrogen doped and have an electric resistivity less than 0.03 Ohm-cm.

### CROSS REFERENCE TO RELATED APPLICATIONS

This application is a § 371 national stage of international application no. PCT/EP2023/063308, filed on May 17, 2023, which claims priority to international application no. PCT/EP2023/057972, filed on Mar. 28, 2023, which claims priority to European application no. 22173970.9, filed on May 18, 2022, the contents of all of which are incorporated by reference herein.

### FIELD OF THE DISCLOSURE

The present invention refers according to claim 1 to a SiC carrier wafer, according claim 12 to a composite substrate, according to claim 13 to a method for producing at least one SiC carrier wafer, according to claim 38 to a method for producing of at least one large SiC piece, according to claim 60 to a method for the production of multiple crack-free workpieces, according to claim 62 to a method for the production of a SiC carrier wafer, according to claim 66 to a method for the production of a composite substrate, according to claim 71 to an electric device, according to claim 72 to a SiC production reactor.

### BACKGROUND

Document WO2022/123078 discloses a beneficial CVD process for the production of PVT source material.

U.S. Pat. Nos. 3,030,189A and 3,011,877A disclose methods for the production of small pieces of SiC. However, none of said documents discloses a method for the production of a SiC carrier wafer being thin and of large size.

The production of carrier wafers made from SiC is expensive. Furthermore, bow and warp of wafers is a critical aspect, since bow and warp increase with the surface size of a wafer due to internal stresses, in particular thin wafer show high bow and warp due to less structural compensation of tensions inside the wafer.

Additionally, due to the disclosed parameters U.S. Pat. Nos. 3,030,189A and 3,011,877A do not describe production of a large ingot which comprises a crack-free section, wherein SiC carrier wafers could be removed from.

Furthermore, U.S. Pat. Nos. 3,030,189A and 3,011,877A disclose SiC growth in a temperature range between 1300° C. and 1400° C., wherein such a temperature range only allows slow growth speed and thereby formation of short crystallites.

Thin and large size SiC carrier wafer are therefore produced by means of epitaxy, which is slow and very expensive.

### SUMMARY

Therefore, it is the object of the present invention to provide cheap and thin SiC carrier wafers of large size having a bow or warp of less than 50 μm.

The before mentioned object is solved by a SiC carrier wafer according to claim 1.

The SiC carrier wafer according to the present invention, in particular crack-free SiC carrier wafer, has a diameter of at least 7.5 cm, wherein the SiC carrier wafer has a height between 200 μm and 500 μm, wherein the SiC carrier wafer comprises at least one or exactly one inner section, in particular one central inner section, and wherein the SiC carrier wafer comprises an outer section, wherein the outer section surrounds the inner section, wherein the inner section consists of a part of a SiC growth substrate, wherein the inner section is formed by a crystal structure, wherein the crystal structure of the inner section is predominantly formed by a 3C crystal structure, and wherein the outer section is formed by a crystal structure, wherein the crystal structure of the outer section is predominantly formed by a 3C crystal structure and comprises crystallites extending in length direction of the individual crystallite more than 5 μm, in particular more than 10 μm and preferably more than 20 μm and particular preferably more than 50 μm and most preferably up to 500 μm or up to 300 μm, wherein a bow of the SiC carrier wafer is below 50 μm, in particular below 20 μm, and/or wherein a warp of the SiC carrier wafer is below 50 μm, in particular below 20 μm, wherein the crystal structure of the inner section and the crystal structure of the outer section, in particular the 3C crystal structure of the inner section and the 3C crystal structure of the outer section, are Nitrogen doped, in particular more than 2000 ppba nitrogen, and comprises an electric resistivity <0.03 Ohm cm, preferably <0.02 Ohm cm and most preferably <0.01 Ohm cm.

This solution is additionally beneficial since due to the presence of crystallites having a length of more than 5 μm, in particular more than 10 μm and preferably more than 20 μm and particular preferably more than 50 μm and most preferably up to 500 μm or up to 300 μm, electric conductivity is enhanced, thus the amount of doping can be smaller to reach the same electric resistivity, in particular <0.03 Ohm cm, preferably <0.02 Ohm cm and most preferably <0.01 Ohm cm. The amount of doping is preferably less than 1019 Nitrogen atoms/cm³, in particular less than 1018 Nitrogen atoms/cm³. Doping is preferably carried out during growth of the second substrate, in particular by adding nitrogen and/or ammonium into a reaction chamber of used CVD reactor. B. Jayant Baliga disclosed in Wide Bandgap Semiconductor Power Devices; Materials, Physics, Design, and Applications; A volume in Woodhead Publishing Series in Electronic and Optical Materials; Book; 2019; ISBN: 978-0-08-102306-8 that the specific electrical resistance can be affected by doping, in particular nitrogen doping.

This solution is beneficial since the substrate is at least partially radially grown, in particular by means of a CVD process. Such a CVD process is e.g., described in: Patent application EP22173970.9, filed 18 May 2022 with the European Patent Office. The subject-matter of EP22173970.9 is entirely incorporated by reference. Thus, the growth starting surface extends in more than two-dimensions respectively surrounds or covers a three-dimensional structure. Growing large SiC ingots by means of a CVD process allows removing a plurality of polycrystalline SiC wafers in a very cost-effective manner. Thus, the radially grown second substrate can be produced much cheaper compared to conventional epitaxy processes. Furthermore, since no homogeneous crystallite orientation is present in a radially grown polycrystalline SiC wafer tensions causing bow and/or warp are compensated by means of the heterogeneous crystallite orientation. Therefore, less post processing steps are required respectively the resulting polycrystalline SiC wafer (second substrate) can be produced even cheaper.

More than 5 crystallites, in particular more than 10 crystallites and highly preferably more than 100 and most preferably more than 500 crystallites or up to 10000 crystallites, which are extending in length direction of the individual crystallite more than 5 μm, in particular more than 10 μm and preferably more than 20 μm and particular preferably more than 50 μm and highly preferably up to 300 μm and most preferably up to 500 μm, are according to a preferred embodiment of the present invention present per 1 mm³ of the outer section. This embodiment is beneficial since a stabilizing effect of the large crystallites increases the more crystallites of large size are present.

The inner section comprises crystallites extending in length direction of the individual crystallite according to a preferred embodiment of the present invention more than 5 μm, in particular more than 10 μm and preferably more than 20 μm and particular preferably more than 50 μm and highly preferably up to 300 μm and most preferably up to 500 μm. More than 50% of all crystallites which are having a length of more than 5 μm extend into width direction (orthogonal to length direction of the individual crystallite) less than 0.8×length extension and preferably less than 0.5χ length extension and highly preferably less than 0.3χ length extension.

This embodiment is beneficial since the compensation of tensions takes place in the inner section and in the outer section. Growth of crystallites having a length of more than 5 μm, in particular more than 10 μm and preferably more than 20 μm and particular preferably more than 50 μm and highly preferably up to 300 μm and most preferably up to 500 μm, require fast material growth respectively a high deposition rate and therefore a deposition surface temperature of the growth face of more than 1400° C.

More than 5 crystallites, in particular more than 10 crystallites and highly preferably more than 100 and most preferably more than 500 crystallites or up to 10000 crystallites, which are extending in length direction of the individual crystallite according to a preferred embodiment of the present invention more than 5 μm, in particular more than 10 μm and preferably more than 20 μm and particular preferably more than 50 μm and highly preferably up to 300 μm and most preferably up to 500 μm, are present per 1 mm³ of the inner section.

This embodiment is beneficial since a stabilizing effect of the large crystallites increases the more crystallites of large size are present.

More than 50% and preferably at least 60% and most preferably at least 70% of all crystallites of the inner section which are extending in length direction of the individual crystallite according to a preferred embodiment of the present invention more than 5 μm, in particular more than 10 μm and preferably more than 20 μm and particular preferably more than 50 μm and highly preferably up to 300 μm and most preferably up to 500 μm, are inclined to a median direction of extension of said crystallites of the inner section in an angle of less than +/−22.5°.

This embodiment is beneficial since the inner section is removed from a part of an ingot which is in a distance to a center line of said ingot. Thus, the ingot is/was of such a size that multiple pieces are removable for removing individual wafers from each of said pieces, wherein the orientation of the crystallites preferably differs from piece to piece. Thus, one ingot provides material for the production of a large number of SiC carrier wafers.

More than 25% and preferably at least 50% and/or most preferably up to 75% of all crystallites of the outer section which are extending in length direction of the individual crystallite according to a preferred embodiment of the present invention more than 5 μm, in particular more than 10 μm and preferably more than 20 μm and particular preferably more than 50 μm and highly preferably up to 300 μm and most preferably up to 500 μm, are inclined to the median direction of extension of the inner section in an angle of more than +/−22.5°.

This embodiment is beneficial since a significant number of crystallites of the outer section is inclined to the median direction of extension of the inner section and thereby causing a beneficial compensation of tensions.

An interface between the outer section and the inner section comprises according to a preferred embodiment of the present invention the same chemical composition compared to the chemical composition of a part inside the outer section between the interface between the outer section and the inner section and a surrounding surface of the outer section and/or the same chemical composition of a part inside the inner section between the interface between the outer section and the inner section and a center of the inner section.

This embodiment is beneficial since no oxid layer is present. Thus, prior to the deposition of SiC on a SiC growth substrate an etching step must be carried out. The surface layer of SiC growth substrates reacts with air and therefore forms an oxid layer. Such an oxid layer needs to be removed in case it is undesired. In view of SiC carrier wafers a homogeneous electric conductivity should be established, thus internal sections having different chemical compositions are undesired. Thus, etching, in particular H-etching or H-plasma-etching is preferably carried out as part of a production method.

The inner section has according to a preferred embodiment of the present invention a cross-sectional area orthogonal to the circumferential direction of at least 0.5 cm² and preferably of at least 2 cm² and most preferably of at least 5 cm² or up to 50 cm².

This embodiment is beneficial since the surface of a SiC growth substrate having a large cross-sectional area is much larger compared to a surface of a SiC growth substrate having a small cross-sectional area. Therefore, the material which can be deposited right from the start is more in case of a SiC growth substrate having a large cross-sectional area compared to a SiC growth substrate having a small cross-sectional area. Furthermore, a SiC growth substrate having a large cross-sectional area is mechanically more stable and therefore requires less care during handling.

The cross-sectional area of the SiC growth substrate has according to a preferred embodiment of the present invention a circular or rectangular shape or the cross-sectional area of the SiC growth substrate has a band-like shape. In case of a band like shape the SiC growth substrate preferably has two large surface sections connected via small surface sections, wherein the surface size of the large surface sections is larger compared to the surface size of the small surface section, in particular more than 5 times larger or more than 50 times larger or up to 1000 times larger.

This embodiment is beneficial since a larger growth face can be provided in case of a “band-like” shape compared to a circular shape.

The SiC carrier wafer comprises according to a preferred embodiment of the present invention a processed surface, wherein the processed surface is generated by mechanically dividing, in particular splitting or sawing, a preferably crack-free SiC piece having a thickness of at least 1 cm.

This embodiment is beneficial since the SiC carrier wafer is removed from a SiC solid, in particular an ingot or boule. Removing multiple SiC carrier wafer from one ingot or boule is much cheaper compared to epitaxial growth of carrier wafer.

The processed surface is according to a preferred embodiment of the present invention a mechanically structured surface, wherein the mechanically structured surface is grinded and/or lapped and/or polished, in particular to reduce surface roughness R_{A} below 5 nm, in particular below 3 nm and most preferably below or equal to 1 nm,

This embodiment is beneficial since a monocrystalline wafer can be bonded thereto.

The before mentioned object is also solved by a composite substrate according to claim 12. The composite substrate according to the present invention comprises at least a SiC carrier wafer according to the present invention, in particular according to any of claim 10 or 11, and a monocrystalline SiC wafer, wherein the monocrystalline SiC wafer is bonded to the processed surface of the carrier wafer.

This solution is beneficial since a cheap and stable composite substrate is provided.

The before mentioned object is also solved by a method for producing at least one SiC carrier wafer, in particular crack-free SiC carrier wafer, according to claim 13. According to the present invention the method comprises at least the steps: Providing a CVD reactor, providing at least one SiC growth substrate inside the CVD reactor, wherein the SiC growth substrate forms a deposition surface surrounding the SiC growth substrate in circumferential direction of the SiC growth substrate, wherein the deposition surface preferably extends in 3D space, growing a SiC solid, in particular to a diameter of at least 7.5 cm or to a cross-sectional area size orthogonal to the length direction of the SiC growth substrate of at least 44.17 cm², by depositing SiC on the deposition surface in the CVD reactor, mechanically removing, in particular by means of sawing, the at least one SiC piece from the SiC solid, and mechanically removing the at least one SiC carrier wafer from the SiC piece, in particular by means of sawing.

This solution is beneficial since a method is provided which is much cheaper in view of large size SiC carrier wafer produced by means of epitaxy.

The step of growing a SiC solid comprises according to a preferred embodiment of the present invention setting up a deposition rate, in particular perpendicular deposition rate, of more than 200 μm/h, in particular of more than 250 μm/h and preferably of more than 300 μm/h and highly preferably of more than 400 μm/h and most preferably of more than 500 μm/h or of up to 2000 μm/h. This embodiment is beneficial since the output can be increased. This is preferably caused by defined heating of the physical structure and defined feeding of feed gases and cooling units at the same time.

A medium supply unit is according to a further preferred embodiment of the present invention configured to feed a one feed-medium or multiple feed-mediums at a pressure of more than 1 bar, in particular of more than 1.2 bar or preferably of more than 1.5 bar or highly preferably of more than 2 bar or 3 bar or 4 bar or 5 bar respectively of up to 10 bar or up to 20 bar, into the process chamber. Additionally, or alternatively the medium supply unit is according to a further preferred embodiment of the present invention configured to feed the one feed-medium or multiple feed-mediums and a carrier gas at a pressure of more than 1 bar, in particular of more than 1.2 bar or 1.5 bar or 2 bar or 3 bar or 4 bar or 5 bar, into the process chamber. This embodiment is beneficial since the material density is high inside the process chamber, thus a high amount of Si and C material reaches the SiC growth surface and therefore causes an enhanced SiC growth.

According to a preferred embodiment of the present invention a step of analyzing the SiC solid to determine a crack-free section of the SiC solid is carried out, wherein the step of analyzing the SiC solid is carried out prior to the step of mechanically removing, in particular by means of sawing, the at least one SiC piece from the SiC solid. This embodiment is beneficial since the crack-free volume of the SiC solid can be identified and utilized for SiC carrier wafer production.

The at least one SiC piece is removed according to a preferred embodiment of the present invention from the crack-free section of the SiC solid or wherein the crack-free section of the SiC solid is removed as the at least one SiC piece.

The step of analyzing the SiC solid to determine a crack-free section of the SiC solid is carried out according to a preferred embodiment of the present invention by optical inspection, in particular by means of a caliper or threshold detection. This embodiment is beneficial since an optical inspection does not damage the SiC solid, furthermore optical inspection methods are well established and provide high quality information.

According to a preferred embodiment of the present invention a step of analyzing the SiC piece or the SiC carrier wafer is carried out to determine defects, in particular cracks. This embodiment is beneficial since further processing of a wafer having defects can be avoided and therefore reduces overall costs.

The step of analyzing the SiC piece or the SiC carrier wafer to determine defects is carried out according to a preferred embodiment of the present invention by means of a bend test, in particular a 2 point bend test, a 3 point bend test or a 4 point bend test, an eddy current testing and/or optical analyzing methods, in particular caliper testing or threshold testing or transmission testings. This embodiment is beneficial since the mentioned detection methods are well established and provide high quality information. Testing methods and systems are described in https://www.isravision.com/en/semiconductor/applications/back-end-of-line/internal-cracks/crack-detection-for-semiconductor-wafers/; https://www.hindawi.com/journals/amse/2013/950791/; https://cjme.springeropen.com/articles/10.1186/s10033-018-0229-2.

According to a preferred embodiment of the present invention a step of heating the SiC growth substrate by conducting electric current from a first power connection to a second power connection or from the second power connection to the first power connection through the SiC growth substrate is carried out. This embodiment is beneficial since the temperature can be adjusted very precisely due to control of electric power supply.

The SiC growth substrate, in particular a growth face of the deposited SiC, is heated according to a preferred embodiment of the present invention to a temperature of more than 1400° C. This embodiment is beneficial since the deposition velocity is higher compared to a temperature range below 1400° C. Due to a high deposition velocity crystallites are growing into the expanding directing of the SiC growth substrate, wherein expanding directing describes the direction the SiC deposits on the SiC growth substrate.

The growth face of the deposited SiC is heated according to a preferred embodiment of the present invention to a temperature of less than 1700° C. and a center of the SiC growth substrate is heated to a temperature above 1400° C. This embodiment is beneficial since due to a large diameter (>7.5 cm) or cross-sectional area (>44.17 cm²) of the SiC solid (inner section plus outer section) the necessary electric power for heating the growth face to a temperature above 1400° C. increases and thereby increases the temperature in the center of the SiC growth substrate. It was found that temperature differences of more than 300K cause tensions inside the SiC solid, wherein said tensions causes cracks inside the SiC solid. Thus, due to the present embodiment cracks can be avoided.

The electric current is according to a preferred embodiment of the present invention provided as alternating current. This embodiment is beneficial, since due to the alternating current the electric power is guided along the outer surface of the growing SiC and therefore heats the center less compared to DC. This is beneficial since the temperature in the center is preferably below the temperature of the outer surface. This is highly beneficial to cause a homogeneous temperature profile between the center and the outer surface, thus the temperature difference between the outer surface and the center is preferably below 300K and more preferably 200K and particular preferably below 100K and most preferably below 50K. This is beneficial to grow the SiC with a low level of tensions to avoid cracking of the SiC.

The frequency of the alternating current is according to a preferred embodiment of the present invention above 5 Hz or preferably above 20 Hz or highly preferably above 50 Hz or most preferably above 500 Hz or up to 5000 Hz, in particular up to 2000 Hz or up to 1000 Hz or up to 500 kHz. Preferably the frequency of the alternating current can be modified during SiC production to better match the needs of a SiC solid having a small growth face and a SiC solid having a large growth face. This embodiment is beneficial since high growth rate and small temperature difference can be established.

The grown SiC solid is according to a further preferred embodiment of the present invention heated for a defined time after growing was finished. The defined time is preferably more than 1 h, in particular for more than 2 h and preferably for more than 3 h and particular preferably for more than 5 h and most preferably for more than 10 h or up to 24 h. The electric energy, in particular alternating current, for heating the SiC solid is preferably reduced continuously and/or in a step wise manner during the defined time, in particular shut off at the end.

The deposited SiC has a minimal thickness of at least 1 cm and wherein the at least one SiC piece is formed between a first plane and a second plane, and wherein the first plane is perpendicular to the main body length and wherein the second plane is perpendicular to the main body length, wherein the distance between the first plane and the second plane is at least 1% and preferably at least 2% and highly preferably at least 5% of the main body length, and wherein the deposited SiC is polycrystalline SiC, wherein the deposited SiC forms volume sections with different crystal structures, wherein a 3C crystal structure is predominantly (mass and/or volume) formed, wherein the volume and/or mass of SiC formed in the 3C crystal structure comprises more than 50% (volume and/or mass) of the deposited SiC, wherein the SiC carrier wafer is crack-free.

The at least one SiC piece has according to a further preferred embodiment of the present invention a cross-sectional size of at least 4 cm² and preferably of at least 8 cm² and highly preferably of at least 12 cm² and a thickness of at least 0, 1 cm and preferably of at least 1 cm and highly preferably of at least 2 cm, and/or wherein the volume (V) of the at least one SiC piece is more than 2 cm³ and preferably more than 4 cm³ and most preferably more than 8 cm³, wherein the at least one SiC piece is crack-free. This embodiment is beneficial since SiC pieces or SiC carrier wafer can be produces in fast and cheap manner.

According to a further preferred embodiment of the present invention the SiC growth substrate comprises a main body, a first power connection and a second power connection, wherein the main body has a main body length, wherein the main body length extends between the first power connection and the second power connection, wherein the first power connection is configured to conduct power into the main body for heating the main body and wherein the second power connection is configured to conduct electric power conducted via the first power connection into the main body out of the main body.

According to a further preferred embodiment of the present invention a step of etching the surface of the SiC growth substrate before the SiC growth substrate is provided inside the CVD reactor is carried out, wherein the step of etching is carried out by hydrofluoric acid etching and/or a step of etching the surface of the SiC growth substrate is carried out after the SiC growth substrate is provided inside the CVD reactor and before the step of growing a SiC solid by depositing SiC on the deposition surface of the SiC growth substrate in the CVD reactor. This embodiment is beneficial since an oxide layer can be removed, which would be present on the surface of the SiC growth substrate and therefore the oxide layer would be present inside a grown SiC solid, since during growth the SiC would deposite onto said oxide layer and therefore would affect the electric properties of the SiC carrier wafer removed from said SiC solid.

The step of etching after the SiC growth substrate is provided inside the CVD reactor is carried out according to a further preferred embodiment of the present invention by gas etching, in particular hydrogen etching, and/or plasma etching, in particular hydrogen-plasma etching. Preferably an etch gas, in particular H, is feed into the reactor chamber, in which the SiC growth substrate is already located. The etch gas can be present inside the reactor chamber for a defined time, in particular up to or more than 5 min or up to or more than 10 min or up to or more than 20 min. However, the etch gas or fractions thereof can be renewed one time or multiple times. It is also possible that a continuous etch gas flow is established into the reaction chamber and out of the reaction chamber. This embodiment is beneficial since hydrogen (H) can be used for etching as well as carrier gas. Thus, the reactor already comprises the necessary features for carrying out the etching step.

The step of growing the SiC solid comprises according to a further preferred embodiment of the present invention the materialization of crystallites having a length of more than 5 μm, in particular more than 10 μm and preferably more than 20 μm and particular preferably more than 50 μm and most preferably up to 500 μm or up to 300 μm. More than 50% of all crystallites which are having a length of more than 5 μm extend into width direction (orthogonal to length direction of the individual crystallite) less than 0.8×length extension and preferably less than 0.5χ length extension and highly preferably less than 0.3χ length extension. This embodiment is beneficial since due to the crystallites which are having a length of more than 5 μm tensions inside a SiC carrier wafer are compensated and thereby causing a bow or warp of preferably less than 50 μm or most preferably less than 20 μm.

According to a further preferred embodiment of the present invention more than 5 crystallites are grown, in particular more than 10 crystallites and highly preferably more than 100 and most preferably more than 500 crystallites or up to 10000 crystallites, per 1 mm³, which are extending in length direction of the individual crystallite more than 5 μm, in particular more than 10 μm and preferably more than 20 μm and particular preferably more than 50 μm and highly preferably up to 300 μm and most preferably up to 500 μm. This embodiment is beneficial since due to a large number of long crystallites tensions inside a SiC carrier wafer are compensated and thereby causing a bow or warp of preferably less than 50 μm or most preferably less than 20 μm.

According to a further preferred embodiment of the present invention the SiC growth substrate comprises crystallites extending in length direction of the individual crystallite more than 5 μm, in particular more than 10 μm and preferably more than 20 μm and particular preferably more than 50 μm and highly preferably up to 300 μm and most preferably up to 500 μm. More than 50% of all crystallites which are having a length of more than 5 μm extend into width direction (orthogonal to length direction of the individual crystallite) less than 0.8×length extension and preferably less than 0.5χ length extension and highly preferably less than 0.3χ length extension. This embodiment is beneficial since long crystallites inside a SiC carrier wafer reduce tensions which would cause bow and warp. Furthermore, due to large crystallites the electric conductivity is enhances and thereby less doping is required compared to SiC having short crystallites.

According to a further preferred embodiment of the present invention more than 5 crystallites, in particular more than 10 crystallites and highly preferably more than 100 and most preferably more than 500 crystallites or up to 10000 crystallites, which are extending in length direction of the individual crystallite more than 5 μm, in particular more than 10 μm and preferably more than 20 μm and particular preferably more than 50 μm and highly preferably up to 300 μm and most preferably up to 500 μm, are present per 1 mm³ of the SiC growth substrate. This embodiment is beneficial since a stabilizing effect of the large crystallites increases the more crystallites of large size are present.

According to a further preferred embodiment of the present invention more than 50% and preferably at least 60% and most preferably at least 70% of all crystallites of the SiC growth substrate which are extending in length direction of the individual crystallite more than 5 μm, in particular more than 10 μm and preferably more than 20 μm and particular preferably more than 50 μm and highly preferably up to 300 μm and most preferably up to 500 μm, are inclined to a median direction of extension of said crystallites of the SiC growth substrate in an angle of less than +/−22.5°. This embodiment is beneficial since the inner section is removed from a part of an ingot which is in a distance to a center line of said ingot. Thus, the ingot is/was of such a size that multiple pieces are removable for removing individual wafers from each of said pieces, wherein the orientation of the crystallites preferably differs from piece to piece. Thus, one ingot provides material for the production of a large number of SiC carrier wafers.

According to a further preferred embodiment of the present invention growing more than 25% and preferably at least 50% and/or most preferably up to 75% of all crystallites which are extending in length direction of the individual crystallite more than 5 μm, in particular more than 10 μm and preferably more than 20 μm and particular preferably more than 50 μm and highly preferably up to 300 μm and most preferably up to 500 μm, inclined to the median direction of extension of the inner section in an angle of more than +/−22.5°. This embodiment is beneficial since a significant number of crystallites of the outer section is inclined to the median direction of extension of the inner section and thereby causing a beneficial compensation of tensions.

According to a further preferred embodiment of the present invention the SiC is deposited until the SiC solid has a minimal thickness of at least 1 cm and wherein the at least one SiC piece is formed between a first plane and a second plane due to the deposition of SiC, and wherein the first plane is perpendicular to the main body length and wherein the second plane is perpendicular to the main body length, wherein the distance between the first plane and the second plane is at least 1% and preferably at least 2% and highly preferably at least 5% of the main body length, and wherein the deposited SiC is polycrystalline SiC, wherein the SiC forms due to deposition volume sections with different crystal structures, wherein a 3C crystal structure is predominantly (mass and/or volume) formed due to deposition of the SiC, wherein the volume and/or mass of SiC formed in the 3C crystal structure due to deposition of SiC comprises more than 50% (volume and/or mass) of the deposited SiC, wherein the SiC carrier wafer is crack-free.

The at least one SiC piece has preferably a cross-sectional size of at least 4 cm² and preferably of at least 8 cm² and highly preferably of at least 12 cm² and a thickness of at least 0.1 cm and preferably of at least 1 cm and highly preferably of at least 2 cm, and/or wherein the volume (V) of the at least one SiC piece is more than 2 cm³ and preferably more than 4 cm³ and most preferably more than 8 cm³, wherein the at least one SiC piece is crack-free

This embodiment is beneficial since SiC pieces or SiC carrier wafer can be produces in fast and cheap manner.

The above-mentioned object is also solved by a method for producing of at least one large SiC piece, in particular an ingot or boule, according to claim 38. The method for producing of at least one large SiC piece according to the present invention preferably comprises at least the steps:

Providing a CVD reactor, wherein the CVD reactor, providing at least one SiC growth substrate inside the CVD reactor, wherein the SiC growth substrate forms a deposition surface surrounding the SiC growth substrate in circumferential direction of the SiC growth substrate, growing a polycrystalline SiC solid by depositing SiC on the deposition surface in the CVD reactor, wherein the depositing is carried out until the SiC solid is grown to a diameter of at least 1 cm, or preferably of at least 5 cm or particular preferably of at least 10 cm or most preferably of at least 20 cm or up to 100 cm, wherein the depositing is carried out until the SiC solid is grown to a cross-sectional size of at least 40 cm², in particular of at least 50 cm² or of at least 200 cm² or of at least 500 cm² and/or up to 1000 cm² or preferably up to 2000 cm² and most preferably up to 8000 cm², orthogonal to a current conduction path inside the SiC growth substrate, analyzing the SiC solid to determine the position of at least one crack-free SiC piece having a cross-sectional size of at least 4 cm² inside the SiC solid, removing the at least one crack-free SiC piece from the SiC solid. This solution is beneficial since at least one crack-free SiC piece can be produced with a CVD process, wherein the SiC piece can be used e.g. to remove multiple carrier wafers therefrom, in particular two or more than two or five or more than five or up to ten or ten or more than ten or up to twenty or twenty or more than twenty or up to fifty or fifty or more than fifty or up to one hundred or one hundred or more than one hundred.

According to a further preferred embodiment of the present invention the step of analyzing the SiC solid to determine a crack-free section of the SiC solid is carried out by optical inspection, in particular by means of a caliper or threshold detection. This embodiment is beneficial since an optical analysis can be carried out in a fast and cheap manner, without the danger of damaging the SiC solid.

The step of analyzing the SiC solid to determine the position of at least one crack-free SiC piece having a cross-sectional size of at least 4 cm² inside the SiC solid is carried out according to a further preferred embodiment of the present invention by determining the positions and/or orientations of defects, in particular cracks, inside the SiC piece. This embodiment is beneficial since an optimum of crack-free SiC can be determined and removed from the remaining material.

According to a further preferred embodiment of the present invention the step of analyzing the SiC piece to determine the positions and/or orientations of defects is carried out by means of a bend test, in particular a 2 point bend test, a 3 point bend test or a 4 point bend test, an eddy current testing and/or optical analyzing methods, in particular caliper testing or threshold testing. This embodiment is beneficial since the mentioned detection methods are well established and provide high quality information. Testing methods and systems are described in https://www.isravision.com/en/semiconductor/applications/back-end-of-line/internal-cracks/crack-detection-for-semiconductor-wafers/; https://www.hindawi.com/journals/amse/2013/950791/; https://cjme.springeropen.com/articles/10.1186/s10033-018-0229-2.

According to a further preferred embodiment of the present invention the step of heating the SiC growth substrate by conducting electric current from a first power connection to a second power connection or from the second power connection to the first power connection through the SiC growth substrate is carried out. T This embodiment is beneficial since the temperature can be adjusted very precisely due to control of electric power supply. According to a further preferred embodiment of the present invention the SiC growth substrate, in particular a growth face of the deposited SiC, is heated to a temperature of more than 1400° C. This embodiment is beneficial since the deposition velocity is higher compared to a temperature range below 1400° C. Due to a high deposition velocity crystallites are growing into the expanding directing of the SiC growth substrate, wherein expanding directing describes the direction the SiC deposits on the SiC growth substrate.

According to a further preferred embodiment of the present invention the growth face of the deposited SiC is heated to a temperature of less than 1700° C. and a center of the SiC growth substrate is heated to a temperature above 1400° C. This embodiment is beneficial since due to a large diameter (>7.5 cm) or cross-sectional area (>44.17 cm²) of the SiC solid (inner section plus outer section) the necessary electric power for heating the growth face to a temperature above 1400° C. increases and thereby increases the temperature in the center of the SiC growth substrate. It was found that temperature differences of more than 300K cause tensions inside the SiC solid, wherein said tensions causes cracks inside the SiC solid. Thus, due to the present embodiment cracks can be avoided.

The electric current is according to a further preferred embodiment of the present invention provided with alternating current. This is beneficial, since due to the alternating current the electric power is guided along the outer surface of the growing SiC and therefore heats the center less compared to DC. This is beneficial since the temperature in the center is preferably below the temperature of the outer surface. This is highly beneficial to cause a homogeneous temperature profile between the center and the outer surface, thus the temperature difference between the outer surface and the center is preferably below 300K and more preferably 200K and particular preferably below 100K and most preferably below 50K. This is beneficial to grow the SiC with a low level of tensions to avoid cracking of the SiC.

The frequency of the alternating current is according to a further preferred embodiment of the present invention above 5 Hz or preferably above 20 Hz or highly preferably above 50 Hz or most preferably above 500 Hz or up to 5000 Hz, in particular up to 2000 Hz or up to 1000 Hz or up to 500 kHz. Preferably the frequency of the alternating current can be modified during SiC production to better match the needs of a SiC solid having a small growth face and a SiC solid having a large growth face. This embodiment is beneficial since high growth rate and small temperature difference can be established.

The step of growing a SiC piece comprises according to a further preferred embodiment of the present invention setting up a deposition rate, in particular perpendicular deposition rate, of more than 200 μm/h, in particular of more than 250 μm/h and preferably of more than 300 μm/h and highly preferably of more than 400 μm/h and most preferably of more than 500 μm/h or of up to 2000 μm/h. This embodiment is beneficial since the output can be increased. This is preferably caused by defined heating of the physical structure and defined feeding of feed gases and cooling units at the same time.

According to a further preferred embodiment of the present invention the SiC growth substrate comprises a main body, a first power connection and a second power connection, wherein the main body has a main body length, wherein the main body length extends between the first power connection and the second power connection, wherein the first power connection is configured to conduct power into the main body for heating the main body and wherein the second power connection is configured to conduct electric power conducted via the first power connection into the main body out of the main body.

According to a further preferred embodiment of the present invention a step of etching the surface of the SiC growth substrate before the SiC growth substrate is provided inside the CVD reactor is carried out by hydrofluoric acid etching and/or etching the surface of the SiC growth substrate after the SiC growth substrate is provided inside the CVD reactor and before the step of growing a SiC solid by depositing SiC on the deposition surface of the SiC growth substrate in the CVD reactor.

This embodiment is beneficial since an oxide layer can be removed, which would be present on the surface of the SiC growth substrate and therefore the oxide layer would be present inside a grown SiC solid, since during growth the SiC would deposite onto said oxide layer and therefore would affect the electric properties of the SiC carrier wafer removed from said SiC solid.

The step of etching is carried out according to a further preferred embodiment of the present invention by gas etching, in particular hydrogen etching, and/or plasma etching, in particular hydrogen-plasma etching. Preferably an etch gas, in particular H, is feed into the reactor chamber, in which the SiC growth substrate is already located. The etch gas can be present inside the reactor chamber for a defined time, in particular up to or more than 5 min or up to or more than 10 min or up to or more than 20 min. However, the etch gas or fractions thereof can be renewed one time or multiple times. It is also possible that a continuous etch gas flow is established into the reaction chamber and out of the reaction chamber. This embodiment is beneficial since hydrogen (H) can be used for etching as well as carrier gas. Thus, the reactor already comprises the necessary features for carrying out the etching step.

The step of growing the SiC solid comprises the materialization of crystallites (2414) having a length of more than 5 μm, in particular more than 10 μm and preferably more than 20 μm and particular preferably more than 50 μm and most preferably up to 500 μm or up to 300 μm. More than 50% of all crystallites which are having a length of more than 5 μm preferably extend into width direction (orthogonal to length direction of the individual crystallite) less than 0.8×length extension and preferably less than 0.5χ length extension and highly preferably less than 0.3χ length extension. This embodiment is beneficial since due to the crystallites which are having a length of more than 5 μm tensions inside a SiC carrier wafer are compensated and thereby causing a bow or warp of preferably less than 50 μm or most preferably less than 20 μm.

According to a further preferred embodiment of the present invention the step of growing comprises growing more than 5 crystallites, in particular more than 10 crystallites and highly preferably more than 100 and most preferably more than 500 crystallites or up to 10000 crystallites, per 1 mm³, which are extending in length direction of the individual crystallite more than 5 μm, in particular more than 10 μm and preferably more than 20 μm and particular preferably more than 50 μm and highly preferably up to 300 μm and most preferably up to 500 μm. This embodiment is beneficial since due to a large number of long crystallites tensions inside a SiC carrier wafer are compensated and thereby causing a bow or warp of preferably less than 50 μm or most preferably less than 20 μm.

The SiC growth substrate comprises according to a further preferred embodiment of the present invention crystallites extending in length direction of the individual crystallite more than 5 μm, in particular more than 10 μm and preferably more than 20 μm and particular preferably more than 50 μm and highly preferably up to 300 μm and most preferably up to 500 μm. More than 50% of all crystallites which are having a length of more than 5 μm extend into width direction (orthogonal to length direction of the individual crystallite) less than 0.8×length extension and preferably less than 0.5χ length extension and highly preferably less than 0.3χ length extension. This embodiment is beneficial since long crystallites inside a SiC carrier wafer reduce tensions which would cause bow and warp. Furthermore, due to large crystallites the electric conductivity is enhances and thereby less doping is required compared to SiC having short crystallites.

According to a further preferred embodiment of the present invention more than 5 crystallites, in particular more than 10 crystallites and highly preferably more than 100 and most preferably more than 500 crystallites or up to 10000 crystallites, which are extending in length direction of the individual crystallite more than 5 μm, in particular more than 10 μm and preferably more than 20 μm and particular preferably more than 50 μm and highly preferably up to 300 μm and most preferably up to 500 μm, are present per 1 mm³ of the SiC growth substrate. This embodiment is beneficial since a stabilizing effect of the large crystallites increases the more crystallites of large size are present.

According to a further preferred embodiment of the present invention more than 50% and preferably at least 60% and most preferably at least 70% of all crystallites of the SiC growth substrate which are extending in length direction of the individual crystallite more than 5 μm, in particular more than 10 μm and preferably more than 20 μm and particular preferably more than 50 μm and highly preferably up to 300 μm and most preferably up to 500 μm, are inclined to a median direction of extension of said crystallites of the SiC growth substrate in an angle of less than +/−22.5°. This embodiment is beneficial since the inner section is removed from a part of an ingot which is in a distance to a center line of said ingot. Thus, the ingot is/was of such a size that multiple pieces are removable for removing individual wafers from each of said pieces, wherein the orientation of the crystallites preferably differs from piece to piece. Thus, one ingot provides material for the production of a large number of SiC carrier wafers.

According to a further preferred embodiment of the present invention more than 25% and preferably at least 50% and/or most preferably up to 75% of all crystallites which are extending in length direction of the individual crystallite more than 5 μm, in particular more than 10 μm and preferably more than 20 μm and particular preferably more than 50 μm and highly preferably up to 300 μm and most preferably up to 500 μm, are growing inclined to the median direction of extension of the inner section in an angle of more than +/−22.5°. This embodiment is beneficial since a significant number of crystallites of the outer section is inclined to the median direction of extension of the inner section and thereby causing a beneficial compensation of tensions.

According to a further preferred embodiment of the present invention the SiC solid is grown to a diameter of at least 7.5 cm. This embodiment is beneficial since large SiC carrier wafers can be removed from ingots or boules having a diameter of 7.5 cm or of more than 7.5 cm.

According to a further preferred embodiment of the present invention the SiC, in particular the deposited SiC, is doped with Nitrogen, in particular more than 2000 ppba nitrogen and/or below 1018 Nitrogen atoms/cm³, during the step of growing. This embodiment is beneficial since the necessary electric conductivity can be established with less doping atoms compared to known processes. This results from the large crystallites which are grown due to the present invention.

The SiC solid is according to a further preferred embodiment of the present invention predominantly grown with a 3C crystal structure. This embodiment is beneficial since the properties of a SiC carrier wafer having predominantly a 3C crystal structure is advantageous over other crystal structures.

The above-mentioned object is also solved by a method according to claim 60 for the production of multiple crack-free workpieces. The method for the production of multiple crack-free workpieces preferably comprises according to the present invention at least a herein disclosed method for producing of at least one large SiC piece, in particular a method according to claims 38 to 59, and the step of dividing the at least one crack-free SiC piece in multiple predetermined pieces. The step of dividing preferably comprises cutting the defined volume section with at least one wire saw or weakening the structure of the defined volume with laser radiation and thereby generating a defined laser-split-plane and introducing an external force to propagate a crack along the defined laser-split-plane or implanting ions into the structure of the defined volume and thereby generating a defined ion-split-plane and increasing the pressure inside the defined volume by increasing the volume of the implanted ions, in particular by heating the defined volume, to propagate a crack along the defined ion-split-plane. This solution is beneficial since SiC carrier wafers removed from a SiC piece are much cheaper compared to epitaxial grown SiC carrier wafers.

The predetermined pieces are according to a further preferred embodiment of the present invention wafers, in particular SiC carrier wafers, wherein each wafer has a height between 200 μm and 1000 μm and preferably between 200 μm and 500 μm and most preferably between 300 μm and 450 μm. Wherein “height” preferably defines the distance between two plane surfaces parallel to each other.

The above-mentioned object is also solved by a method according to claim 62 for the production of a SiC carrier wafer. The method for the production of a SiC carrier wafer comprises according to the present invention preferably at least a herein disclosed method for the production of multiple crack-free workpieces, in particular a method according to claim 60 or 61, and the step of processing at least one cutted surface or splitted surface of the wafer, in particular grinding and/or lapping and/or polishing, to generate a processed surface having at least one defined surface property. The cutted surface resulted from cutting, in particular sawing, or the splitted surface resulted from splitting a SiC solid, in particular ingot or boule, into exactly or at least two pieces.

The height of the carrier wafer is according to a further preferred embodiment of the present invention reduced by processing the at least one cutted surface or splitted surface to a height between between 200 μm and 500 μm and most preferably between 300 μm and 450 μm.

According to a further preferred embodiment of the present invention the method comprises the step of analyzing the SiC carrier wafer to determine defects, in particular cracks. This embodiment is beneficial since further processing of damaged wafers respectively of wafer comprising defects can be avoided.

The step of analyzing the SiC piece or the SiC carrier wafer to determine defects is according to a further preferred embodiment of the present invention carried out by means of a bend test, in particular a 2-point bend test, a 3-point bend test or a 4-point bend test, an eddy current testing and/or optical analyzing methods, in particular caliper testing or threshold testing. This embodiment is beneficial since well established method/s can be applied in fast and cheap manner.

The above-mentioned object is also solved by a method according to claim 66 for the production of a composite substrate. The method for the production of a composite substrate according to the present invention preferably comprises at least a herein disclosed method for the production of a carrier wafer, in particular a method according to claim 62, 63, 64 and/or 65 and the step: Bonding a monocrystalline SiC wafer to the processed surface. This solution is beneficial since a composite substrate can be produced in a cheap and fast manner.

The monocrystalline SiC wafer is according to a further preferred embodiment of the present invention formed by a crystal structure, wherein the crystal structure defines a c-axis, wherein the crystal structure is grown perpendicular to the c-axis, wherein the monocrystalline SiC crystal has a preferably flat top surface, a preferably flat bottom surface and a connecting-surface connecting the top surface and bottom surface, wherein the c-axis is aligned in an angle between 0° and 8° and preferably in an angle between 2° and 6° with respect to a normal on the top surface, wherein monocrystalline SiC wafer preferably consists of SiC of the 4H type. This embodiment is beneficial since the produced composite wafer can be further processed for the production of devices.

According to a further preferred embodiment of the present invention the method comprises the step of growing a monocrystalline SiC layer by means of epitaxy onto the monocrystalline SiC wafer, wherein monocrystalline SiC layer has a thickness between 1 μm and 50 μm, in particular between 2 μm and 40 μm or between 3 μm and 30 μm or between 4 μm and 20 μm or between 5 μm and 10 μm. This embodiment is beneficial since a composite wafer is formed that can be used for the production of at least one and preferably multiple products.

The above-mentioned object is also solved by an electric device according to claim 71. The electric device according to the present invention preferably comprises at least a composite substrate, in particular a herein disclosed composite substrate, e.g. a composite substrate according to claim 12 or 70, wherein at least one electric component is grown or produced on or in the monocrystalline SiC crystal layer and wherein the SiC carrier wafer has a thickness of more than 50 μm, in particular more than 60 μm or more than 80 μm or more than 100 μm or more than 150 μm or up to 350 μm. The electronic device can be a MOSFET or a Schottky Diode. This solution is beneficial since said electronic device can be produced at lower costs and higher quality.

The above-mentioned object is also solved by a SiC production reactor according to claim 72, in particular for carrying out a herein disclosed method for producing of at least one large SiC piece, in particular a method according to any of claims 38 to 59. The SiC production reactor preferably comprises at least a process chamber, a gas inlet unit for feeding one feed-medium or multiple feed-mediums into a reaction space of the process chamber, wherein the gas inlet unit is coupled with at least one feed-medium source, or wherein the gas inlet unit is coupled with at least two feed-medium sources, and one or multiple SiC growth substrate, in particular more than 3 or 4 or 6 or 8 or 16 or 32 or 64 or up to 128 or up to 256, are arranged inside the process chamber for depositing SiC, wherein each SiC growth substrate is coupled with a first power connection and a second power connection, wherein the first power connections are first metal electrodes and wherein the second power connections are second metal electrodes, wherein the first metal electrodes and the second metal electrodes are preferably shielded from a reaction space inside the process chamber, wherein each SiC growth substrate is coupled between at least one first metal electrode and at least one second metal electrode for heating the outer surface of the SiC growth substrates or a SiC growth surface of the deposited SiC to temperatures between 1400° C. and 1700° C., in particular by means of resistive heating and preferably by internal resistive heating, an alternating current source, wherein the at least one first metal electrode and at least one second metal electrode are connected to the alternating current source, wherein the alternating current source is configured to set up a frequency of the alternating current above 5 Hz or preferably above 20 Hz or highly preferably above 50 Hz or most preferably above 500 Hz or up to 5000 Hz, in particular up to 2000 Hz or up to 1000 Hz or up to 500 kHz. The process chamber is preferably at least surrounded by a base plate, a side wall section and a top wall section, wherein the base plate preferably comprises at least one cooling element, in particular a base cooling element, for preventing heating of the base plate above a defined temperature and/or wherein the side wall section preferably comprises at least one cooling element, in particular a bell jar cooling element, for preventing heating of the side wall section above a defined temperature and/or wherein the top wall section preferably comprises at least one cooling element, in particular a bell jar cooling element, for preventing heating of the top wall section above a defined temperature. Preferably the at least one cooling element is a passive cooling element, wherein the at least one cooling element is at least partially formed by a polished steel surface of the base plate, the side wall section and/or the top wall section, wherein the cooling element is preferably a coating, wherein the coating is preferably formed on top of the preferably polished steel surface and wherein the coating is preferably configured to reflect heat, wherein the coating is preferably a metal coating or comprises metal, in particular silver or gold or chrome, or alloy coating, in particular a CuNi alloy. The emissivity of the polished steel surface and/or of the coating is preferably below 0.3, in particular below 0.1 or below 0.03.

This solution is beneficial since one or multiple SiC solids can be produced, wherein each of said SiC solids comprises a low level of tensions due to small temperature mismatch between the core temperature of the SiC growth substrate and the temperature of the growth face. Said low level of tensions results in SiC solids having only a few, in particular up to 5 or 10 or 20, cracks and thereby can be used to produce SiC carrier wafer having low warp and/or bow, in particular below 50 μm and preferably below 20 μm.

A gas outlet unit for outputting vent gas and a vent gas recycling unit are provided according to a further preferred embodiment of the present invention, wherein the vent gas recycling unit is connected to the gas outlet unit, wherein the vent gas recycling unit comprises at least a separator unit for separating the vent gas into a first fluid and into a second fluid, wherein the first fluid is a liquid and wherein the second fluid is a gas, wherein a first storage and/or conducting element for storing or conducting the first fluid is part of the separator unit or coupled with the separator unit and wherein a second storage and/or conducting element for storing or conducting the second fluid is part of the separator unit or coupled with the separator unit. This embodiment is beneficial since source material costs can significantly be reduced. The separator unit is preferably operated at a pressure above 5 bar and a temperature below-30° C. The vent gas is therefore preferably fed into the separation unit, which can be a cold distillation column, where the Si-bearing compounds condense from gas to liquid form and travel down the column and exit out the bottom while the remaining gases of H, HCl, and methane travel up the column and exit out the top. The liquid is the first fluid and preferably comprises predominantly HCl and Chlorosilanes with minor percentage of H2 and C-gas. The gas is the second fluid, preferably comprising predominantly H2 and C-gas with minor percentage of HCl and Chlorosilanes.

The vent gas recycling unit comprises according to a further preferred embodiment of the present invention a further separator unit for separating the first fluid into at least two parts, wherein the two parts are a mixture of chlorosilanes and a mixture of HCl, H2 and at least one C-bearing molecule, and preferably into at least three parts, wherein the three parts are a mixture of chlorosilanes and HCl and a mixture of H2 and at least one C-bearing molecule, wherein the first storage and/or conducting element connects the separator unit with the further separator unit. This embodiment is beneficial since the HCl and H2 and at least one C-bearing molecule can be directly feed into a process chamber of a SiC production reactor for the production of SiC material, in particular material to manufacture SiC carrier wafer, or PVT source material. The further separator unit is preferably configured to be operate at a pressure above 5 bar and a temperature below −30° C. and/or a temperature above 100° C.

The further separator unit is according to a further preferred embodiment of the present invention coupled with a mixture or chlorosilanes storage and/or conducting element and with a HCl storage and/or conducting element and with a H2 and C storage and/or conducting element.

In the context of the present invention “C” can be understood as “at least one C-bearing molecule”, thus the H2 and C storage and/or conducting element can be alternatively understood as H2 and at least one C-bearing molecule storage and/or conducting element.

The mixture of chlorosilanes storage and/or conducting element forms according to a further preferred embodiment of the present invention a section of a mixture of chlorosilanes mass flux path for conducting the mixture of chlorosilanes into the process chamber. This embodiment is beneficial since the chlorosilanes can be used as mixture. Thus, it is not necessary to further process the mixture of chlorosilanes with respect to a separation of the individual chlorosilanes.

Thus, due to the present invention it is also possible to manufacture a SiC material, in particular material to manufacture SiC carrier wafer, or SiC source material with at least 6N or preferably 7N or more preferably 8N in large scales, wherein the provided feed gases used are recycled back from vent gases of a first SiC source production reactor. This is achieved by measuring the atomic ratio of H to C in the mixture and providing an appropriate ratio of makeup H hydrogen and C-bearing gas to the CVD reactor along with the mixture such that the overall H to C molar ratio of hydrogen and carbon in the C-bearing gas is in the required range. Under the given conditions in both the CVD reaction and the subsequent cold distillation, any carbon is present as methane. Any side products derived from methane in the CVD reaction will have higher boiling points and been separated from the gas phase in the cold distillation. Methane can be quantified e.g. by inline or online measurement (PAT, process analytical techniques), such as flame ionization detector, infrared spectrometry in any style (e.g. FTIR or NIR) or cavity ring-down spectroscopy (with most sensitive detection limits), or any other inline or online analytical method, which provides results with the required accuracy within seconds. The hydrogen content can be calculated from the measured total mass flow of the gas mixture and the quantified methane concentration. Losses are preferably compensated to maintain the molar ratio of the original feed gas mixture. This embodiment is beneficial since due to the recycling of the vent gas the purity of the recycled Si, C and H2 is further increased, thus the purity of the produced SiC is even better.

A Si mass flux measurement unit for measuring an amount of Si of the mixture of chlorosilanes is provided according to a further preferred embodiment of the present invention as part of the mass flux path prior to the process chamber, in particular prior to a mixing device, and preferably as further Si feed-medium source providing a further Si feed medium. The mixture of chlorosilanes storage and/or conducting element forms according to a further preferred embodiment of the present invention a section of a mixture of chlorosilanes mass flux path for conducting the mixture of chlorosilanes into a further process chamber of a further SiC production reactor. This embodiment is beneficial since it can be very precisely controlled if a feed medium from a feed source or a feed medium from the recycling unit is used. Additionally or alternatively feed medium from the feed source can be added to the feed medium from the recycling unit in case the feed medium of the recycling unit is not sufficient.

The H2 an C storage and/or conducting element forms according to a further preferred embodiment of the present invention a section of a H2 and C mass flux path for conducting the H2 and the at least one C-bearing molecule into the process chamber. It is possible that HCl is also present. A C mass flux measurement unit for measuring an amount of C of the mixture of H2 and the at least one C-bearing molecule is provided according to a further preferred embodiment of the present invention as part of the H2 and C mass flux path prior to the process chamber, in particular prior to a mixing device, and preferably as further C feed-medium source providing a further C feed medium. The H2 an C storage and/or conducting element forms according to a further preferred embodiment of the present invention a section of a H2 and C mass flux path for conducting the H2 and the at least one C-bearing molecule into a further process chamber of a further SiC production reactor. The second storage and/or conducting element forms according to a further preferred embodiment of the present invention a section of the H2 and C mass flux path for conducting the second fluid, which comprises H2 and at least one C-bearing molecule, into the process chamber, wherein the second storage and/or conducting element and the H2 an C storage and/or conducting element are preferably fluidly coupled. The second storage and/or conducting element forms according to a further preferred embodiment of the present invention a section of a further H2 and C mass flux path for conducting the second fluid, which comprises H2 and at least one C-bearing molecule, into the process chamber. A further C mass flux measurement unit for measuring an amount of C of the second fluid is provided according to a further preferred embodiment of the present invention as part of the further H2 and C mass flux path prior to the process chamber, in particular prior to a mixing device. This embodiment is beneficial since besides the usage of chlorosilanes also H2 and at least one C-bearing molecule are recycled and therefore the overall efficiency is increased.

The second storage and/or conducting element is coupled according to a further preferred embodiment of the present invention with a flare unit for burning the second fluid.

A first compressor for compressing the vent gas to a pressure above 5 bar is according to a further preferred embodiment of the present invention provided as part of the separator unit or in a gas flow path between the gas outlet unit and the separator unit. A further compressor for compressing the first fluid to a pressure above 5 bar is according to a further preferred embodiment of the present invention provided as part of the further separator unit or in a gas flow path between the separator unit and the further separator unit.

The further separator unit preferably comprises a cryogenic distillation unit, wherein the cryogenic distillation unit is according to a further preferred embodiment of the present invention preferably configured to be operated at temperatures between −180C° and −40C°.

This embodiment is beneficial since TCS has a boiling point of 31.8° C. and STC has a boiling point of 57.7° C. With such low but substantially different boiling points, TCS and STC can be effectively and economically separated from each other and from any heavy contaminants such as trace metals by conventional distillation methods and apparatuses. On the other hand, purification of methane from N requires more complicated cryogenic distillation. The boiling point of methane is −161.6° C. and the boiling point of N is −195.8° C. Therefore, a distillation column can to be operated at a temperature somewhere in between so that the methane is liquid and travels toward the bottom of the column and the nitrogen is gaseous and travels toward the top of the column.

A control unit for controlling fluid flow of a feed-medium or multiple feed-mediums is according to a further preferred embodiment of the present invention part of the SiC production reactor, wherein the multiple feed-mediums comprise the first medium, the second medium, the third medium and the further Si feed medium and/or the further C feed medium via the gas inlet unit into the process chamber is provided. The further Si feed medium preferably consists of at least 95% [mass] or at least 98% [mass] or at least 99% [mass] or at least 99.9% [mass] or at least 99.99% [mass] or at least 99,999% [mass] of a mixture of chlorosilanes. The further C feed medium preferably comprises the at least one C-bearing molecule, H2, HCl and a mixture of chlorosilanes, wherein the further C feed medium comprises of at least 3% [mass] or preferably at least 5% [mass] or highly preferably at least 10% [mass] of C respectively of the at least one C-bearing molecule and wherein the further C feed medium comprises up to 10% [mass] or preferably between 0.001% [mass] and 10% [mass], highly preferably between 1% [mass] and 5% [mass], of HCl and wherein the further C feed medium comprises more than 5% [mass] or preferably more than 10% [mass] or highly preferably more than 25% [mass] of H2 and wherein the further C feed medium comprises more than 0.01% [mass] and preferably more than 1% [mass] and highly preferably between 0.001% [mass] and 10% [mass] of the mixture of chlorosilanes.

A heating unit is according to a further preferred embodiment of the present invention arranged in fluid flow direction between the further separator unit and the gas inlet unit for heating the mixture of chlorosilanes to transform the mixture of chlorosilanes from a liquid form into a gaseous form.

The base plate comprises according to a further preferred embodiment of the present invention at least one additional cooling element, in particular a base cooling element, for preventing heating of the base plate above a defined temperature, in particular for preventing heating of the base plate above 1100° C. and preferably above 1000° C. and most preferably above 900° C. Additionally or alternatively the side wall section comprises at least one additional cooling element, in particular a bell jar cooling element, for preventing heating of the side wall section above a defined temperature, in particular for preventing heating of the base plate above 1100° C. and preferably above 1000° C. and most preferably above 900° C.

Additionally or alternatively the top wall section comprises at least one additional cooling element, in particular a bell jar cooling element, for preventing heating of the top wall section above a defined temperature, in particular for preventing heating of the base plate above 1100° C. and preferably above 1000° C. and most preferably above 900° C. The additional cooling element is preferably an active cooling element. The base plate and/or side wall section and/or top wall section comprises according to a further preferred embodiment of the present invention a cooling fluid guide unit for guiding a cooling fluid, wherein the cooling fluid guide unit is configured to limit heating of the base plate and/or side wall section and/or top wall section to a temperature below 1000° C. This embodiment is beneficial since metal components can be used, in particular the bell jar can be made of metal.

A base plate and/or side wall section and/or top wall section sensor unit is provided according to a further preferred embodiment of the present invention to detect temperature of the base plate and/or side wall section and/or top wall section and to output a temperature signal or temperature data and/or a cooling fluid temperature sensor is provided to detect the temperature of the cooling fluid, and a fluid forwarding unit is provided for forwarding the cooling fluid through the fluid guide unit, wherein the fluid forwarding unit is preferably configured to be operated in dependency of the temperature signal or temperature data provided by the base plate and/or side wall section and/or top wall section sensor unit and/or cooling fluid temperature sensor. This solution is beneficial since the base plate, the side wall section and the top wall section can be made of metal, in particular steel. A metal base plate, side wall section and a top wall section allows the production of larger reactors and therefore helps to increase the output or to reduce the costs.

According to a further preferred embodiment of the present invention the cooling fluid is water. The cooling fluid is according to a further preferred embodiment of the present invention oil or water, wherein the water preferably comprises at least one additive, in particular corrosion inhibiter/s and/or antifouling agent/s (biocides). This embodiment is beneficial since the cooling liquid can be modified to avoid defects or contaminations of the SiC production reactor.

The base plate comprises according to a further preferred embodiment of the present invention at least one active cooling element and one passive cooling element for preventing heating of the base plate above a defined temperature and/or the side wall section comprises at least one active cooling element and one passive cooling element for preventing heating of the side wall section above a defined temperature and/or the top wall section comprises at least one active cooling element and one passive cooling element for preventing heating of the top wall section above a defined temperature.

The side wall section and the top wall section are formed according to a further preferred embodiment of the present invention by a bell jar, wherein the bell jar is preferably movable with respect to the base plate. More than 50% [mass] of the side wall section and/or more than 50% [mass] of the top wall section and/or more than 50% [mass] of base plate is according to a further preferred embodiment of the present invention made of metal, in particular steel. This embodiment is beneficial since large steel bell jars can be manufactured causing a significant increase in process chamber volume and therefore in potential SiC material. Thus a bell jar is preferably provided, wherein the bell jar comprises according to a further preferred embodiment of the present invention a contact region for forming an interface with the base unit, wherein the interface is sealed against leakage of gaseous species, wherein the bell jar comprises a bell jar cooling unit, wherein the bell jar cooling element forms at least one channel or trench or recess for holding or guiding a bell jar cooling liquid, wherein the bell jar cooling element is configured to cool at least one section of the bell jar and preferably the entire bell jar below a defined temperature respectively to remove a defined amount of heat per min during the production run. The bell jar cooling element and/or base plate cooling element is preferably controlled by the control unit. Additionally, or alternatively the bell jar cooling element and/or base cooling element are coupled with each other to form one major cooling unit.

According to a further preferred embodiment of the present invention a carrier gas medium source provides a third feed medium, in particular H2. This embodiment is beneficial since the carrier gas can also be used to etch the surface of a SiC growth substrate prior to SiC deposition.

According to a further preferred embodiment of the present invention the Si and C feed-medium source provides at least Si and C, in particular SiCl₃(CH₃). This embodiment is beneficial since the ratio of Si and C is fix in case of one source gas.

According to a further preferred embodiment of the present invention a Si feed medium source provides at least Si, in particular the Si feed medium source provides a first feed medium, wherein the first feed medium is a Si feed medium, in particular a Si gas according to the general formula SiH_{4-y} X_{y} (X═[Cl, F, Br, J]und y=[0 . . . 4]. Additionally a C feed medium source provides at least C, in particular the C feed medium source provided a second feed medium, wherein the second feed medium is a C feed medium, in particular natural gas, Methane, Ethan, Propane, Butane and/or Acetylene. This embodiment is beneficial since the source gases can be individually purchased and therefore costs can be reduced. Furthermore, the mixture can be modified during a production run.

A carrier gas medium source provides according to a further preferred embodiment of the present invention a third feed medium, wherein the third feed medium is a carrier gas, in particular H2.

SiC pieces can be used in different applications, in particular as braking wheels or PVT source material or carrier wafers. However, carrier wafer are produced according to the state of the art by depositing a thin layer on a substrate in a CVD process. Said process is very slow and therefore expensive.

Therefore, it is the object of the present invention to provide a method allowing cheaper production of SiC for use as SiC piece.

The before mentioned object can also be solved by a method for producing at least one crack-free SiC piece. Said method preferably comprises at least the steps: Providing a CVD reactor, wherein the CVD reactor comprises at least one SiC growth substrate, wherein the at least one SiC growth substrate comprises a main body, a first power connection and a second power connection, wherein the main body has a main body length, wherein the main body length extends between the first power connection and the second power connection, wherein the first power connection is configured to conduct power into the main body for heating the main body and wherein the second power connection is configured to conduct electric power conducted via the first power connection into the main body out of the main body, wherein the main body forms a physical structure, wherein the physical structure forms a deposition surface for deposition of SiC. The method preferably also comprises the step of growing a SiC solid by depositing SiC on the physical structure in the CVD reactor, wherein the at least one crack-free SiC piece is part of the SiC solid, wherein the deposited SiC has a minimal thickness of at least 1 cm, wherein the at least one SiC piece is formed between a first plane and a second plane, wherein the first plane is perpendicular to the main body length and wherein the second plane is perpendicular to the main body length, wherein the distance between the first plane and the second plane is at least 1% and preferably at least 2% and highly preferably at least 5% of the main body length. The preferably also comprises the step of removing the at least one crack-free SiC piece from the SiC solid, wherein the at least one crack-free SiC piece has a cross-sectional size of at least 4 cm² and preferably of at least 8 cm² and highly preferably of at least 12 cm² and a thickness of at least 0, 1 cm and preferably of at least 1 cm and highly preferably of at least 2 cm.

This solution is beneficial since crack-free SiC is produced which allows the production of SiC solids which can be used for different applications, in particular applications having high mechanical, thermal and/or electrical load.

The mentioned CVD reactor (in particular each mentioned CVD reactor of the present invention) can be a modification of a CVD reactor according to PCT/EP2021/085479. The subject-matter of PCT/EP2021/085479 is entirely incorporated into the present subject-matter by reference.

Removing can be carried out by means of different technologies, e.g. according to WO2021191511, WO2016162428 or US2014038392.

The volume of the at least one crack-free SiC piece is according to a preferred embodiment of the present invention more than 2 cm³ and preferably more than 4 cm³ and most preferably more than 8 cm³. This embodiment is beneficial since large crack-free volumetric bodies allow the production of large SiC solids, in particular large carrier wafer.

The at least one crack-free SiC piece extends according to a preferred embodiment of the present invention in a first direction more compared to a second direction, wherein the second direction is orthogonal to the first direction. This embodiment is beneficial since the SiC piece can be a defined block of SiC, in particular for usage as PVT source material.

The first direction is according to a preferred embodiment of the present invention parallel to the main body length or coaxial to the main body length or aligned in an angle of less than 50°, in particular of less than 30° and preferably of less than 10° and most preferably of less than 5° or of 0°, with respect to the main body length. The first direction is preferably aligned in an angle between 120° and 60°, in particular in an angle between 110° and 70° and preferably in an angle between 100° and 80° and most preferably in an angle between 95° and 85° or in an angle of 90°, with respect to the main body length. This embodiment is beneficial since the SiC solid can be aligned in an angle different to 0° or 90° with respect to the length direction.

The at least one crack-free SiC piece is according to a preferred embodiment of the present invention formed in a distance to the physical structure. This embodiment is beneficial since the physical structure can be reused since the crack-free SiC piece could be removed from the grown crust.

The physical structure comprises according to a preferred embodiment of the present invention less than 5% (mass) SiC and preferably less than 2% (mass) SiC and highly preferably less than 1% (mass) SiC. This embodiment is beneficial since the physical structure can be made of a material mainly (mass) or entirely (mass) different from SiC.

The physical structure comprises according to a preferred embodiment of the present invention more than 90% (mass) of graphite, tungsten or a carbon-fiber-composite (CFC) material and preferably more than 95% (mass) of graphite, tungsten or a carbon-fiber-composite (CFC) material and highly preferably more than 99% (mass) of graphite, tungsten or a carbon-fiber-composite (CFC) material and most preferably more than 99.9% (mass) of graphite, tungsten or a carbon-fiber-composite (CFC) material. This embodiment is beneficial since a physical structure made of graphite, tungsten or carbon-fiber composite (CFC) material can be reused and can be easily manufactured.

The at least one crack-free SiC piece is according to a preferred embodiment of the present invention formed at least partially as part of the physical structure. This embodiment is beneficial since the crack-free SiC piece can be significant larger compared to SiC pieces only removed from the crust.

The physical structure comprises according to a preferred embodiment of the present invention more than 90% (mass) and preferably more than 95% (mass) and particular preferably more than 99% (mass) and most preferably more than 99.99% SiC, in particular polycrystalline SiC, in particular of a 3C crystal structure. The deposited SiC is according to a preferred embodiment of the present invention polycrystalline SiC, wherein the deposited SiC forms volume sections with different crystal structures, wherein a 3C crystal structure is predominantly (mass and/or volume) formed. The volume and/or mass of SiC formed in the 3C crystal structure comprises according to a preferred embodiment of the present invention more than 50% (volume and/or mass) and preferably more than 90% (volume and/or mass) and particular preferably more than 99% (volume and/or mass) and most preferably more than 99.9% (volume and/or mass) of the deposited SiC. This embodiment is beneficial since the crust and the physical structure are preferably having the same crystal structure or mainly the same crystal structure or at least a similar crystal structure, therefore SiC pieces consisting of parts of the physical structure and the crust are having very uniform mechanical, electrical and/or chemical properties, which allows usage in a large range of applications. Uniform mechanical, electrical and/or chemical
properties have to be understood as differing preferably less than 10% and particular preferably less than 5% and most preferably less than 1%.

The method comprises according to a preferred embodiment of the present invention the step of controlling cooling of the deposited SiC and the physical structure. Current flow through the physical structure is according to a preferred embodiment of the present invention reduced in a defined manner, in particular over a defined time, in particular of more than 1 h or preferably of more than 2 h or particular preferably of more than 3 h or most preferably of more than 4 h. This embodiment is beneficial since due to a controlled cooling tensions resulting from thermal differences can be limited respectively reduced. The reduction of thermal induced tensions reduces the generation and/or propagation of cracks.

The deposited SiC comprises according to a preferred embodiment of the present invention less than 2000 ppba nitrogen, in particular less than 100 ppba nitrogen. This embodiment is beneficial since the deposited SiC respectively the SiC pieces can be used in a PVT reactor as source material without contaminating the monocrystalline SiC with nitrogen in case nitrogen is not desired.

The method comprises according to a preferred embodiment of the present invention the step of feeding nitrogen into the CVD reactor for doping the SiC during depositing. This embodiment is beneficial since SiC pieces can be manufactured with defined electrical properties for use e.g. as carrier wafer.

The deposited SiC and/or the physical structure has according to a preferred embodiment of the present invention impurities of less than 10 ppm (weight) of the substance N and of less than 1000 ppb (weight), in particular of less than 500 ppb (weight), of each of the substances B, Al, P, Ti, V, Fe, Ni. The deposited SiC and/or the physical structure has preferably impurities of less than 2 ppm (weight) of the substance N and of less than 100 ppb (weight) of each of the substances B, Al, P, Ti, V, Fe, Ni. The deposited SiC and/or the physical structure has highly preferably impurities of less than 10 ppb (weight) of the substance Ti. The deposited SiC and/or the physical structure has most preferably impurities of less than 10 ppm (weight) of the substance N and of less than 1000 ppb (weight), in particular of less than 500 ppb (weight), of the sum of all of the metals Ti, V, Fe, Ni. This embodiment is beneficial the SiC piece or multiple SiC pieces can be used as high-quality PVT source material for the production of monocrystalline SiC crystals having a very small amount of one or multiple of the substances B, Al, P, Ti, V, Fe, Ni.

The above-mentioned object can also be solved by a method for the production of multiple crack-free workpieces. Said method preferably comprises at least a method for producing at least one crack-free SiC piece as disclosed herein and the step of dividing the at least one crack-free SiC piece in multiple predetermined pieces. This solution is beneficial since multiple carrier wafer, in particular two or more than two and preferably five or more than five and particular preferably ten or more than ten or up to 50, can be removed from one SiC piece. Since removing of carrier wafers is much faster compared to growing each single polycrystalline SiC wafer in a CVD process the costs can be significantly reduced by means of the present invention.

The dividing step comprises according to a preferred embodiment of the present invention cutting the defined volume section with at least one wire saw or weakening the structure of the defined volume with laser radiation and thereby generating a defined laser-split-plane and introducing an external force to propagate a crack along the defined laser-split-plane or implanting ions into the structure of the defined volume and thereby generating a defined ion-split-plane and increasing the pressure inside the defined volume by increasing the volume of the implanted ions, in particular by heating the defined volume, to propagate a crack along the defined ion-split-plane. This embodiment is beneficial since different dividing methods can be applied. Thus, in dependency of the required properties a matching dividing method can be selected. E.g. in case the contamination should be very small, a defined laser-split-plane could be used. In case the costs should be as small as possible a wire saw could be used.

Thus, dividing can be carried out by means of different technologies, e.g. according to WO2021191511, WO2016162428 or US2014038392.

The predetermined pieces are according to a preferred embodiment of the present invention wafers, wherein each wafer has a height of more than 200 μm, in particular of more than 250 μm and preferably of up to 1000 μm or of more than 1000 μm. This embodiment is beneficial since the generated wafers have a high mechanical strength and could therefore be used as carrier wafer for carrying very small monocrystalline wafers, in particular very small monocrystalline SiC wafers. Very small preferably defines a thickness of less than 100 μm and preferably of less than 50 μm and most preferably of less than 40 μm.

A diameter of the main body has according to a preferred embodiment of the present invention a minimum length of 100 mm and preferably a minimum length of 150 mm and particular preferably a minimum length of 250 mm and most preferably a minimum or maximum length of 300 mm. This embodiment is beneficial since large SiC pieces can be generated.

The above-mentioned object can also be solved by a method for the production of a composite substrate. The method preferably comprises at least a herein disclosed method for the production of multiple crack-free workpieces and the steps: Processing at least one surface of the wafer, in particular grinding and/or lapping and/or polishing, to generate a processed surface having at least one defined surface property and bonding a monocrystalline SiC wafer to the processed surface. This solution is beneficial since the composite substrate can be produced at low cost, since the costs for the production of the carrier wafer are significantly reduces.

According to a preferred embodiment of the present invention each SiC growth substrate comprises a first power connection and a second power connection, wherein the first power connections are first metal electrodes and wherein the second power connections are second metal electrodes, wherein the first metal electrodes and the second metal electrodes are preferably shielded from a reaction space inside the process chamber, wherein each SiC growth substrate is coupled between at least one first metal electrode and at least one second metal electrode for heating the outer surface of the SiC growth substrates or the surface of the deposited SiC to temperatures between 1400° C. and 1700° C., in particular by means of resistive heating and preferably by internal resistive heating. This embodiment is beneficial since the SiC growth substrates can be heated in a very effective manner.

Since flowing electrical current requires an inlet and an outlet electrode, these electrodes are preferably disposed in multiple pairs, such as preferably 12 pairs or 18 pairs or 24 pairs or 36 pairs or more. A deposition substrate respectively SiC growth substrate is preferably attached to each electrode, in particular metal electrode, of an electrode pair (first and second metal electrode) and the substrates are connected at the top by a cross member respectively bridge of the same material as the substrate to complete the electrical circuit. The deposition substrates respectively SiC growth substrates are preferably attached to the electrodes via an intermediate piece respectively chuck. The chuck preferably has a reducing cross-sectional area extending from the electrode to the deposition substrate so that electrical current is concentrated and resistive heating increases. The purpose of the chuck is to maintain a temperature below deposition temperature at the lower wider end and to maintain a temperature above deposition temperature at the upper narrower end. The chuck is preferably conical in shape. The chuck, deposition substrate, and bridge are preferably made from graphite or more preferably from high purity graphite with total ash content of less than 50000 ppm and preferably less than 5000 ppm and highly preferably less than 500 ppm. The deposition substrate is also preferably made from SiC. According to a further aspect of the present invention contact between first metal electrode and SiC growth substrate is in a different plane than the contact between second metal electrode and SiC growth substrate. The second electrode can preferably be arranged or provided on an opposite side of the process chamber and/or as part of the bell jar.

The process chamber is according to a preferred embodiment of the present invention at least surrounded by a base plate, a side wall section and a top wall section. This embodiment is beneficial since the process chamber can be isolated respectively defined by the base plate, side wall section and top wall section. The baseplate is preferably also disposed with a plurality of gas inlet ports and one gas outlet port or multiple a gas outlet ports. The gas inlet ports and outlet port are arranged so as to create an optimal flow of feed gas inside the CVD reactor respectively SiC production reactor, in particular SiC PVT source material production reactor, such that fresh feed gas is continually brought in contact with the deposition surfaces on the deposition substrates.

The gas inlet unit is according to a further preferred embodiment of the present invention coupled with at least one feed-medium source, wherein the one feed-medium source is a Si and C feed-medium source, wherein the Si and C feed-medium source provides at least Si and C, in particular SiCl3(CH3), and wherein a carrier gas feed-medium source provides a carrier gas, in particular H2, or wherein the gas inlet unit is coupled with at least two feed-medium sources, one of the two feed-medium sources is a Si feed medium source, wherein the Si feed medium source provides at least Si, in particular a Si gas according to the general formula SiH4-y Xy (X═[Cl, F, Br, J]und y=[0 . . . 4], and another one of the two feed-medium sources is a C feed medium source, wherein the C feed medium source provides at least C, in particular natural gas, Methane, Ethan, Propane, Butane and/or Acetylene, and wherein a carrier gas medium source provides a carrier gas, in particular H2.

Alternatively the first feed medium is a Si feed medium, in particular a Si gas according to the general formula SiH4-y Xy (X═[Cl, F, Br, J]und y=[0 . . . 4], wherein the gas inlet unit is coupled with at least one feed-medium source, wherein a Si and C feed-medium source provides at least Si and C, in particular SiCl3(CH3) and wherein a carrier gas feed-medium source provides a carrier gas, in particular H2, or wherein the gas inlet unit is coupled with at least two feed-medium sources, wherein a Si feed medium source provides at least Si, in particular the Si feed medium source provides a first feed medium, wherein the first feed medium is a Si feed medium, in particular a Si gas according to the general formula SiH4-y Xy (X═[Cl, F, Br, J]und y=[0 . . . 4], and wherein a C feed medium source provides at least C, in particular the C feed medium source provided a second feed medium, wherein the second feed medium is a C feed medium, in particular natural gas, Methane, Ethan, Propane, Butane and/or Acetylene, and wherein a carrier gas medium source provides a third feed medium, wherein the third feed medium is a carrier gas, in particular H2.

Natural gas preferably defines a gas having multiple components, wherein the largest component is methane, in particular more than 50% [mass] is methane and preferably more than 70% [mass] is methane and highly preferably more than 90% [mass] is methane and most preferably more than 95% [mass] or more than 99% [mass] is methane.

Thus, the SiC production reactor respectively the CVD SiC apparatus is preferably also equipped with a feed gas unit respectively a medium supply unit for feeding the feed gas to the gas inlet unit. The feed gas unit respectively medium supply unit ensures the feed gases are heated to the right temperature and mixed in the right ratios before they are pumped into the CVD reactor respectively SiC production reactor, in particular SiC PVT source material production reactor. The feed gas unit respectively medium supply unit begins with pipes and pumps which transport feed gases from their respective sources, in particular storage tanks, to the proximity of the CVD reactor respectively SiC production reactor, in particular SiC PVT source material production reactor. Here the mass flowrate of preferably each feed gas is preferably controlled by a separate mass flow meter connected to an overall process control unit so that the correct ratio of the various feed gases can be achieved. The separate feed gases are then preferably mixed in a mixing unit, in particular of the medium supply unit, and pumped into the CVD reactor respectively SiC production reactor, in particular SiC PVT source material production reactor, via the gas inlet unit, in particular via multiple gas inlet ports of the gas inlet unit. Preferably the feed gas unit respectively medium supply unit is able to mix three feed gases including an Si-bearing gas such as STC and/or TCS, a C-bearing gas such as methane, and a carrier gas such as H. In another preferred embodiment of the invention, there is a feed gas that bears both Si and C such as MTCS and the feed gas unit mixes two gases instead of three, namely MTCS and H. It should be noted that STC, TCS, and MTCS are liquid at room temperature. As such a preheater can be required upstream of the gas inlet unit, in particular upstream of the feed gas unit respectively medium supply unit to first heat these feed liquids so that they become feed gases ready for mixing with the other feed gases.

Preferably the gases are mixed such that there is a 1:1 atomic ratio between Si and C. In some cases, it may be more preferably to mix the gases such that there is a different atomic ratio between the Si and the C. Sometimes it is desirable to maintain the deposition surfaces at the higher end of the deposition temperature range of 1400 to 1700° C. to achieve a faster deposition rate. However, in such a condition there is the possibility of excess C deposition in the SiC. This can be moderated by mixing the feed gases such that the Si:C ratio is higher than 1:1, preferably 1:1.1 or 1:1.2, or 1:1.3. Conversely, sometimes it is desirable to maintain the deposition surfaces at the lower end of the deposition temperature range to achieve a slow stress-free deposition. In such a condition there is the possibility of excess Si deposition in the SiC. This can be moderated by mixing the feed gases such that the Si:C ratio is lower than 1:1, preferably 1:0.9, or 1:0.8, or 1:0.7.

A further important consideration for the feed gas mixture is the atomic ratio of H to Si and C. Excess H can dilute the Si and C and reduce the deposition rate. It can also increase the volume of vent gases exiting the CVD reactor respectively SiC production reactor, in particular SiC PVT source material production reactor, and complicate any treatment and recycling of these vent gases. On the other hand, insufficient H can retard the chemical reaction chain that results in the deposition of SiC. The molar ratio of H2 to Si is preferably in the range of 2:1 to 10:1 and more preferably between 4:1 and 6:1.

According to a further embodiment of the present invention more or up to 4 or preferably 6 or 8 more or up to or highly preferably more or up to 16 or 32 or 64 or most preferably up to 128 or up to 256 SiC growth substrates can be arranged inside one SiC production reactor.

This embodiment is beneficial since the output of the SiC reactor can be significantly increased by adding additional SiC growth substrates.

A control unit for setting up a feed medium supply of the one feed-medium or the multiple feed-mediums into the process chamber is provided according to a further preferred embodiment of the present invention, wherein the control unit is configured to set up the feed medium supply between a minimum amount of feed medium supply [mass] per min. and a maximum amount of feed medium supply [mass] per min., wherein the minimum amount of feed medium supply [mass] per min. corresponds to a deposited minimum amount of Si [mass] and a minimum amount of C [mass] at a defined mass growth rate, wherein the defined mass growth rate is larger than 0.1 g per hour and per cm² of the SiC growth surface, wherein the maximum amount of feed medium supply per min is up to 30% [mass] or to 20% [mass] or up to 10% [mass] or up to 5% [mass] or up to 3% [mass] higher compared to the minimum amount of feed medium supply. This embodiment is beneficial since the feed medium supply can be controlled in dependency of the desired SiC conditions.

The control unit is according to a further preferred embodiment of the present invention configured to control the current flow through the SiC growth substrate/s to maintain the surface temperature of the SiC growth substrate/s or to set up the surface temperature of the deposited SiC. This embodiment is beneficial since the deposition of the SiC can be maintained by setting up the required temperature conditions.

The control unit is according to a further preferred embodiment of the present invention configured to control the current flow and the amount of feed medium supply for at least one hour and preferably for at least two hours or four hours or six hours to continuously deposit SiC with the defined surface growth rate and/or with a defined radial growth rate. This embodiment is beneficial since large SiC solids can be generated.

The control unit is according to a further preferred embodiment of the present invention a hardware arrangement configured to modify the current flow, wherein modification of the current flow within a first defined time span from the start of a production run are predefined. This embodiment is beneficial since the hardware can be adapted to a defined process, thus additional sensors are not necessary. The first-time span is preferably one hour or more than one hour or up to 60% of the duration of the production run or up to 80% of the duration of the production run or up to 90% of the duration of the production run or up to 100% of the duration of the production run. The hardware arrangement is preferably configured to modify the amount of feed medium supply, wherein modification of the amount of feed medium supply within a second defined time span from the start of a production run is predefined, wherein the second time span is one hour or more than one hour or up to 60% of the duration of the production run or up to 80% of the duration of the production run or up to 90% of the duration of the production run or up to 100% of the duration of the production run.

At least one sensor is according to a further preferred embodiment of the present invention provided, wherein the sensor is coupled with the control unit to provide sensor signals or sensor data to the control unit, wherein the control unit controls current flow and the amount of feed medium supply in dependency of the sensor signals or sensor data of the at least one sensor, wherein the at least one sensor is a temperature sensor for monitoring the surface temperature of at least one of the substrates. At least one temperature sensor is preferably a camera, in particular an IR camera, wherein preferably multiple temperature sensors are provided, wherein the number of temperature sensors corresponds to the number of SiC growth substrates, wherein per 10 SiC growth substrates at least 1, in particular 2 or 5 or 10 or 20, temperature sensor is provided or wherein per 5 SiC growth substrates at least 1, in particular 2 or 5 or 10 or 20, temperature sensor is provided or wherein per 2 SiC growth substrates at least 1, in particular 2 or 5 or 10 or 20, temperature sensor is provided, wherein the temperature sensor preferably outputs temperature sensor signals or temperature sensor data representing a measured temperature, in particular surface temperature. This embodiment is beneficial since the conditions inside the SiC production reactor can be immediately adjusted.

At least one substrate diameter measuring sensor is according to a further preferred embodiment of the present invention provided, wherein the substrate diameter measuring sensor is preferably an IR camera for determining substrate diameter growth, wherein the substrate diameter measuring sensor preferably outputs diameter measuring signals or diameter measuring data representing a measured substrate diameter or a variation of a measured substrate diameter and/or a resistance determination means for determining electrical resistance variation for determining substrate diameter growth, wherein the substrate diameter measuring sensor preferably outputs diameter measuring signals or diameter measuring data representing a measured substrate diameter or a variation of a measured substrate diameter. This embodiment is beneficial since in dependency of the measured data or values parameter like current flow or feed medium supply can be amended, in particular increased.

One valve or multiple vales is/are according to a further preferred embodiment of the present invention provided, wherein the one or multiple valves are configured to be actuated in dependency of the measured temperature, in particular in dependency of the temperature sensor signals or temperature sensor data and/or wherein the one or multiple valves are configured to be actuated in dependency of the measured substrate diameter, in particular in dependency of the diameter measuring signals or diameter measuring data. The one valve or the multiple valves can be part of the gas inlet unit. This embodiment is beneficial since a feed medium flow and/or vent gas flow can be controlled. Thus, the control unit is according to a further preferred embodiment of the present invention configured to increasing the electrical energizing of the at least one SiC growth substrate over time, in particular to heat a surface of the deposited SiC to a temperature between 1400° C. and 1700° C.

The power supply unit for providing the current is according to a further preferred embodiment of the present invention configured to provide current in dependency of the diameter measuring signals or diameter measuring data. This embodiment is beneficial since a feed medium flow and/or vent gas flow can be controlled.

Thus, the control unit is preferably configured to receive the temperature sensor signals or temperature sensor data and/or the diameter measuring signals or diameter measuring data and to process the temperature sensor signals or temperature sensor data and/or the diameter measuring signals or diameter measuring data and/or to control the one or multiple vales and/or the power supply unit.

The control unit is according to a further preferred embodiment of the present invention configured to control feed-medium flow and temperature of the surface of the deposited SiC for depositing SiC at the set deposition rate, in particular perpendicular deposition rate, for more than 2 hours, in particular for more or up to 3 hours or for more or up to 5 hours or for more or up to 8 hours or preferably for more or up to 10 hours or highly preferably for more or up to 15 hours or most preferably for more or up to 24 hours or up to 72 h or up to 100 h. This embodiment is beneficial since a large amount of SiC can be grown.

The base plate comprises according to a further preferred embodiment of the present invention at least one cooling element, in particular a base cooling element, for preventing heating the base plate above a defined temperature and/or the side wall section comprises at least one cooling element, in particular a bell jar cooling element, for preventing heating the side wall section above a defined temperature and/or the top wall section comprises at least one cooling element, in particular a bell jar cooling element, for preventing heating the top wall section above a defined temperature.

This embodiment is beneficial since the present invention discloses a CVD SiC apparatus for large volume commercial production of ultrapure bulk CVD SiC. The central equipment in the CVD SiC apparatus is the CVD unit respectively CVD reactor respectively SiC production reactor, in particular SiC PVT source material production reactor. The CVD reactor respectively SiC production reactor, in particular SiC PVT source material production reactor, preferably comprises a cooling element, in particular a double walled fluid, in particular water or oil, cooled lower housing respectively baseplate and a double walled liquid cooled upper housing respectively bell jar. The inner walls of the baseplate and in particular the bell jar are preferably made of materials with service temperatures compatible with the operating temperatures of the CVD reactor respectively SiC production reactor, in particular SiC PVT source material production reactor. In particular, the inner wall of the bell jar can be made from stainless steel. Preferably, this inner wall is additionally or alternatively coated with a reflective coating such as preferably silver or preferably gold to reflect back radiant energy and minimize heat losses and therefore electricity costs. The bell jar and/or the base plate are preferably made of stainless steel that withstands high temperatures. However, current high temperature steels with additions of chromium, nickel, cerium or yttrium only withstand temperatures up to 1300° C. (in air). As an example, the steel EN 1.4742 (X10CrAlSi18) is heat resistant up to temperatures of 1000° C. In another example the alloy steel EN 2.4816 (UNS N06600) withstands temperature of 1250° C., melts above 1370° C., however its tensile strength drops to less than 10% of its room temperature value at temperatures above 1100° C. Therefore, none of these steels can withstand the enormous temperature required for SiC absorption of more than 1300° C.

It is therefore beneficial to provide a cooling element to reduce the temperature of the bell jar and/or the base plate to a level that is acceptable for the usage of high temperature stainless steel.

The baseplate is preferably disposed with one or multiple fluid, in particular water or oil, cooled electrodes for providing electrical through-connections to the CVD reactor respectively SiC production reactor, in particular SiC PVT source material production reactor, for the purpose of resistively heating deposition substrates. The cooling element is according to a further preferred embodiment of the present invention an active cooling element.

The base plate and/or side wall section and/or top wall section comprises according to a further preferred embodiment of the present invention a cooling fluid guide unit for guiding a cooling fluid, wherein the cooling fluid guide unit is configured limit heating of the base plate and/or side wall section and/or top wall section to a temperature below 1300° C. This embodiment is beneficial since a metal, in particular steel bell jar can be provided. A steel bell jar is beneficial since it can be produced significant larger compared to quartz bell jars.

A base plate and/or side wall section and/or top wall section sensor unit is provided according to a further preferred embodiment of the present invention to detect temperature of the base plate and/or side wall section and/or top wall section and to output a temperature signal or temperature data, and a fluid forwarding unit is provided for forwarding the cooling fluid through the fluid guide unit. This embodiment is beneficial since a continuous cooling can take place without loss or contamination of the cooling fluid and/or the process chamber.

The fluid forwarding unit is according to a further preferred embodiment of the present invention configured to be operated in dependency of the temperature signal or temperature data provided by the base plate and/or side wall section and/or top wall section sensor unit. This embodiment is beneficial since metal impurities can be avoided in case the bell jar and/or base plate are operated at temperatures below 1000° C. and preferably below 800° C. and highly preferably below 400° C. respectively in case the bell jar and/or base plate are cooled to temperatures below 1000° C. and preferably below 800° C. and highly preferably below 400° C.

The cooling fluid is according to a further preferred embodiment of the present invention oil or water, wherein the water preferably comprises at least one additive, in particular corrosion inhibiter/s and/or antifouling agent/s (biocides). This embodiment is beneficial since the cooling liquid can be modified to avoid defects or contaminations of the SiC production reactor.

The cooling element is according to a further preferred embodiment of the present invention a passive cooling element. This embodiment is beneficial since a passive cooling element does not require constant monitoring.

The cooling element is according to a further preferred embodiment of the present invention at least partially formed by a polished steel surface of the base plate, the side wall section and/or the top wall section. The cooling element is according to a further preferred embodiment of the present invention a coating, wherein the coating is formed above the polished steel surface and wherein the coating is configured to reflect heat. The coating is according to a further preferred embodiment of the present invention a metal coating or a comprises metal, in particular silver or gold or chrome, or alloy coating, in particular a CuNi alloy. The emissivity of the polished steel surface and/or of the coating is according to a further preferred embodiment of the present invention below 0.3, in particular below 0.1 or below 0.03. This embodiment is beneficial since due to the polished surface and/or the coating a high amount of heat radiation can be reflected back to the SiC growth surface.

Thus, at least one section of the bell jar surface and/or at least one section of the base unit surface comprises according to a further preferred embodiment of the present invention a coating, in particular a reflective coating, wherein the section of the bell jar surface and/or the section of the base unit surface delimits the reaction space, wherein the coating is a metal coating, in particular comprises or consists of gold, silver, aluminum and/or platinum and/or wherein the coating is configured to reflect at least 2% or at least 5% or at least 10% or at least 20% of the radiant energy radiated during one production run onto the coating.

The base plate comprises according to a further preferred embodiment of the present invention at least one active cooling element and one passive cooling element for preventing heating the base plate above a defined temperature and/or the side wall section comprises at least one active cooling element and one passive cooling element for preventing heating the side wall section above a defined temperature and/or the top wall section comprises at least one active cooling element and one passive cooling element for preventing heating the top wall section above a defined temperature.

The side wall section and the top wall section are formed according to a further preferred embodiment of the present invention by a bell jar, wherein the bell jar is preferably movable with respect to the base plate. More than 50% [mass] of the side wall section and/or more than 50% [mass] of the top wall section and/or more than 50% [mass] of base plate is according to a further preferred embodiment of the present invention made of metal, in particular steel. This embodiment is beneficial since large steel bell jars can be manufactured causing a significant increase in process chamber volume and therefore in potential SiC material. Thus a bell jar is preferably provided, wherein the bell jar comprises according to a further preferred embodiment of the present invention a contact region for forming an interface with the base unit, wherein the interface is sealed against leakage of gaseous species, wherein the bell jar comprises a bell jar cooling unit, wherein the bell jar cooling element forms at least one channel or trench or recess for holding or guiding a bell jar cooling liquid, wherein the bell jar cooling element is configured to cool at least one section of the bell jar and preferably the entire bell jar below a defined temperature respectively to remove a defined amount of heat per min during the production run. The bell jar cooling element and/or base plate cooling element is preferably controlled by the control unit. Additionally, or alternatively the bell jar cooling element and/or base cooling element are coupled with each other to form one major cooling unit.

The base unit comprises according to a further preferred embodiment of the present invention at least one base cooling element for cooling the base unit, wherein the base cooling element forms at least one channel or trench or recess for holding or guiding a base cooling liquid. The base cooling element is according to a further preferred embodiment of the present invention arranged in an area of at least one of the first metal electrodes and preferably also in an area of at least one second metal electrode, wherein the base cooling element is configured to cool the base unit, in particular a surface of the base unit, which is arranged inside the reactor, in the area of at least one of the first metal electrodes and preferably also in the area of the at least one second metal electrode below a defined temperature respectively to remove a defined amount of heat per min from the base unit or the base cooling element is configured to cool the entire base unit during a complete production run below a defined temperature respectively to remove a defined amount of heat per min during the production run. This embodiment is beneficial since electrodes can be operated with high current without damaging the SiC reactor.

The first metal electrode and the SiC growth substrate are according to a further preferred embodiment of the present invention connected with each other via a first graphite chuck and/or the second metal electrode and the SiC growth substrate are connected with each other via a second graphite chuck. This embodiment is beneficial since the current can be introduced in a homogeneous manner into the SiC growth substrate. The first graphite chuck and/or the second graphite chuck is/are according to a further preferred embodiment of the present invention mounted to the base unit.

The first metal electrodes and second metal electrodes are according to a further preferred embodiment of the present invention sealed from the reaction chamber to avoid metal species contamination of the reaction chamber by metal species of the first metal electrodes and second metal electrodes, the first metal electrodes and second metal electrodes preferably enter the base unit from a first side of the base unit, wherein the first metal electrodes and second metal electrodes preferably extend inside the base unit to another side of the base unit, wherein the other side of the base unit is opposite to the first side, wherein the first metal electrodes and preferably the second metal electrodes extend inside the base unit to a sealing level below a process chamber surface of the base unit, wherein the process chamber surface is formed on the other side of the base unit. This embodiment is beneficial since contaminations of the reaction space can be avoided.

A sealing wall member is according to a further preferred embodiment of the present invention formed between the sealing level and the process chamber surface, wherein the sealing wall member separates the SiC growth substrate from the first metal electrode and preferably from the second metal electrode. This embodiment is beneficial since short circuiting can be prevented.

The control unit is according to a further preferred embodiment of the present invention configured to control the current flow through the SiC growth substrate/s to maintain the surface temperature of the SiC growth substrate/s or to set up the surface temperature of the deposited SiC, wherein the control unit is coupled to a power supply unit for providing the current, wherein the power supply unit is configured to receive power supply data or power supply signals provided by the control unit; and/or the feed medium supply of the one feed-medium or the multiple feed-mediums into the process chamber, wherein the control unit is coupled to a medium supply unit for providing the one feed-medium or the multiple feed-mediums to the gas inlet unit, wherein the medium supply unit is configured to receive medium supply data or medium supply signals provided by the control unit; and/or a cooling of the base unit, wherein the control unit is coupled to the base cooling element for cooling the base unit, wherein the base cooling element is configured to receive base cooling data or base cooling signals provided by the control unit, and/or a cooling of the bell jar, wherein the control unit is coupled to the bell jar cooling element for cooling the bell jar, wherein the bell jar cooling element is configured to receive bell jar cooling data or bell jar cooling signals provided by the control unit, and/or the control unit is configured to set up a deposition rate, in particular perpendicular deposition rate, of more than 200 μm/h, in particular by controlling at least the power supply unit and the medium supply unit. This embodiment is beneficial since the control unit can control multiple parameters, thus the output can be increased by operating the heating, feeding and cooling units at the same time.

The medium supply unit is according to a further preferred embodiment of the present invention configured to feed the one feed-medium or multiple feed-mediums at a pressure of more than 1 bar, in particular of more than 1.2 bar or preferably of more than 1.5 bar or highly preferably of more than 2 bar or 3 bar or 4 bar or 5 bar respectively of up to 10 bar or up to 20 bar, into the process chamber. Additionally, or alternatively the medium supply unit is according to a further preferred embodiment of the present invention configured to feed the one feed-medium or multiple feed-mediums and a carrier gas at a pressure of more than 1 bar, in particular of more than 1.2 bar or 1.5 bar or 2 bar or 3 bar or 4 bar or 5 bar, into the process chamber. This embodiment is beneficial since the material density is high inside the process chamber, thus a high amount of Si and C material reaches the SiC growth surface and therefore causes an enhanced SiC growth.

The above-mentioned object is also solved by a usage of a wafer produced according to a herein disclosed method for the production of multiple crack-free workpieces as carrier wafer for holding a monocrystalline SiC wafer, wherein the monocrystalline SiC wafer has a height of less than 50 μm. This solution is beneficial since the carrier wafer is produced with very low costs.

The above-mentioned object can also be solved by a carrier wafer, in particular produced according to a herein disclosed method for the production of multiple crack-free workpieces, wherein the predetermined pieces are preferably wafers, wherein each wafer has a height of more than 200 μm, in particular of more than 250 μm and preferably of up to 1000 μm or of more than 1000 μm and/or wherein a diameter of the main body has a minimum length of 100 mm and preferably a minimum length of 150 mm and particular preferably a minimum length of 250 mm and most preferably a minimum or maximum length of 300 mm, wherein the carrier wafer has a diameter of at least 7.5 cm, a height of at least 200 μm and wherein the carrier wafer is predominantly formed by a 3C crystal structure. This embodiment is beneficial since the carrier wafer can have a large size and therefore allow bonding it with monocrystalline wafers of the same size.

The 3C crystal structure is according to a preferred embodiment of the present invention Nitrogen doped, in particular more than 2000 ppba nitrogen, and comprises an electric resistivity <0.01 Ohm cm. This embodiment is beneficial since preferred mechanical and electrical properties can be provided to allow usage of the carrier wafer in a wide range of different use cases.

The grain orientation of the 3C crystal structure varies according to a preferred embodiment of the present invention between 0° and 80°. This embodiment is beneficial since the SiC piece respectively the carrier wafer is removed from the grown crust respectively from one quarter of the grown crust.

The grain orientation of the 3C crystal structure varies according to a preferred embodiment of the present invention more than 80°. This embodiment is beneficial since the SiC piece respectively the carrier wafer is removed from at least two quarters of the grown crust and preferably also from the center of the physical structure.

The above-mentioned object can also be solved by a crack-free SiC piece, in particular produced according to a herein disclosed method for producing at least one crack-free SiC piece. The crack-free SiC piece is predominantly formed by a 3C crystal structure, wherein the dimensions of the crack-free SiC piece are at least 2 cm×2 cm×1 cm. This embodiment is beneficial since the crack-free piece can be used to produce multiple or different or large elements respectively devices.

The grain orientation of the 3C crystal structure varies according to a preferred embodiment of the present invention between 0° and 80° and preferably below 70° and most preferably below 60° or alternatively above 90° and preferably above 120° or particular preferably above 160° and most preferably above 220°. This embodiment is beneficial since the SiC piece or SiC pieces can be removed in dependency of the required grain orientation.

The density of the crack-free SiC piece is according to a preferred embodiment of the present invention more than 3 g/cm³. This embodiment is beneficial since the mechanical and/or electrical and/or chemical properties of the crack-free SiC piece are enhanced. Due to better mechanical stability carrier wafers can be thinner and therefore allow less energy consuming processing.

The above-mentioned object can also be solved by a method for producing predefined PVT source material pieces for filling a source material receiving space of PVT reactor. The PVT source material is SiC, wherein the SiC predominantly has a 3C crystal structure. The method preferably comprises at least the steps: Providing a CVD reactor, wherein the CVD reactor comprises at least one SiC growth substrate, wherein the at least one SiC growth substrate comprises a main body, a first power connection and a second power connection, wherein the main body has a main body length, wherein the main body length extends between the first power connection and the second power connection, wherein the first power connection is configured to conduct power into the main body for heating the main body and wherein the second power connection is configured to conduct electric power conducted via the first power connection into the main body out of the main body, wherein the main body forms a physical structure, wherein the physical structure forms a deposition surface for deposition of SiC. The method preferably also comprises the step of growing a SiC solid by depositing SiC on the physical structure in the CVD reactor, wherein the at least one SiC piece is part of the SiC solid, wherein the deposited SiC has a minimal thickness of at least 1 cm. The method preferably also comprises the step of removing the at least one SiC piece from the SiC solid, wherein the at least one SiC piece has a cross-sectional size of at least 4 cm² and preferably of at least 8 cm² and highly preferably of at least 12 cm² and a thickness of at least 0, 1 cm and preferably of at least 1 cm and highly preferably of at least 2 cm, wherein the at least one SiC piece has a shape configured to fill at least 75% of a volume of a defined source material receiving space of a defined PVT reactor or wherein the at least one SiC piece has a shape configured to fill together with at least one further SiC piece having the same shape at least 75% of a volume of a defined source material receiving space of a defined PVT reactor. This solution is beneficial since due to the block shape of the SiC piece/s more mass of SiC can be provided compared to powder as source material within a defined receiving space of a PVT reactor and therefore allows larger growth of a monocrystalline SiC crystal during one production run.

The above-mentioned object can also be solved by a SiC piece, in particular produced according to a method for producing predefined PVT source material pieces for filling a source material receiving space of a PVT reactor, wherein the SiC piece is predominantly formed by a 3C crystal structure, wherein the dimensions of the crack-free SiC piece are at least 2 cm×2 cm×1 cm.

The grain orientation of the 3C crystal structure varies according to a preferred embodiment of the present invention between 0° and 80° and preferably below 70° and most preferably below 60° or alternatively above 90° and preferably above 120° or particular preferably above 160° and most preferably above 220°. This embodiment is beneficial since the SiC piece or SiC pieces can be removed in dependency of the required grain orientation.

The density of the SiC piece is according to a preferred embodiment of the present invention more than 3 g/cm³. This embodiment is beneficial since the mechanical and/or electrical and/or chemical properties of the crack-free SiC piece are enhanced. Due to better mechanical stability carrier wafers can be thinner and therefore allow less energy consuming processing.

The above-mentioned object can also be solved by a method for producing SiC material. Said method preferably comprises the steps: Providing at least one furnace apparatus for growing SiC crystals, wherein the furnace apparatus comprises a furnace unit, wherein the furnace unit comprises a furnace housing with an outer surface and an inner surface, at least one crucible unit, wherein the crucible unit is arranged inside the furnace housing, wherein the crucible unit comprises a crucible housing, wherein the housing has an outer surface and an inner surface, wherein the inner surface at least partially defines a crucible volume, wherein a receiving space for receiving a solid SiC source material is arranged or formed inside the crucible volume, wherein a seed holder unit for holding a defined seed wafer is arranged inside the crucible volume, wherein the furnace housing inner wall and the crucible housing outer wall define a furnace volume, at least one heating unit for heating the source material, wherein the receiving space for receiving the source material is at least in parts arranged below the seed holder unit, Arranging source material in the receiving space within the crucible housing, wherein the source material is made of exactly one SiC piece, wherein the source material fills at least 75% and preferably at least 90% and highly preferably at least 95% and most preferably at least 98% of a volume of the receiving space or wherein the source material is made of multiple SiC pieces preferably produced according to a herein disclosed method for producing predefined PVT source material pieces for filling a source material receiving space of a PVT reactor, wherein at least a plurality and preferably all of the multiple SiC pieces have the same shape, wherein the source material fills at least 75% and preferably at least 90% and highly preferably at least 95% and most preferably at least 98% of a volume of the receiving space, Heating the source material, Feeding a carrier gas into the crucible housing. This solution is beneficial since larger monocrystalline SiC crystals can be produced during one run, since more mass of SiC can be arranged inside the receiving space compared to prior art source material.

Document PCT/EP2021/082340 discloses a furnace apparatus which can be used to carry out the before mentioned method according to the present invention. The subject-matter of PCT/EP2021/082340 is entirely incorporated into the present subject-matter by reference.

Further advantages, objectives and features of the present invention are explained with reference to the following description of accompanying drawings, in which the device(s) according to the invention are shown by way of example. Components or elements of the device or reactor or system or SiC growth substrate according to the invention, which at least substantially correspond in the figures with respect to their function, can be marked with the same reference signs, whereby these components or elements do not have to be numbered or explained in all figures.

Individual or all representations of the figures described in the following are preferably to be regarded as construction drawings, i.e. the dimensions, proportions, functional relationships and/or arrangements resulting from the figure or figures preferably correspond exactly or preferably substantially to those of the device according to the invention or the product according to the invention or the method according to the invention.

### BRIEF DESCRIPTION OF THE DRAWINGS

FIG. 1 schematically shows a first example of a CVD reactor according to the present invention,

FIG. 2 schematically shows a second example of a CVD reactor according to the present invention,

FIG. 3 schematically shows a third example of a CVD reactor according to the present invention,

FIG. 4a schematically shows a CVD reactor before production run and

FIG. 4b schematically shows a CVD reactor after a production run,

FIG. 5 schematically shows the production of SiC pieces and SiC carrier wafer and composite wafers,

FIG. 6 shows a PVT reactor, which can be operated with source material produced according to the invention,

FIG. 7 shows a PVT reactor filled with large solid SiC source material pieces,

FIG. 8a shows positions of SiC pieces inside the entire CVD SiC structure,

FIG. 8b shows positions of SiC pieces inside the entire CVD SiC structure,

FIG. 9a shows a step of the production of a composite wafer according to the present invention;

FIG. 9b shows a step of the production of a composite wafer according to the present invention;

FIG. 9c shows a step of the production of a composite wafer according to the present invention;

FIG. 9d shows a step of the production of a composite wafer according to the present invention;

FIG. 9e further shows an optional further step of growing an epi-layer on the composite wafer;

FIG. 10a shows a similar method compared to FIGS. 9a-d, wherein the thin substrate layer is thicker compared to FIGS. 9a-d to provide a composite wafer that can be used for device production without an epi-layer production step;

FIG. 10b shows a similar method compared to FIGS. 9a-d, wherein the thin substrate layer is thicker compared to FIGS. 9a-d to provide a composite wafer that can be used for device production without an epi-layer production step;

FIG. 10c shows a similar method compared to FIGS. 9a-d, wherein the thin substrate layer is thicker compared to FIGS. 9a-d to provide a composite wafer that can be used for device production without an epi-layer production step;

FIG. 10d shows a similar method compared to FIGS. 9a-d, wherein the thin substrate layer is thicker compared to FIGS. 9a-d to provide a composite wafer that can be used for device production without an epi-layer production step;

FIG. 11 shows a high-resolution photo of the crystal structure of the second substrate,

FIG. 12 shows FIG. 11 with modifications indicating the main growth direction (radial direction) as well as multiple orientations of large crystallites;

FIG. 13a shows a conventional growth of a carrier wafer;

FIG. 13b shows a schematic illustration of the growth direction in specific sections;

FIG. 13c shows a schematic illustration of the growth direction in specific sections;

FIG. 13d shows a schematic illustration of the growth direction in specific sections;

FIG. 14 shows an enlarged section of FIG. 3, wherein the length direction and boundary of one crystallite is highlighted;

FIG. 15a shows line shaped elements generated during the growth process.

FIG. 15b shows line shaped elements generated during the growth process.

FIG. 16 shows an example of the CVD SiC apparatus according to the present invention, wherein also a vent gas treatment unit is shown,

FIG. 17 shows an example of the CVD SiC apparatus according to the present invention, wherein also a vent gas recovery unit is shown,

FIG. 18 shows an example of a feed gas unit according to the present invention with three gases,

FIG. 19 shows an example of the feed gas unit according to the present invention with two gases,

FIG. 20 shows an example of the vent gas treatment unit according to the present invention,

FIG. 21 shows an example of the vent gas recycling unit according to the present invention,

FIG. 22 shows an example of a preferred system setup according to the invention,

FIG. 23 shows a schematic example of a comminution unit and

FIG. 24 shows a schematic example of an etching unit,

FIG. 25a shows the orientation of crystallites inside different SiC growth substrates,

FIG. 25b shows the orientation of crystallites inside different SiC growth substrates,

FIG. 25c shows the orientation of crystallites inside different SiC growth substrates,

FIG. 26a shows the orientation of crystallites in an inner section and in an outer section of a SiC solid,

FIG. 26b shows the orientation of crystallites in an inner section and in an outer section of a SiC solid,

FIG. 27 shows a further example of a grown SiC solid.

### DETAILED DESCRIPTION

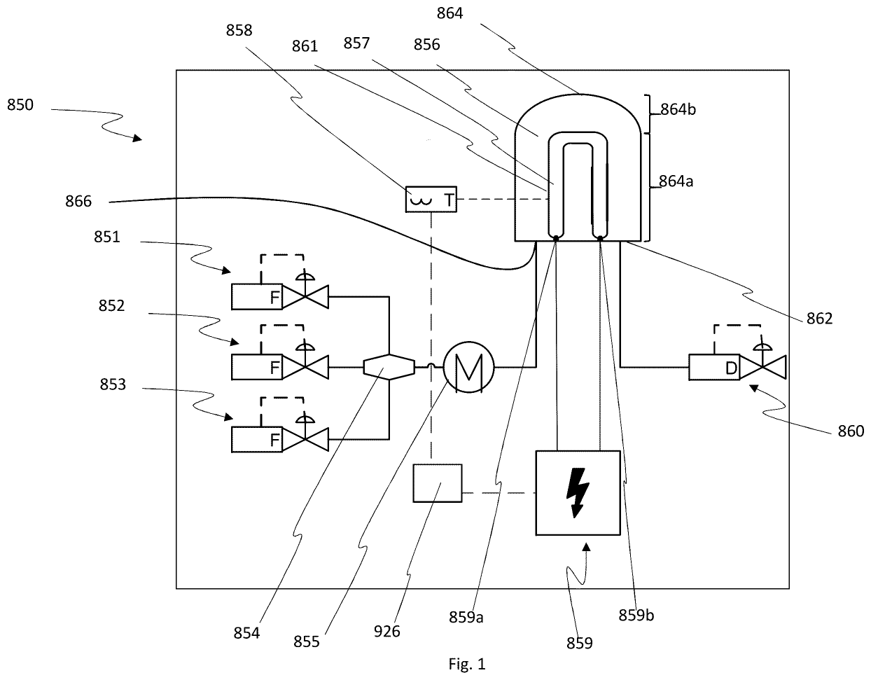

FIG. 1 shows an example of a manufacturing device 850 for producing SiC material, in particular 3C—SiC material. This device 850 respectively reactor comprises a first feeding device 851, a second feeding device 852 and a third feeding device 853. The first feed device 851 is preferably designed as a first mass flow controller, in particular for controlling the mass flow of a first source fluid, in particular a first source liquid or a first source gas, wherein the first source fluid preferably comprises Si, in particular e.g. silanes/chlorosilanes of the general composition SiH4-mClm or organochlorosilanes of the general composition SiR4-mClm (where R=hydrogen, hydrocarbon or chlorohydrocarbon). The second feed device 852 is preferably designed as a second mass flow controller, in particular for controlling the mass flow of a second source fluid, in particular a second source liquid or a second source gas, wherein the second source fluid preferably comprises C, e.g. hydrocarbons or chlorohydrocarbons, preferably with a boiling point <100° C., particularly preferably methane. The third feed device 853 is preferably designed as a third mass flow controller, in particular for controlling the mass flow of a carrier fluid, in particular a carrier gas, wherein the carrier fluid or carrier gas preferably comprises H or H2, respectively, or mixtures of hydrogen and inert gases.

The reference sign 854 indicates a mixing device or a mixer by which the source fluids and/or the carrier fluid can be mixed with one another, in particular in predetermined ratios. The reference sign 855 indicates an evaporator device or an evaporator by which the fluid mixture which can be supplied from the mixing device 854 to the evaporator device 855 can be evaporated.

The evaporated fluid mixture is then fed to a process chamber 856 or a separator vessel, which is designed as a pressure vessel. At least one deposition element 857 respectively SiC growth substrate and preferably several deposition elements 857 are arranged in the process chamber 856, wherein Si and C are deposited from the vaporized fluid mixture at the deposition element 857 and SiC is formed.

The reference sign 858 indicates a temperature measuring device, which is preferably provided for determining the surface temperature of the deposition element 857 and is preferably connected to a control device (not shown) by data and/or signal technology.

The reference sign 859 indicates an energy source, in particular for introducing electrical energy into the separating element 857 for heating the separating element. The energy source 859 is thereby preferably also connected to the control device in terms of signals and/or data. Preferably, the control device controls the energy supply, in particular power supply, through the deposition element 857 depending on the measurement signals and/or measurement data output by the temperature measurement device 858. The energy source 859 preferably provides alternating current.

Furthermore, a pressure holding device is indicated by the reference sign 860. The pressure holding device 860 can preferably be implemented by a pressure-regulated valve or the working pressure of a downstream exhaust gas treatment system.

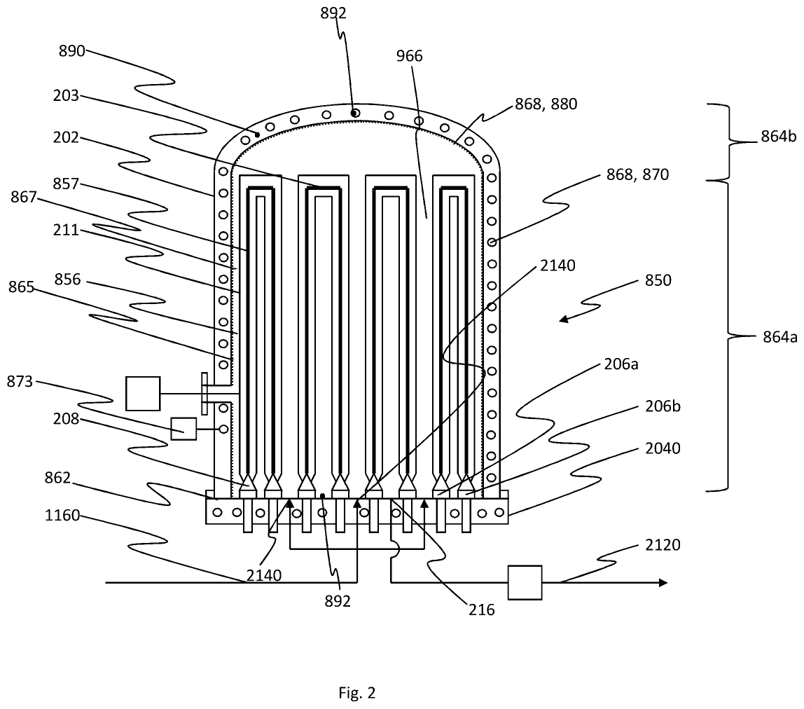

FIG. 2 shows the CVD unit respectively CVD reactor respectively SiC production reactor, in particular SiC PVT source material production reactor, 850 of one preferred embodiment of the present invention. The CVD unit respectively CVD reactor respectively SiC production reactor, in particular SiC PVT source material production reactor, 850 preferably comprises a fluid, in particular oil or water, cooled steel upper housing 202 or bell jar which seals, in particular by means of one or multiple gaskets, against a preferably fluid, in particular oil or water, cooled lower housing 2040 or base plate creating a deposition chamber respectively process chamber 856 which can be pressurized preferably to at least 6 bar, in particular to a pressure between 2 bar and 15 bar. The feed gas mixture 1160 preferably enters the deposition chamber respectively process chamber 856 through a plurality of feed gas inlets 2140 and the vent gas 2120 preferably exists through the gas outlet unit respectively vent gas outlet 216. Inside the deposition chamber preferably a plurality of resistively self-heated deposition substrates respectively SiC growth substrate 857 preferably made of graphite or silicon carbide or metal are provided which are connected to chucks 208 which are preferably made of graphite. The chucks 208 are in turn connected to water cooled electrodes 206 preferably made of copper which pass through the baseplate so that they can be connected to an external source of electrical power. The deposition substrates respectively SiC growth substrate 857 are preferably arranged as pairs via cross members 203 to complete an electrical circuit for resistive heating.

The purpose of the chucks 208 is to create a temperature gradient between the electrodes 206 which are in a temperature range of preferably between 850° C. and 400° C. and the deposition substrate respectively SiC growth substrate 857 which is preferably in temperature range of 1400° C. and 1700° C. and preferably between 1400° C. and 1650° C. and most preferably between 1400° C. and 1600° C. The chuck 208 preferably achieves this by having a continuously reducing current flow cross section area resulting in higher and higher resistive heating. Thus, the chuck 208 preferably has a conical shape. In this manner the starting point for the deposition of CVD SiC crust 211 can be controlled preferably to a point for example midway up the chuck 208 such that the final deposition substrate respectively SiC growth substrate 857 with the deposited CVD SiC crust 211 has a structurally strong connection at the bottom and will not break or fall over.

The plurality of feed gas inlets 2140 is preferably designed to create a turbulent gas flow pattern inside the deposition chamber respectively process chamber 856 so as to maximize the contact of fresh feed gas with the surface of the CVD SiC crust 211 being deposited on the deposition substrates respectively SiC growth substrate 857. Additionally, or alternatively it is possible to provide a gas turbulence generating apparatus, in particular inside the process chamber 856. The gas turbulence generating apparatus can be a ventilator or circulator pump. This ensures that a minimum excess of feed gas mixture 1160 is used to produce a given quantity of CVD SiC crust 211. The vent gas 2120 which contains unreacted feed gas mixture as well as altered Si-bearing gas and HCl gas is forced out of the deposition chamber respectively process chamber 856 through the vent gas outlet by the incoming feed gas mixture 1160.

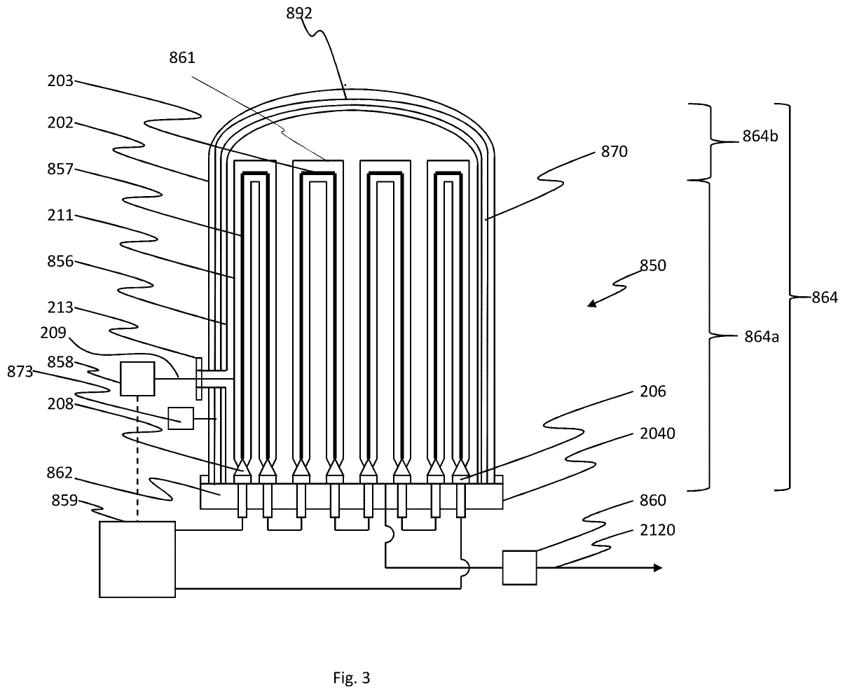

FIG. 3 shows examples of the temperature and pressure control methods for the CVD unit. A temperature control unit respectively temperature measuring device 858 is positioned such that to measure the temperature of the CVD SiC crust 211 along the temperature measurement path 209 preferably through the sight glass 213 which is preferably fluid, in particular oil or water, cooled. The temperature control unit respectively temperature measuring device 858 preferably measures the temperature of the surface of the CVD SiC crust and sends a signal to the power supply unit respectively energy source 859 to increase or decrease power to the deposition substrates respectively SiC growth substrate 857 depending on whether the temperature is below or above the desired temperature respectively. The power supply unit respectively energy source 859 is wired to the fluid, in particular oil or water-cooled electrodes 206 and adjusts voltage and/or current to the fluid, in particular oil or water, cooled electrodes 206 accordingly. The energy source 859 preferably provides alternating current. The deposition substrates respectively SiC growth substrate 857 are wired in pairs and have connecting cross members at the top so as to form a complete electrical circuit for the flow of current.

Pressure inside the deposition chamber respectively process chamber 856 is adjusted by means of a pressure control unit respectively pressure maintaining device 860 which senses the pressure and decreases or increases the flowrate of vent gas 2120 from the deposition chamber respectively process chamber 856.

Thus, as shown in FIGS. 1, 2 and 3 the SiC production reactor 850 according to the present invention preferably comprises at least a process chamber 856, wherein the process chamber 856 is at least surrounded by a base plate 862, a side wall section 864a and a top wall section 864b. The reactor 850 preferably comprises a gas inlet unit 866 for feeding one feed-medium or multiple feed-mediums into a reaction space of the process chamber 856 for generating a source medium inside the process chamber 856. The base plate 862 preferably comprises at least one cooling element 868, 870, 880, in particular a base cooling element, for preventing heating the base plate 862 above a defined temperature and/or wherein the side wall section 864a preferably comprises at least one cooling element 868, 870, 880, in particular a bell jar cooling element, for preventing heating the side wall section 864a above a defined temperature and/or wherein the top wall section 864b preferably comprises at least one cooling element 868, 870, 880, in particular a bell jar cooling element, for preventing heating the top wall section 864b above a defined temperature. The cooling element 868 can be an active cooling element 870, thus the base plate 862 and/or side wall section 864a and/or top wall section 864b preferably comprises a cooling fluid guide unit 872, 874, 876 for guiding a cooling fluid, wherein the cooling fluid guide unit 872, 874, 876 is configured limit heating of the base plate 862 and/or side wall section 864a and/or top wall section 864b to a temperature below 1000° C. It is additionally possible that a base plate and/or side wall section and/or top wall section sensor unit 890 is provided to detect the temperature of the base plate 862 and/or side wall section 864a and/or top wall section 864b and to output a temperature signal or temperature data. The at least one base plate and/or side wall section and/or top wall section sensor unit 890 can be arranged as part of a surface or on a surface inside the process chamber, in particular on a surface of the base plate 862 or the side wall section 864a or the top wall section 864b. Additionally or alternatively it is possible to provide one or more base plate and/or side wall section and/or top wall section sensor unit/s 890 inside the base plate 862 or inside the side wall section 864a or inside the top wall section 864b. Additionally or alternatively it is possible to provide a cooling fluid temperature sensor 820 to detect the temperature of the cooling fluid guided through the cooling fluid guide unit 870. A fluid forwarding unit 873 can be provided for forwarding the cooling fluid through the fluid guide unit 872, 874, 876, wherein the fluid forwarding unit 873 is preferably configured to be operated in dependency of the temperature signal or temperature data provided by the base plate and/or side wall section and/or top wall section sensor unit 890 and/or cooling fluid temperature sensor 892. The cooling fluid can be oil or preferably water, wherein the water preferably comprises at least one additive, in particular corrosion inhibiter/s and/or antifouling agent/s (biocides).

Additionally, or alternatively the cooling element 868 is a passive cooling element 880. Thus, the cooling element 868 can be at least partially formed by a polished steel surface 865 of the base plate 862, the side wall section 864a and/or the top wall section 864b, preferably by a polished steel surface 865 of the base plate 862, the side wall section 864a and the top wall section 864b. The passive cooling element 868 can be a coating 867, wherein the coating 867 is preferably formed above the polished steel surface 865 and wherein the coating 867 is configured to reflect heat. The coating 867 can be a metal coating or a comprises metal, in particular silver or gold or chrome, or can be an alloy coating, in particular a CuNi alloy. The emissivity of the polished steel surface 865 and/or of the coating 867 is 0.3, in particular below 0.1 and highly preferably below 0.03.

The base plate 862 can comprise at least one active cooling element 870 and one passive cooling element 880 for preventing heating the base plate 862 above a defined temperature and/or the side wall section 864a can comprise at least one active cooling element 870 and one passive cooling element 880 for preventing heating the side wall section 864a above a defined temperature and/or the top wall section 864b can comprises at least one active cooling element 870 and one passive cooling element 880 for preventing heating the top wall section 864b above a defined temperature.

The side wall section 864a and the top wall section 864b are preferably formed by a bell jar 864, wherein the bell jar 864. The bell jar 864 is preferably movable with respect to the base plate 862.

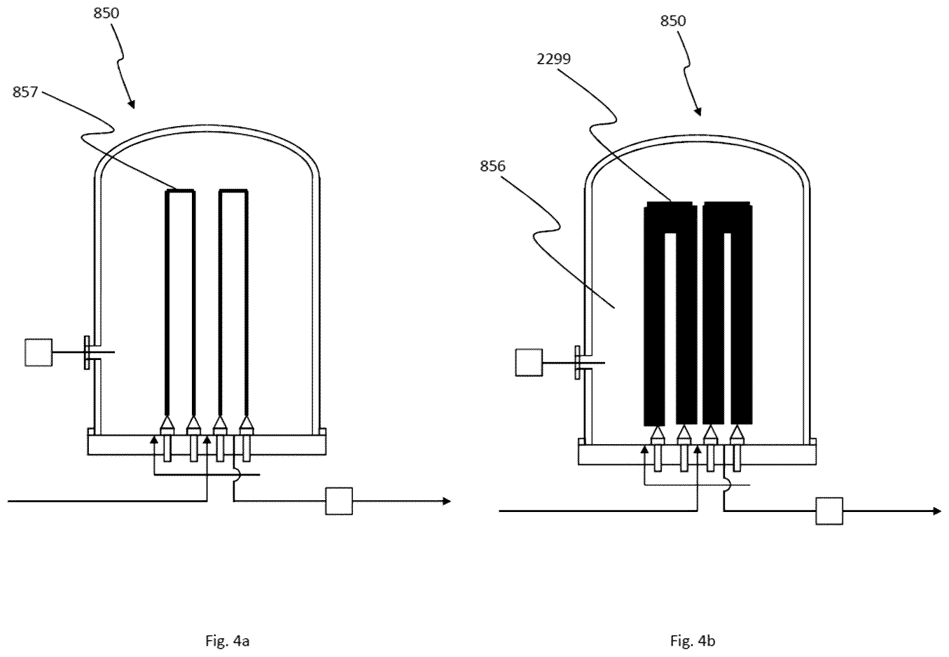

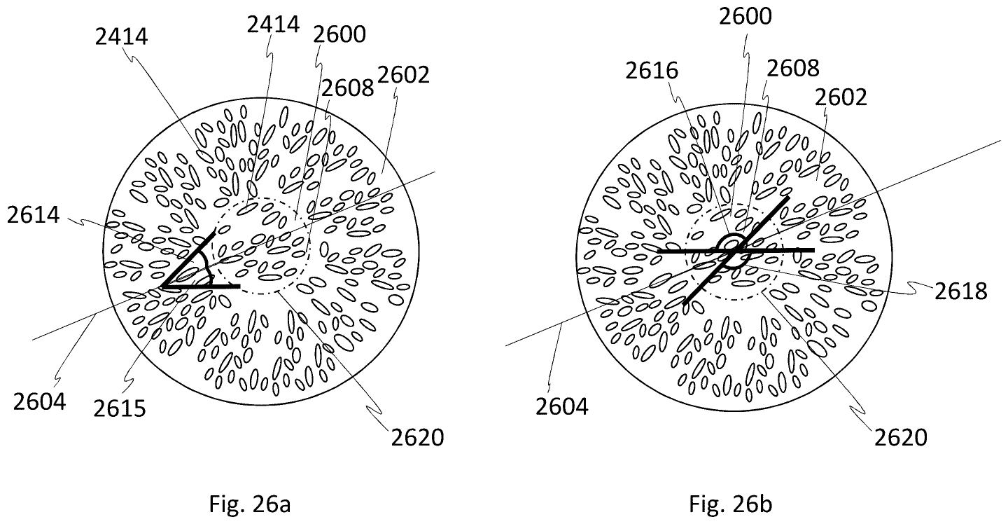

FIG. 4a shows an example of the reactor 850 according to any of FIGS. 1 to 3, wherein the reactor 850 comprises at least one SiC growth substrate 857, in particular two or more than two SiC growth substrates 857. Said SiC growth substrate/s 857 is/are preferably made of SiC, in particular polycrystalline 3C SiC. The reactor 850 can preferably comprise an optional nitrogen inlet for feeding nitrogen into the process chamber 856, for doping the SiC solid, in particular the SiC crust or the “outer section 2602” (cf. FIG. 26a/b), during growth

FIG. 4b shows the reactor of FIG. 4a after a production run and after cooling down. Reference number 2299 refers to the entire structure comprising the SiC growth substrate 857 and the grown crust 211.

The CVD reactors according to FIGS. 1 to 4a are used to grow SiC material, in particular SiC solid/s, for the production of SiC carrier wafer 2322. Such a SiC carrier wafer 2322 preferably has a height between 200 μm and 500 μm and a diameter of at least 7.5 cm and preferably of at least 10 cm and most preferably of at least 12 cm or 15 cm. Additionally or alternatively the SiC material, in particular the SiC solid, in particular the SiC carrier wafer 2322, is predominantly formed by a 3C crystal structure, wherein the SiC carrier wafer 2322 is preferably doped, in particular Nitrogen doped, in particular more than 2000 ppba nitrogen but preferably less than 1019 and particular preferably less than 1018 and most preferably less than 1017 Nitrogen atoms/cm³. The SiC carrier wafer 2322 preferably has an electric resistivity <0.03 Ohm cm, preferably <0.02 Ohm cm and most preferably <0.01 Ohm cm.

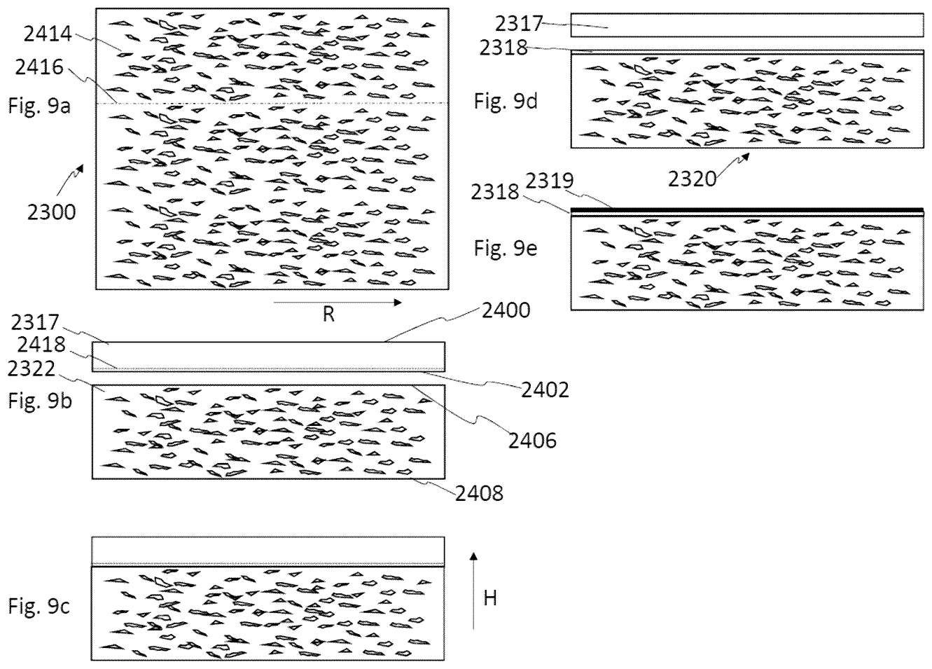

The SiC carrier wafer 2322 preferably comprises at least one or exactly one inner section 2600 (cf. FIG. 26a or 26b), in particular one central inner section, and wherein the SiC carrier wafer 2322 preferably comprises an outer section 2602 (cf. FIG. 26a or 26b), wherein the outer section 2602 surrounds the inner section 2600. The inner section consists of a part of a SiC growth substrate 857, wherein the inner section 2600 is preferably predominantly formed by a 3C crystal structure. The outer section 2602 is preferably predominantly formed by a 3C crystal structure and comprises crystallites 2414 (cf. FIG. 9a-10d and FIG. 26a/b) extending in length direction of the individual crystallite more than 5 μm, in particular more than 10 μm and preferably more than 20 μm and particular preferably more than 50 μm and most preferably up to 500 μm or up to 300 μm. A bow of the carrier wafer is preferably below 50 μm, in particular below 20 μm, and/or wherein a warp of the carrier wafer is preferably below 50 μm, in particular below 20 μm.

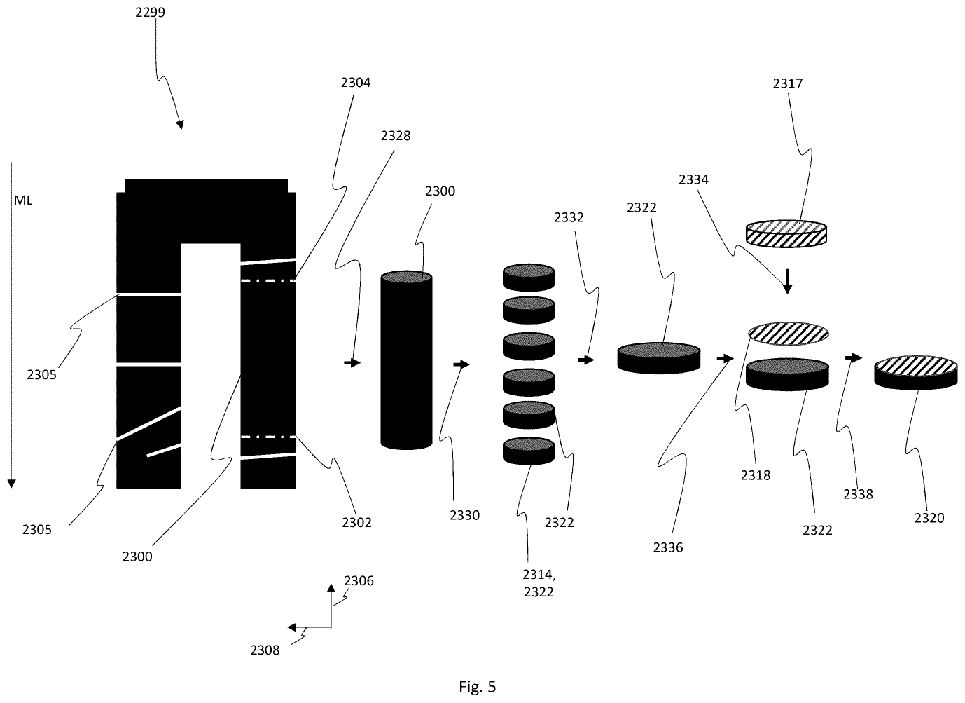

FIG. 5 also shows the entire structure 2299, which comprises one or multiple regions without cracks 2305. One region respectively crack-free SiC piece 2300 without cracks 2305 is preferably formed between a first plane 2302 and a second plane 2304, wherein the first plane 2302 and the second plane 2304 are preferably parallel to each other and arranged in a distance of more than 200 μm or preferably more than 500 μm or particular preferably more than 2500 μm or highly preferably more than 5000 μm or most preferably more than or up to 10000 μm or in a distance between 500 μm and 50000 μm. Arrow 2328 indicates a rough sawing step for removing the crack-free SiC piece 2300 from the structure 2299 and/or for removing the crack-free SiC piece 2300 from the crust 211. The crack-free SiC piece 2300 is in a further step 2330 sliced in a plurality of wafers 2322, in particular SiC carrier wafer, and preferably in more than two wafers 2322 and particular preferably more than 5 or up to 5 wafer 2322 or highly preferably more than 10 or up to 10 wafer 2322 or most preferably more than 15 or up to 15 wafer 2322 or between 2 and 50 wafer 2322.

It was found that large crystallites, in particular having a length of more than 5 μm or more than 10 μm or more than 30 μm or more than 50 μm, increase stability of the structure and therefore compensates tensions. However, further reduction of tensions due to small thermal mismatch, in particular temperature differences of less than 300K inside the SiC solid further reduce tensions and therefore causes crack-free regions inside the SiC solid. In case of electric current applied as AC current temperature difference between the core of the SiC solid and the growth face can be minimized. Additionally or alternatively, the grown SiC solid is preferably heated for a defined time after growing was finished, wherein the defined time is more than 1 h, in particular for more than 2 h and preferably for more than 3 h and particular preferably for more than 5 h and most preferably for more than 10 h or up to 24 h, wherein the electric energy for heating the SiC solid is reduced continuously and/or in a step wise manner during the defined time. Thus, due to each of said measures tensions inside the SiC solid are reduced or compensated and therefore large crack-free regions can be formed inside the SiC solid respectively as part of the SiC solid. “Large crack-free regions” preferably describe one or multiple regions inside the SiC solid sufficiently large to remove at least two and preferably at least five and most preferably at least 10 or 20 or up to 50 or 100, SiC carrier wafer having a diameter of more than 6 cm, in particular of more than 7.5 cm or more than 10 cm, and a height of up to 500 μm.

One, multiple or all SiC carrier wafers 2322 are preferably processed, in particular lapped, in step 2332. After the step of lapping a step of polishing (reference number 2336) is preferably carried out. Reference number 2317 indicates a SiC monocrystal, wherein according to reference number 2334 a wafer, in particular a monocrystalline wafer thinner than 50 μm, is removed from the SiC monocrystal 2317. Reference number 2338 indicates a bonding step for bonding the monocrystalline SiC wafer 2334 and the SiC carrier wafer 2322 and thereby generating the bonded structure 2320. The SiC carrier wafer 2322 preferably has a height between 200 μm and 500 μm and a diameter of at least 7.5 cm and preferably of at least 10 cm and most preferably of at least 12 cm or 15 cm. Additionally or alternatively the SiC carrier wafer 2322 is predominantly formed by a 3C crystal structure, wherein the SiC carrier wafer 2322 preferably doped, in particular Nitrogen doped, in particular more than 2000 ppba nitrogen but preferably less than 1019 and particular preferably less than 1018 and most preferably less than 1017 Nitrogen atoms/cm³. The SiC carrier wafer 2322 preferably has an electric resistivity <0.03 Ohm cm, preferably <0.02 Ohm cm and most preferably <0.01 Ohm cm.

The SiC carrier wafer 2322 preferably comprises at least one or exactly one inner section 2600 (cf. FIG. 26a or 26b), in particular one central inner section, and wherein the SiC carrier wafer 2322 preferably comprises an outer section 2602 (cf. FIG. 26a or 26b), wherein the outer section 2602 surrounds the inner section 2600. The inner section consists of a part of a SiC growth substrate 857, wherein the inner section 2600 is preferably predominantly formed by a 3C crystal structure. The outer section 2602 is preferably predominantly formed by a 3C crystal structure and comprises crystallites 2414 (cf. FIG. 9a-10d and FIG. 26a/b) extending in length direction of the individual crystallite more than 5 μm, in particular more than 10 μm and preferably more than 20 μm and particular preferably more than 50 μm and most preferably up to 500 μm or up to 300 μm. A bow of the carrier wafer is preferably below 50 μm, in particular below 20 μm, and/or wherein a warp of the carrier wafer is preferably below 50 μm, in particular below 20 μm.

Thus, the present invention preferably refers to a method for producing at least one crack-free SiC piece at least comprising the step: Providing a CVD reactor 850, wherein the CVD reactor 850 comprises at least one SiC growth substrate 857, a first power connection 859a and a second power connection 859b, wherein the SiC growth substrate 857 has a SiC growth substrate 857 length ML, wherein the SiC growth substrate 857 length ML extends between the first power connection 859a and the second power connection 859b, wherein the first power connection 859a is configured to conduct power into the main body 2200 for heating the main body 2200 and wherein the second power connection 859b is configured to conduct electric power conducted via the first power connection 859a into the SiC growth substrate 857 out of the SiC growth substrate 857, wherein the SiC growth substrate 857 forms a deposition surface 861 for deposition of SiC. Additionally, the step of growing a SiC solid 211 by depositing SiC on the deposition surface 861 in the CVD reactor 850, wherein the at least one crack-free SiC piece 2300 is part of the SiC solid 211, wherein the deposited SiC has a minimal thickness of at least 1 cm, wherein the at least one SiC piece 2300 is formed between a first plane 2302 and a second plane 2304, wherein the first plane 2302 is perpendicular to the SiC growth substrate 857 length ML and wherein the second plane 2304 is perpendicular to the SiC growth substrate 857 length ML, wherein the distance D between the first plane 2302 and the second plane 2304 is at least 1% and preferably at least 2% and highly preferably at least 5% of the SiC growth substrate 857 length ML. Additionally, the step of removing the at least one crack-free SiC piece 2300 from the SiC solid 211, wherein the at least one crack-free SiC piece 2300 has a cross-sectional size of at least 4 cm² and preferably of at least 8 cm² and highly preferably of at least 12 cm² and a thickness of at least 0, 1 cm and preferably of at least 1 cm and highly preferably of at least 2 cm. The first power connection 859a and the second power connection 859b preferably connect the SiC growth substrate 857 with a power source, in particular an electric power source, in particular an alternating current source.

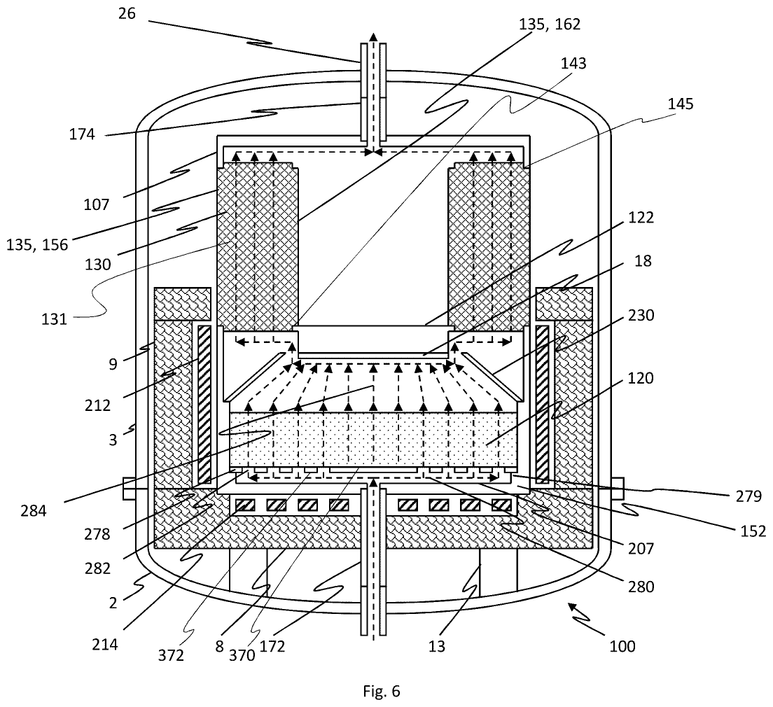

FIG. 6 shows a furnace unit 102. The furnace unit 102 preferably comprises a furnace housing 108 with an outer surface 242 and an inner surface 240, at least one crucible unit 106 and at least one heating unit 124 for heating the source material 120. The crucible unit 106 is preferably arranged inside the furnace housing 108, wherein the crucible unit 106 comprises a crucible housing 110, wherein the housing 110 has an outer surface 112 and an inner surface 114, wherein the inner surface 114 at least partially defines a crucible volume 116, wherein a receiving space 118 for receiving a solid SiC source material 120 is arranged or formed inside the crucible volume 116, wherein a seed holder unit 122 for holding a defined seed wafer 18 is arranged inside the crucible volume 116, wherein the furnace housing inner wall 240 and the crucible housing outer wall 112 define a furnace volume 104, wherein the receiving space 118 for receiving the source material 120 is at least in parts arranged below the seed holder unit 122. The receiving space 118 preferably has a defined volume for receiving a maximum volume of source material 120. Operating the furnace unit 102, in particular PVT reactor, with source material 120 which has a higher density, compared to source material with a lower density allows the production of larger SiC crystals in one run. Thus, usage of source material 120 which is made of exactly one SiC piece 2300 according to the present invention is highly beneficial in case the source material fills at least 75% and preferably at least 90% and highly preferably at least 95% and most preferably at least 98% of the volume of the receiving space 118. Alternatively, usage of multiple SiC pieces is beneficial in case at least a plurality and preferably all of the multiple SiC pieces 2300 have the same shape, wherein the source material 120 fills at least 75% and preferably at least 90% and highly preferably at least 95% and most preferably at least 98% of the volume of the receiving space 118.

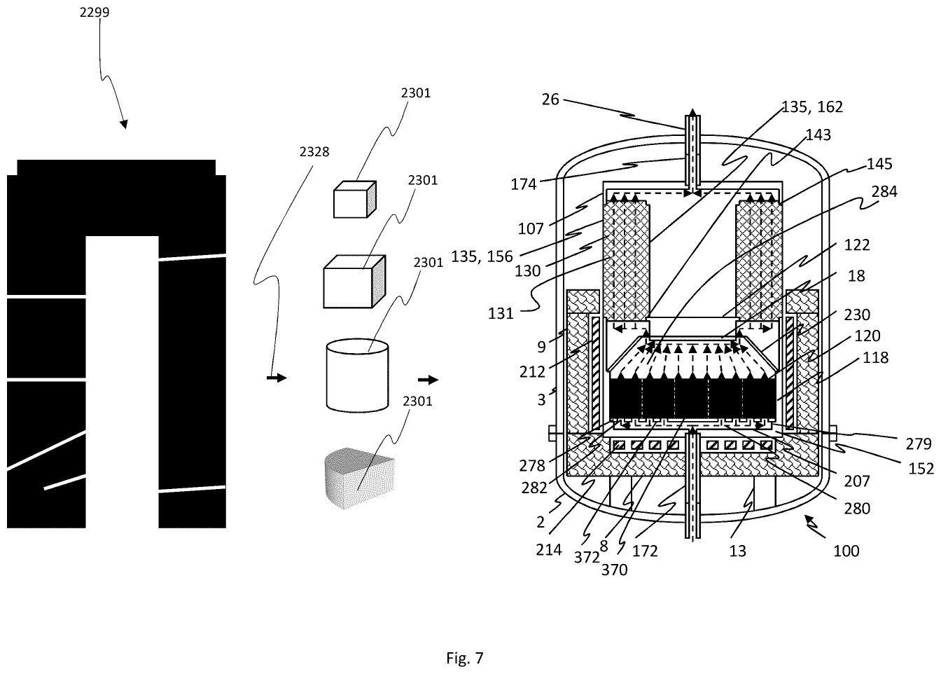

FIG. 7 shows the entire CVD SiC structure 2299 and a step of raw sawing 2328 the CVD SiC structure 2299. The raw sawing 2328 causes forming of SiC pieces 2301 in defined shapes, wherein the defined shapes are such that more than 80% (vol.) and preferably more than 90% (vol.) or highly preferably more than 95% (vol.) of a receiving space of a PVT reactor can be filled with one or multiple SiC pieces 2301, wherein each of the SiC pieces have a volume of more than 1 cm×1 cm×1 cm and preferably of more than 2 cm×1 cm×1 cm and highly preferably of more than 2 cm×2 cm×1 cm.

The source material 120 is schematically divided in different pieces by “white doted lines” indicating the SiC pieces 2301. The SiC pieces 2301 can be crack-free but do not have to be crack-free.

Thus, one entire CVD SiC structure 2299 can be divided in crack-free SiC pieces 2300 and not-crack-free SiC pieces 2301, wherein the crack-free SiC pieces 2300 can be used for the production of SiC devices, like carrier wafers 2322, and the not-crack-free SiC pieces 2301 can be used as high-density source material for the production of monocrystalline SiC, in particular in a PVT reactor.

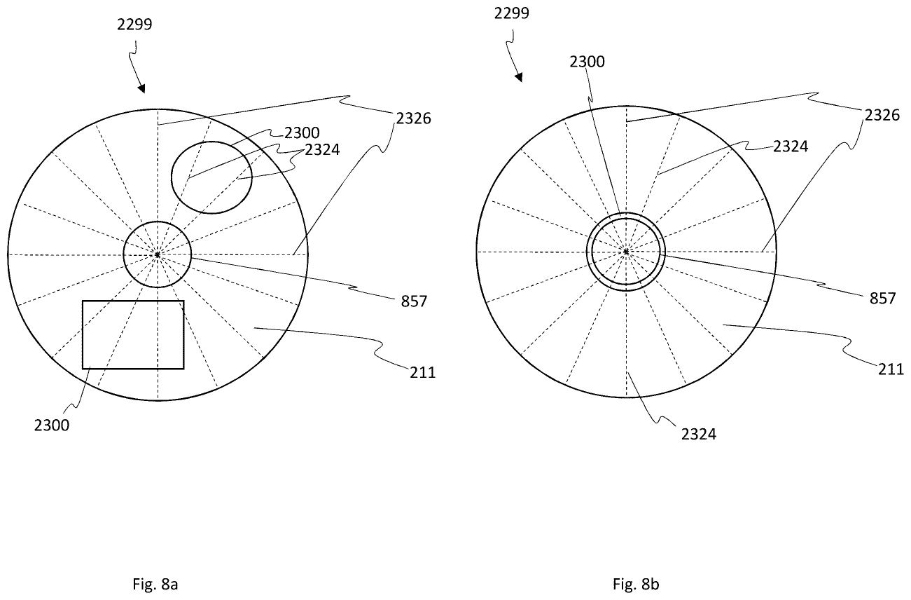

FIGS. 8a and 8b schematically show positions of crack-free SiC pieces inside the entire CVD SiC structure 2299.

According to FIG. 8a the pieces 2300 are arranged in the crust 211 of the CVD SiC structure 2299. Thus, the majority of grain orientations is aligned in an angle of less than 90° and preferably in an angle of less than 100°.

Reference number 2326 indicates schematically corners of a first “quarter”. Thus, it is possible to virtually divide the CVD SiC structure 2299 in four quarters. In case the grain orientation of a SiC piece 2300 is less than 90° the SiC piece 2300 was preferably removed from one quarter.

FIG. 8b shows that the majority of grain orientations is aligned in an angle of more than 90° and preferably in an angle of more than 180° and most preferably in an angle of more than 270°. The SiC pieces 2300 shown in FIGS. 8a and 8b can be used as SiC growth substrates 857 for use in any of the herein described CVD reactor 850.

FIG. 9a shows a polycrystalline SiC piece 2300, in particular an ingot or boule. Reference number 2414 schematically refers to a crystallite at least mainly orientated into radial direction (R), wherein crystallites 2414 are present having a length of more than 5 μm, in particular of more than 10 μm and most preferably of more than 30 μm. Line 2416 schematically illustrates a dividing plane along which the SiC piece 2300 is divided in two pieces. In the shown example the smaller section of the SiC piece 2300 respectively the section above line 2416 forms a “second substrate” 2322 according to the present invention respectively a SiC carrier wafer 2322.

FIG. 9b shows a first substrate 2317 and a second substrate 2322 according to the present invention. The first substrate 2317 is preferably a monocrystalline SiC crystal and the second substrate is preferably a polycrystalline SiC structure respectively a SiC carrier wafer 857, wherein the first substrate 2317 and the second substrate 2322 are both at least partially (vol.) and preferably mainly (vol.) or most preferably entirely grown in radial direction.

The first substrate 2317 preferably comprises ions arranged on a layer 2418 for dividing a thin substrate layer 2318 from the first substrate 2317. The ions can be expanded during a later heating process and locally cause the crystal structure to crack and thereby divide the first substrate 2317 into to pieces. Such a dividing is known as “Smart-Cut-Process”.

FIG. 9c shows the first substrate 2317 and the second substrate 2322 bonded together. Arrow “H” indicates the height direction respectively the direction in which the top surface 2406 of second substrate 2322 and bottom surface of second substrate 2408 are arranged in a distance to each other as well as the top surface of first substrate 2400 and bottom surface of first substrate 2402 are arranged in a distance to each other.

FIG. 9d shows the composite wafer 2320 of the present invention after the step of dividing the thin substrate layer 2318 from the first substrate 2317.

FIG. 9e shows an optional step of growing an epi-layer 2319 on top of the thin substrate layer 2318.

The epi-layer 2319 is a monocrystalline SiC crystal layer 2319 which is produced on the thin substrate layer 2318, wherein the monocrystalline SiC crystal layer 2319 is grown by means of epitaxy and wherein the thin substrate layer 2318 has a thickness of less than 1 μm and wherein the monocrystalline SiC crystal layer 2319 preferably has a thickness of 0.5 μm to 20 μm, in particular of 1 μm to 15 μm or 1 μm to 12 μm or preferably 2 μm to 15 μm or 2 μm to 12 μm.

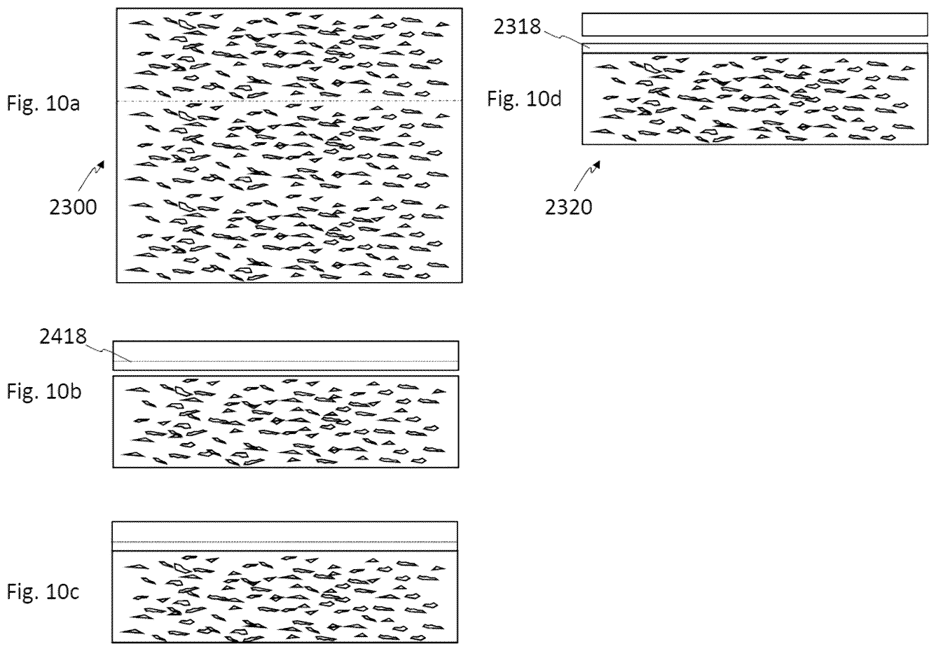

Thus, in view of FIG. 9a-d and FIG. 10a-d the method for the production of a compound respectively composite wafer respectively or multi-substrate wafer 2320 according to the present invention preferably comprises the steps of providing a first substrate, providing a second substrate 2322 and bonding the first substrate 2317 and the second substrate 2322 together. The first substrate 2317 is preferably a monocrystalline SiC crystal, wherein the monocrystalline SiC crystal 2317 is formed by a crystal structure, wherein the crystal structure defines a c-axis, wherein the crystal structure is grown perpendicular to the c-axis, wherein the monocrystalline SiC crystal 2317 has a preferably flat top surface 2400, a preferably flat bottom surface 2402 and a connecting-surface 2404 connecting the top surface 2400 and bottom surface 2402, wherein the c-axis is aligned in an angle between 0° and 8° and preferably in an angle between 2° and 6° with respect to a normal on the top surface 2400. The second substrate 2322 preferably comprises or consists of polycrystalline SiC, in particular 3C—SiC, wherein the at least 60% [volume] of the polycrystalline SiC is grown in radial direction, wherein the second substrate 2322 has a specific electrical resistance of less than 15 mOhmcm, bonding the first substrate 2317 and the second substrate 2322 together. The second substrate respectively the SiC carrier wafer 2322 preferably has a height between 200 μm and 500 μm and a diameter of at least 7.5 cm and preferably of at least 10 cm and most preferably of at least 12 cm or 15 cm. Additionally or alternatively the SiC carrier wafer 2322 is predominantly formed by a 3C crystal structure, wherein the SiC carrier wafer 2322 preferably doped, in particular Nitrogen doped, in particular more than 2000 ppba nitrogen but preferably less than 1019 and particular preferably less than 1018 and most preferably less than 1017 Nitrogen atoms/cm³. The SiC carrier wafer preferably has an electric resistivity <0.03 Ohm cm, preferably <0.02 Ohm cm and most preferably <0.01 Ohm cm.

The SiC carrier wafer 2322 preferably comprises at least one or exactly one inner section 2600 (cf. FIG. 26a or 26b), in particular one central inner section, and wherein the SiC carrier wafer 2322 preferably comprises an outer section 2602 (cf. FIG. 26a or 26b), wherein the outer section 2602 surrounds the inner section 2600. The inner section consists of a part of a SiC growth substrate 857, wherein the inner section 2600 is preferably predominantly formed by a 3C crystal structure. The outer section 2602 is preferably predominantly formed by a 3C crystal structure and comprises crystallites 2414 extending in length direction of the individual crystallite more than 5 μm, in particular more than 10 μm and preferably more than 20 μm and particular preferably more than 50 μm and most preferably up to 500 μm or up to 300 μm. A bow of the carrier wafer is preferably below 50 μm, in particular below 20 μm, and/or wherein a warp of the carrier wafer is preferably below 50 μm, in particular below 20 μm.

The method preferably also comprises the step of transforming the first substrate 2317 in a thin substrate layer 2318 by reducing the thickness of the first substrate 2317 to less than 20 μm, wherein the step of reducing the thickness of the first substrate 2317 to less than 20 μm is carried out after the first and second substrate 2322 are bonded together.

Thus, the present invention refers to a multi-substrate wafer 2320. Said multi-substrate wafer 2320 comprises at least a first substrate 2317 and a second substrate, wherein the first substrate 2317 and the second substrate 2322 are bonded together, wherein the first substrate 2317 is a monocrystalline SiC crystal 2317, wherein the second substrate 2322 comprises polycrystalline 3C—SiC, wherein the at least 30% [volume], in particular at least 50% [volume] and preferably at least 70% [volume], of the polycrystalline 3C—SiC is grown in radial direction around at least one or exactly one central element 857, wherein the central element 857 preferably comprises or consists of SiC, wherein the second substrate 2322 has a specific electrical resistance of less than 15 mOhmcm, wherein the second substrate 2322 is at least nitrogen doped, wherein more than 1017 nitrogen atoms per cm³ are present inside the second substrate 2322 due to doping.

FIG. 10a corresponds to FIG. 9a.

FIG. 10b shows the first substrate 2317 comprising an ion layer 2418 for removing the thin layer 2318, wherein the ion layer 2418 is arranged in a larger distance compared to FIG. 9b.

FIG. 10a-d show that the thin substrate layer 2318 preferably has a thickness between 2 μm and 20 μm, in particular between 5 μm and 12 μm, and wherein the thin substrate layer 2318 highly preferably comprises 1015-1016 nitrogen atoms per cm³. Thus, the substrate layer 2318 can act as n-Drift region and the second substrate can act as n+ substrate in case of an electric device, like e.g., a SCHOTTKEY Diode.

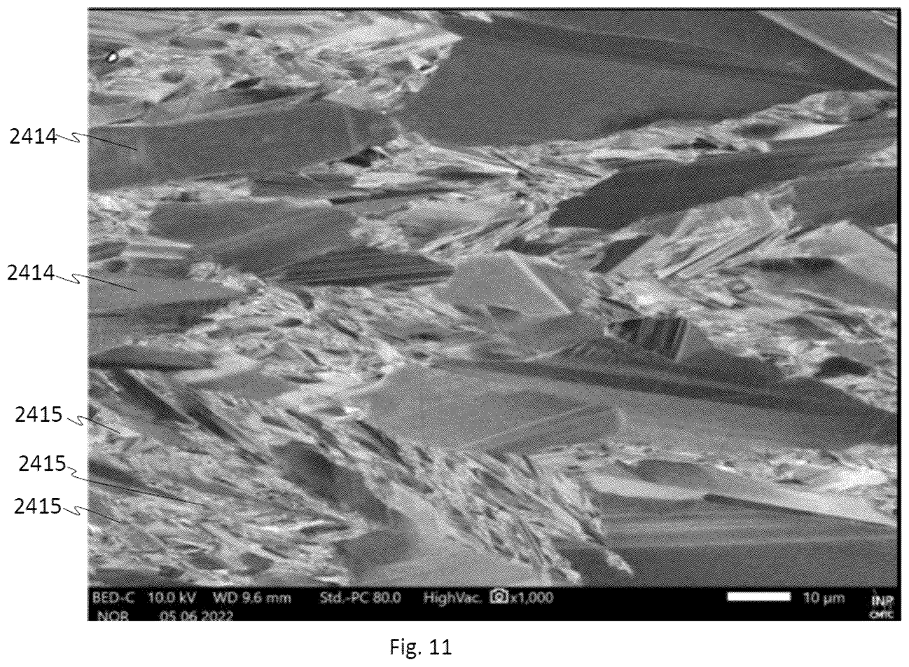

FIG. 11 show a high-resolution photo of a section of a second substrate 2322. Reference numbers 2414 refer to crystallites having a length extension (preferably in the image plane) of more than 5 μm and refence numbers 2415 refer to crystallites having a length extension (preferably in the image plane) of less than 5 μm.

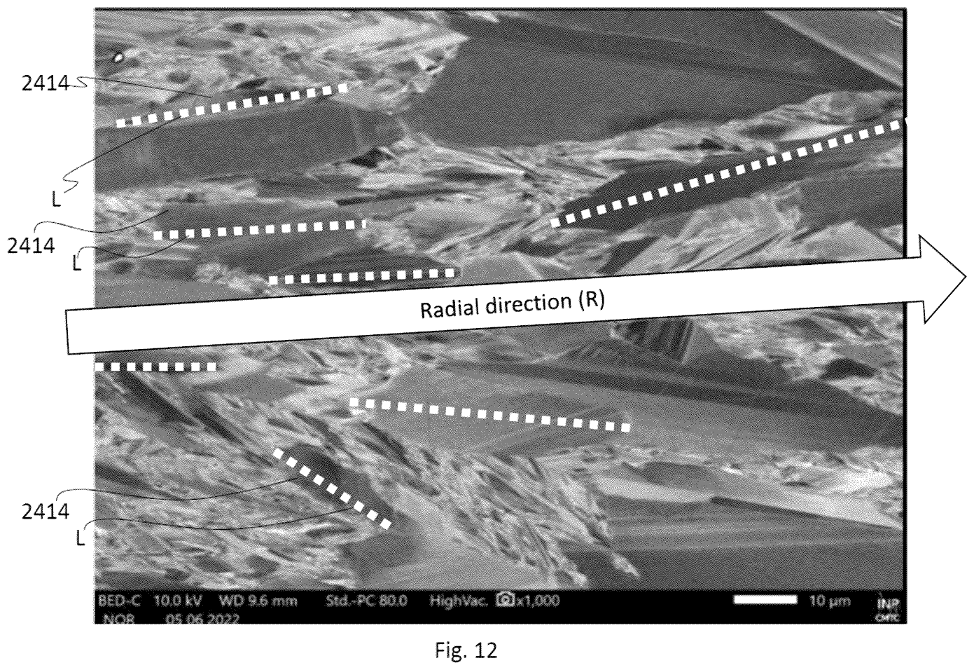

FIG. 12 shows a modified version of FIG. 11. Multiple large crystallites 2414 are identified (preferably in the image plane) and the length direction of said large crystallites 2414 is indicated by dotted lines. An overall radial direction R indicates the direction of expansion of the polycrystalline SiC during growth.

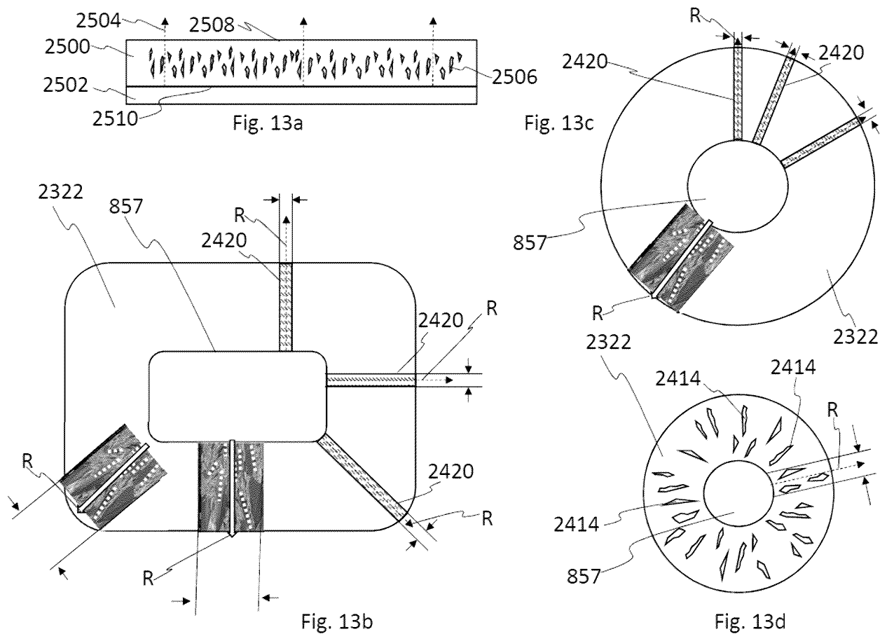

FIG. 13a shows a state-of-the-art carrier wafer 2500. Said carrier wafer 2500 is grown by means of epitaxy in a flat growth substrate 2502. The growth direction 2504 is only in one direction respectively orthogonal to the plane surface of growth substrate 2502. FIG. 5a also schematically shows that the length direction of the plurality of large crystallites 2506 is mainly orientated in one direction. Most or all crystallites of SiC carrier wafer 2500 are orientated in growth direction and therefore parallel to the height direction, wherein the two main surfaces 2508 and 2510 are arranged in a distance of more than 300 μm in height direction to each other, wherein said main surfaces 2508 and 2510 are flat and parallel to each other.

FIG. 13b shows that a central element respectively SiC growth substrate 857 provides a growth face extending in 3D space and therefore not only in 2D space.

FIGS. 13b and 13c/d show that the central element/SiC growth substrate 857 can have multiple shapes.

With respect to FIGS. 13b, 13c and 13d it has to be understood that “radial” does not only apply in cases, in which the central element/SiC growth substrate 857 has a circular shape (cross-sectional) respectively in cases in which a “radius” is present. “Radial” describes in the context of the present invention the growth direction during expanding of the polycrystalline structure, along a lateral surface respectively growth face. Thus, the radial direction R of the polycrystalline structure 2322 can be preferably determined for multiple sections of the polycrystalline structure 2322, wherein each section 2420 preferably comprises in its center the radial direction R of the respective section 2420, wherein the respective section 2420 preferably has a width of less than 500 μm, in particular of less than 300 μm and preferably of less than 100 μm, wherein the alignment between the radial direction R of the polycrystalline structure 2322 and the length direction L of the individual crystallite 2414 which extends more than 5 μm, in particular more than 10 μm and preferably more than 20 μm, is limited to crystallites 2414 present in a respective section 2420 and the radial direction R of the respective section 2420.

The central element/SiC growth substrate 857 is preferably also grown in radial direction, in particularly removed from a radially grown section of a SiC piece 2300, in particular ingot or boule.

FIG. 13d schematically shows that the orientation of the large crystallites 2414 changes in circumferential direction of the polycrystalline crystal structure 2322.

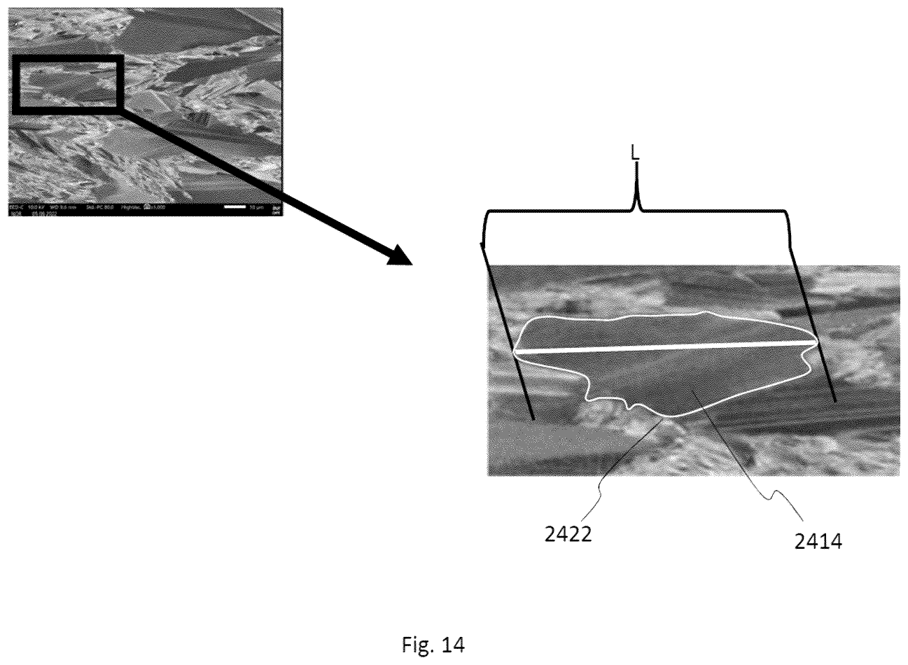

FIG. 14 shows an enlarged section of FIG. 11. Said section shows a crystallite 2414, wherein the boundary 2422 of said crystallite 2414 is marked with a thin white line. A straight white line connects two points of the crystallite 2414 which are arranged in the largest distance to each other in the respective plane. Thus, the white line represents the length direction of the crystallite 2414. Said definition of the length direction L of the crystallite 2414 is used with respect to all embodiments of the present invention.

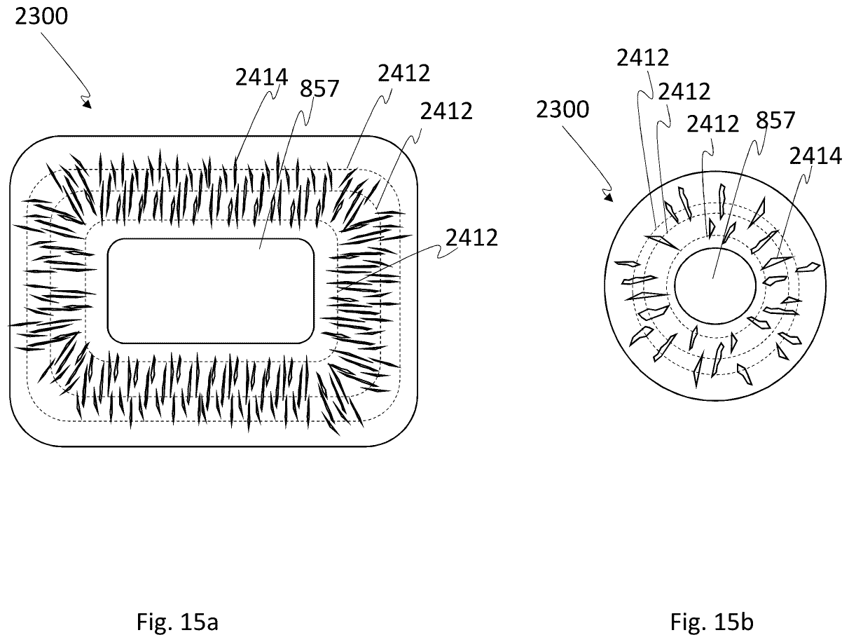

FIGS. 15a and 15b schematically show that band shaped or line shaped or straight elements 2412 representing growth rings or growth lines can be present in the grown SiC piece 2300. The plurality of line shaped, in particular at least partially curved, in particular at least partially circular or at least partially arc shaped, and/or at least partially straight elements 2412 is preferably formed in a distance of at least 1 nm to the preferably flat top surface 2406 inside, the preferably flat bottom surface 2408 and the connecting-surface 2410.

At least one and preferably at least two curved, circular, straight and/or arc-shaped elements 2412 have at least a length in circumferential direction of the second substrate 2322 of at least 10 nm, in particular at least 20 nm or 50 nm or 100 nm. Preferably are at least one or two curved, circular, straight and/or arc-shaped elements 2412 extending entirely around the central element/SiC growth substrate 857.

Said line shaped or band shaped or straight elements preferably result from variations of growth face temperature and/or feed gas composition.

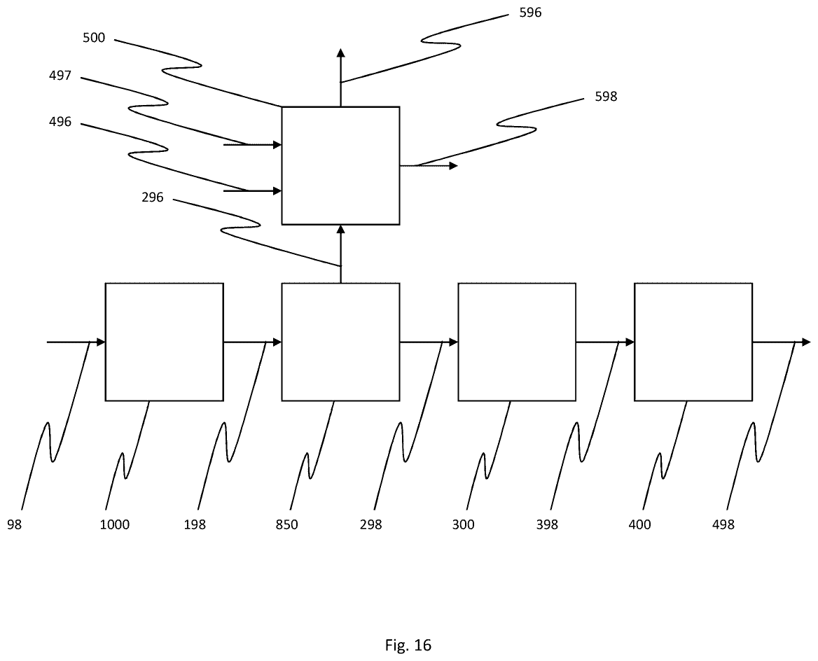

In one preferred embodiment of the present invention, FIG. 16 shows preferred main units of the SiC, in particular UPSiC (ultra pure SiC), production reactor 850, in particular for the production of SiC, wherein the SiC production reactor 850 comprises according to this embodiment a SiC vent gas treatment. The separate feed gases 98 are pumped from their respective storage units to the feed gas unit 1000 where there are mixed in the required mass ratios to form the feed gas mixture 198. The feed gas mixture 198 is fed to the CVD unit respectively CVD reactor respectively SiC production reactor 850, in particular SiC PVT source material production reactor, where the deposition reaction occurs resulting in the production of SiC rods 298 and vent gas 296. The vent gas 296 is routed to the vent gas treatment unit 500 where preferably scrubber inlet water 496 is used to remove Si-bearing compounds and HCl from the vent gas 296. The scrubber outlet water 598 containing the absorbed Si-bearing compounds and HCl is discharged and the scrubbed vent gas is preferably sent to a flare for combustion. The flare can use flare combustion gas 497 such as natural gas to achieve the combustion of the scrubbed vent gas and the resulting flare exhaust gas is discharged. The CVD reactor 850 according to FIG. 1, 2, 3, 4 can also be equipped or coupled with a herein disclosed vent gas treatment respectively recycling unit.

The SiC rods 298 are preferably conveyed to the comminution unit 300 where they are reduced to the required form factor, e.g., granules. Also, any heterogenous material, e.g., graphite seed rods, are preferably separated from the SiC material in such a manner as to minimize any residual contamination from this material, e.g., by heating the SiC to at least 1500° C. to burn off any residual graphite. The SiC, in particular UPSiC, granules 398 are preferably conveyed to the acid etching unit 400 where they preferably undergo an additional or alternative surface cleaning step of acid etching in an acid bath. Finally, the SiC, in particular UPSiC, etched granules 498 which have been washed and dried after the acid bath are ready for packaging and shipment.

Alternatively, the SiC rods 298 are treated as described with respect to FIG. 5.

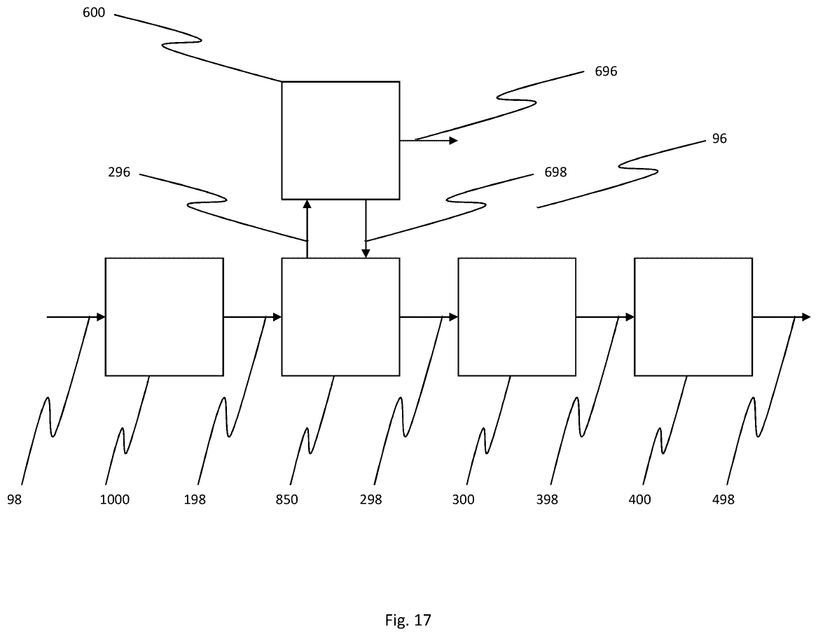

In another preferred embodiment of the present invention, FIG. 17 shows the main units of the entire CVD SiC, in particular UPSiC, apparatus 850, in particular according to FIG. 1, 2, 3, 4, in this case with vent gas recycling. Here the vent gas 296 exits the CVD unit respectively CVD reactor respectively SiC production reactor, in particular SiC PVT source material production reactor, 850 and is routed to the vent gas recycling unit 600. HCl is preferably separated from the vent gas 296 and exits the vent gas recycling unit 600 as the HCl discharge 696. The recycled vent gas 698 is then fed back to the CVD unit respectively CVD reactor respectively SiC production reactor, in particular SiC PVT source material production reactor, 850 thus reducing the amount of fresh feed gas mixture 198 required and reducing production costs.

Since product purity is highly beneficial, in the apparatus described in FIGS. 16, preferably extreme care is taken not to introduce any contaminants, particularly trace metals and nitrogen or oxygen into the feed gases or any intermediate and final products. Virtually all equipment and piping is fabricated from metals, particularly various steel alloys, but they are highly preferably kept at temperatures where the entrainment of metal particles into the feed gases and products is minimized. The feed gases and products are preferably further isolated from any moisture or air that could result in nitrogen and or oxygen contamination. Nitrogen could be used as a blanket and purge gas in tanks, pipes and vessels, but it is preferably removed from any liquid feedstocks with degassing equipment and any nitrogen purge gases are preferably chased with hydrogen to minimize the possibility of nitrogen contamination.

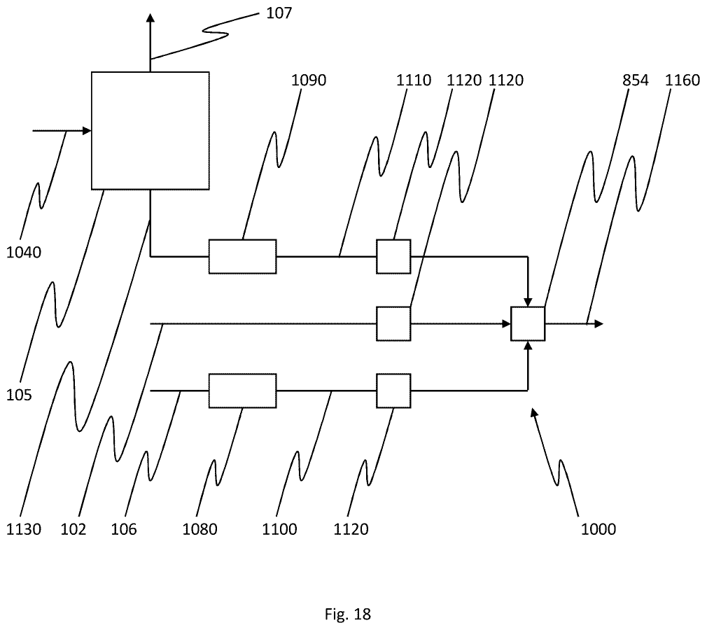

FIG. 18 shows an example of the preparation of three separate feed gases into the feed gas mixture 1160 in the feed gas unit 1000. First, a preferably industrial C-bearing gas 1040 preferably natural gas needs to be purified of excess nitrogen to result in a C-bearing gas 111 pure enough for use in the manufacture of SiC, in particular UPSiC. Thus, the industrial C-bearing gas 1040 is highly preferably routed to a cryogenic distillation unit 105 where the low temperatures cause the industrial C-bearing gas 1040 to condense into its liquid state. Any contaminating nitrogen remains in its gaseous state and exits as N gas discharge 1070 from the top of the cryogenic distillation unit 105. Meanwhile the C-bearing liquid 1130 preferably exits from the bottom of the cryogenic distillation unit 105 and preferably pumped to a C-bearing liquid evaporator 1090 where it is evaporated into C-bearing gas 111. The C-bearing gas 111 mass flow rate is adjusted by the mass flow meter 1120 and the correct flowrate of C-bearing gas is preferably routed to the mixer respectively mixing device 854.

Already purified hydrogen gas 102 is preferably also passed through a mass flow meter 1120 and fed to the mixer respectively mixing device 854 in the correct ratio respectively a defined ratio with the C-bearing gas 111. Finally, an already purified Si-bearing liquid 106 preferably silicon tetrachloride (STC) is fed to a Si-bearing liquid evaporator 1080 and evaporated into Si-bearing gas 110. This Si-bearing gas 110 is preferably also fed to a mass flow meter 1120 and preferably sent to the mixer 114 in the correct respectively in a defined mass flow ratio to the hydrogen gas 102 and/or the C-bearing gas 111. The mixer 114 ensures that the three gases are homogenously mixed and outputs the feed gas mixture 1160.

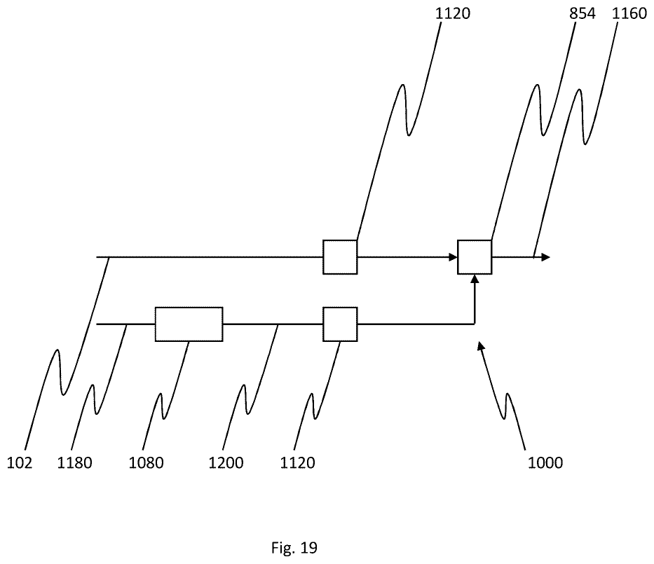

In another preferred embodiment of the present invention shown in FIG. 19, a single C/Si-bearing liquid 1180 is evaporated in Si-bearing liquid evaporator 1080 to become C/Si-bearing gas 1200. This C/Si-bearing gas 1200 is preferably sent to mass flow meter 1120 where its mass flowrate is preferably adjusted to create the required or defined mass ratio with hydrogen gas 102 which preferably has also passed through a mass flow meter 1120. The two gases are preferably mixed into a homogenous mixture in the mixer respectively mixing device 854 and exit as the feed gas mixture 1160.

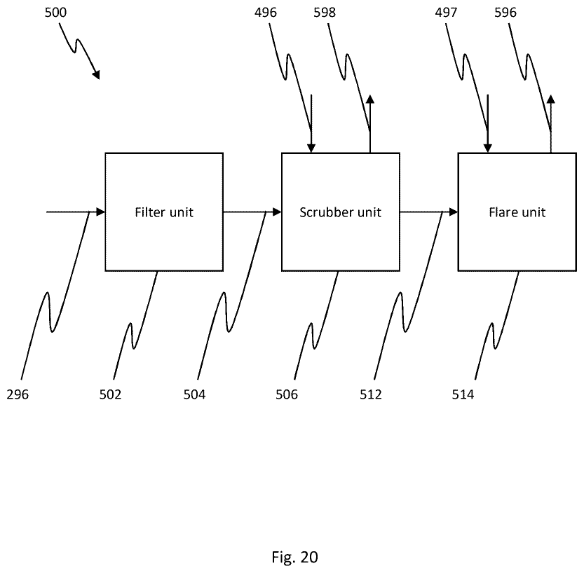

FIG. 20 shows the vent gas treatment unit 500 of the CVD SiC, in particular UPSiC, apparatus 850 in one preferred embodiment of the present invention where the vent gas 296 is treated and discharged rather than recycled. The vent gas 296 is routed from the CVD unit respectively CVD reactor respectively SiC production reactor, in particular SiC PVT source material production reactor, 850 to the filter unit 502 of the vent gas treatment unit 500 where any particulates that may have formed in the gas are removed. The filtered vent gas 504 is then preferably sent to the scrubber unit 506 where it is preferably absorbed into scrubber inlet fluid, in particular water 496. Scrubber outlet water 598 preferably containing any Si-bearing compounds and HCl then exits the scrubber, in particular to be processed for disposal. The scrubbed vent gas 512 is then preferably sent to the flare unit 514 where it is combusted with flare combustion gas 497, preferably natural gas, and the resulting flare exhaust gas 596 is suitable for discharge.

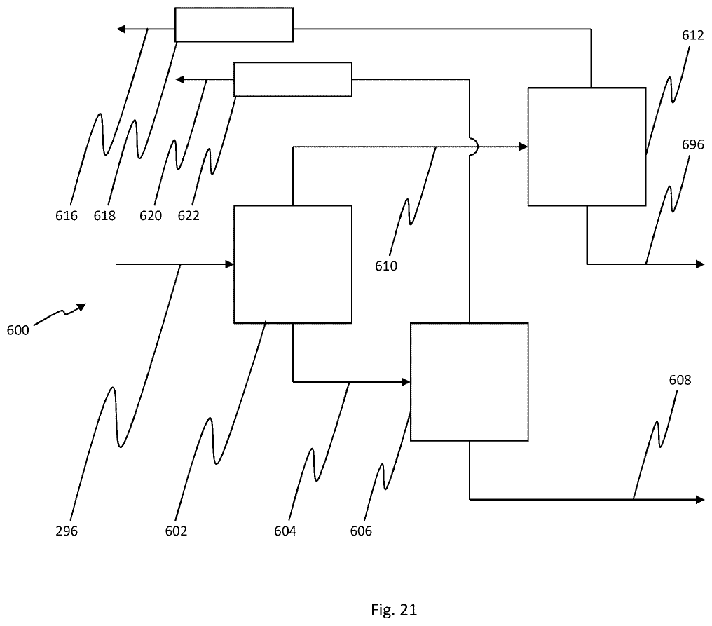

FIG. 21 shows an example of a vent gas recycling unit 600 of the CVD SiC, in particular UPSiC, apparatus 850 in another preferred embodiment of the present invention where the vent gas 296 is recycled rather than treated and discharged. The vent gas 296 is routed from the CVD unit respectively CVD reactor respectively SiC production reactor, in particular SiC PVT source material production reactor 850 to the cold distillation unit 602 which preferably operates in a temperature range of −30° C. to −196° C. In this temperature range any Si-bearing gases condense and exit the bottom of the distillation unit 602 as an Si-bearing liquid mixture 604. This Si-bearing liquid mixture 604 is periodically routed to a HMW distillation unit 606 which operates in a temperature range that evaporates the Si-bearing liquid 604 while any heavy-molecular-weight compounds remain liquid and exit the bottom of the HMW distillation unit 606 as the HMW liquids discharge 608.

Meanwhile, the Si-bearing gas mixture 620 is exiting the top of the HMW distillation unit 606 and passing through an Si detector unit 622 which determines the mass of Si present. The Si detector unit 622 communicates this information to the central process control unit of the CVD SiC, in particular UPSiC, apparatus 850 which then adjusts the mass flow meter 1120 on the Si-bearing gas 110 line such that the total mass of Si coming from the Si-bearing gas mixture 620 and the Si-bearing gas 110 is in the desired ratio with the total mass of C coming from the H/C-bearing gas mixture 616 and the C-bearing gas 111. Meanwhile, cold distillation gas 610 is exiting the top of the top of the cold distillation unit 602 and is sent to the cryogenic distillation unit which preferably operates in a temperature range between −140° C. and −40° C. in this temperature range, the H/C-bearing gas mixture 616 remains in the gaseous form but the HCl condenses and is removed from the bottom of the Cryogenic distillation unit 612 as the HCl liquid discharge 696 to be further processed for disposal.

The H/C-bearing gas mixture 616 is passed through an H/C detector unit which determines the masses of H and C present. The H/C detector unit communicates this information to the central process control unit of the CVD SiC, in particular UPSiC, apparatus 850 which then adjusts the mass flow meters 1120 on the hydrogen gas 102 line and the C-bearing gas 111 line such that the mass ratios of H, C, and Si are all in the desired range.

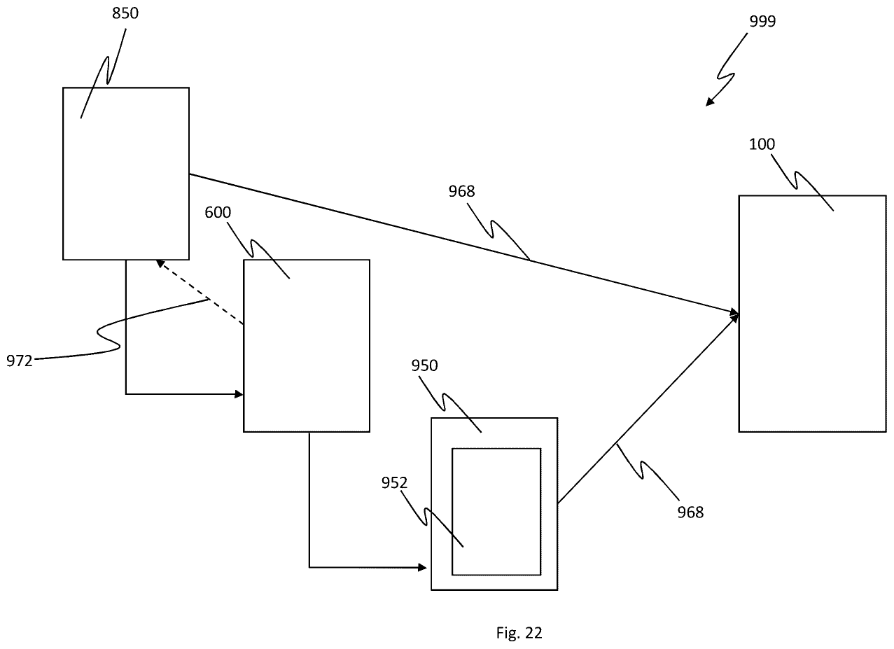

FIG. 22 show an example of a system 999 according to the present invention. The inventive system 999 comprises at least one SiC production reactor 850 and one PVT reactor 100, wherein the SiC production reactor 850 produces SiC source material which is used in the PVT reactor 100 to produce monocrystalline SiC.

According to FIG. 22 it is additionally or alternatively possible that multiple SiC production reactors 850, 950 are provided. It is additionally or alternatively possible that multiple PVT reactors 100 are provided. Furthermore, it is possible that a SiC production reactor 850 comprises a vent gas recycling unit 600. It is alternatively possible that multiple SiC production reactors 850, 950 are connected through a vent gas recycling unit 600. Thus, the vent gas of a first SiC production reactor 850 can be recycled and used as source material for the other SiC production reactor 950. Thus, at least some output of the vent gas recycling unit 600, in particular the Si, C and H2 components, can be used as feed gas for the same or another SiC production reactor 850. Arrow 972 alternatively indicates that the output of the vent gas recycling unit 600 can be used for the CVD reactor 850 which emitted the vent gas.

Thus, due to the before mentioned system the present invention provides a method for the production of at least one SiC crystal. Said method preferably comprises the steps: Providing a CVD reactor 850 for the production of SiC of a first type, introducing at least one source gas, in particular a first source gas, in particular SiCl3(CH3), into a process chamber 856 for generating a source medium, wherein the source medium comprises Si and C, introducing at least one carrier gas into the process chamber 856, the carrier gas preferably comprising H, electrically energizing at least one SiC growth substrate 857 disposed in the process chamber 856 to heat the SiC growth substrate 857, wherein the surface of the SiC growth substrate 857 is heated to a temperature in the range between 1400° C. and 1700° C., depositing SiC of the first type onto the SiC growth substrate 857, in particular at a deposition rate of more than 200 μm/h, wherein the deposited SiC is preferably polycrystalline SiC, removing the deposited SiC of the first type from the CVD reactor 850, preferably transforming the removed SiC into fragmented SiC of the first type or into one or multiple solid bodies SiC of the first type, providing a PVT reactor 100 for the production of SiC of a second type, adding the preferably fragmented SiC of the first type or adding one or multiple solid bodies of SiC of the first type as source material 120 into a receiving space 118 of the PVT reactor 100, sublimating the SiC of the first type inside the PVT reactor 100 and depositing the sublimated SiC on a seed wafer 18 as SiC of the second type.

The PVT reactor 100 hereby preferably comprises a furnace unit 102, wherein the furnace unit 102 comprises a furnace housing 108 with an outer surface 242 and an inner surface 240, at least one crucible unit 106, wherein the crucible unit 106 is arranged inside the furnace housing 108, wherein the crucible unit 106 comprises a crucible housing 110, wherein the crucible housing 110 has an outer surface 112 and an inner surface 114, wherein the inner surface 114 at least partially defines a crucible volume 116, wherein a receiving space 118 for receiving a source material 120 is arranged or formed inside the crucible volume 116, wherein a seed holder unit 122 for holding a defined seed wafer 18 is arranged inside the crucible volume 116, wherein the seed wafer holder 122 holds a seed wafer 18, wherein the furnace housing inner wall 240 and the crucible housing outer wall 112 define a furnace volume 104, at least one heating unit 124 for heating the source material 120, wherein the receiving space 118 for receiving the source material 120 is at least in parts arranged above the heating unit 124 and below the seed holder unit 122.

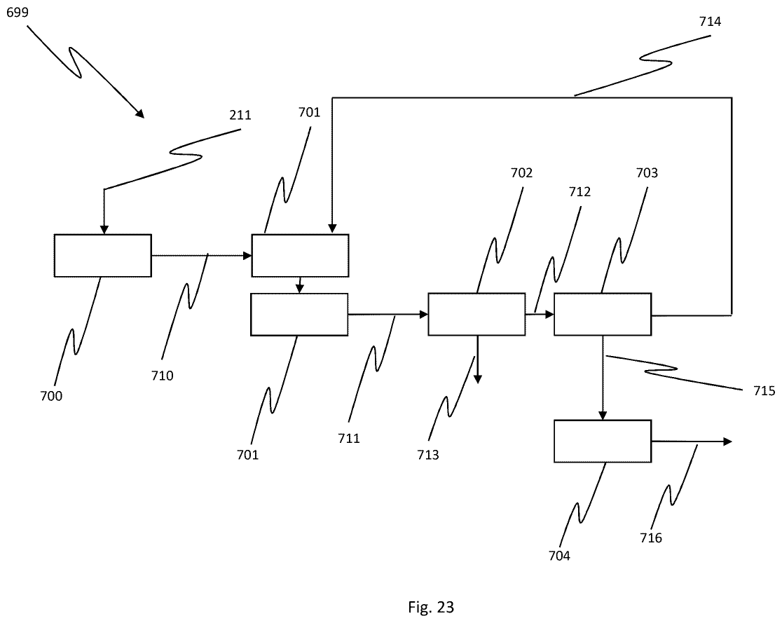

FIG. 23 shows a comminution unit 699.

At the end of the deposition process, after purging the reactor and rendering inert, the bell jar can be lifted and the thick rods removed from the CVD reactor. This process is widely known as harvesting.

The harvested rods have to be transferred into a shape suitable for PVT processing. This can either be a cut rod segment or broken chips and chunks of various sizes.

Different methods to comminute hard and brittle solids like silicon carbide into smaller pieces are known. Most common is the mechanical approach. SiC rods or larger fragments thereof are fed into a crusher, which is preferably a jaw crusher or a roll crusher. Adjustable machine parameters as gap distance, rotational speed or swing amplitude are determining the final particle size distribution. To avoid large amounts of fines and/or high contamination level, a multiple stage application of crusher machines is possible. Crushing machines are ordered in series, where the outlet of one crusher is connected, either directly or indirectly via a transportation device like belt conveyor or vibrating chutes, with the feed opening of a subsequent crusher with differing machine parameters. Finally, the comminuted pieces have to be classified to remove undersize material and to return oversize material to the comminution process.

Alternative crushing methods are also applicable. A known method is thermal cracking. A rod of hard, brittle material is heated and cooled down with a high temperature gradient, e.g. by rapid dipping into a cold fluid.

Typically, mechanically driven screening machines are used to classify irregular pieces of solid material into size classes. A summary of used screening machines is described in US2018169704. The mechanical approach to classify pieces of solid material can be extended by a more flexible optoelectronic method, which was disclosed in US 2009/120848.

The comminution process excavates the starting substrate, if graphite is used as starting material, because the interface between starting substrate and silicon carbide growth layer acts as a predetermined breaking point. This fact can be used to easily remove the graphite substrate from the product by annealing/heating to at least 900° C. to 1400° C. in the presence of air or any gas mixture enriched with oxygen. The surface color changes from grey to blueish-brownish, caused by thin layers (100-300 nm) of silicon oxides. This can easily be removed by an acid treatment.

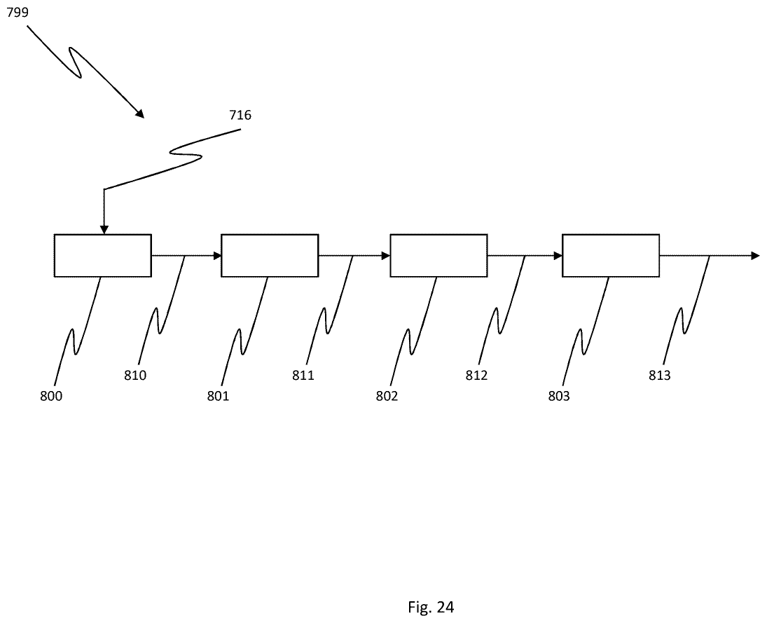

FIG. 24 shows an etching unit 799. The etching unit preferably comprises the following units:

An etching basin 800, water basins (water cascade) 801, a drying unit 802, a packaging unit 803. Reference number 810 indicates etched SiC and refence number 811 indicates acid-free SiC and reference number 812 indicates dried SiC and reference number 813 indicates packed SiC, in particular according to a specification.

Thus, the present invention relates to a method for producing a preferably elongated SiC solid, in particular of polytype 3C. The method according to the invention preferably comprises at least the following steps: Introducing at least a first source gas into a process chamber, said first source gas comprising Si, introducing at least one second source gas into the process chamber, the second source gas comprising C, electrically energizing at least one separator element disposed in the process chamber to heat the separator element, setting a deposition rate of more than 200 μm/h, wherein a pressure in the process chamber of more than 1 bar is generated by the introduction of the first source gas and/or the second source gas, and wherein the surface of the deposition element is heated to a temperature in the range between 1400° C. and 1700° C.

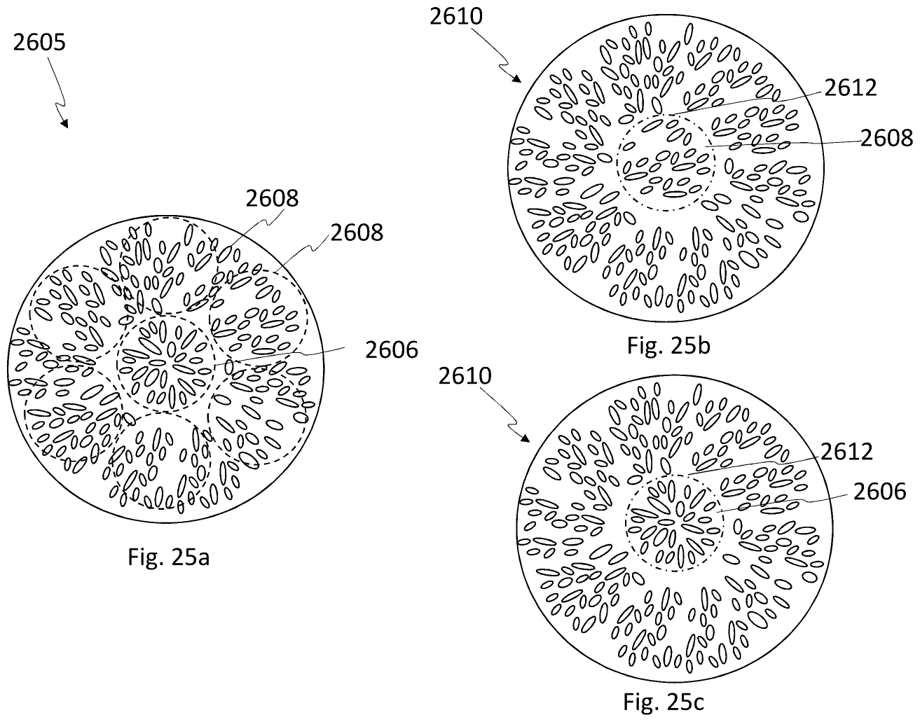

FIG. 25a schematically shows a cross-sectional view of a SiC solid 2605 for removing SiC growth substrates 2606, 2608. In the present example only one SiC growth substrate 2606 grown in a center of a SiC solid but multiple SiC growth substrates 2608 grown in a distance to a center of a SiC solid are present.

FIG. 25b schematically shows a cross-sectional view of a SiC solid grown around a SiC growth substrates 2608 grown in a distance to a center of a SiC solid.

FIG. 25c schematically shows a cross-sectional view of a SiC solid grown around a SiC growth substrate 2606 grown in a center of a SiC solid.

FIG. 26a schematically shows the orientation of crystallites 2414 in the inner section 2600 of SiC carrier wafer 2322.

More than 50% and preferably at least 60% and most preferably at least 70% of all crystallites 2414 of the inner section 2600 which are extending in length direction (cf. definition of “length direction” with respect to FIG. 14) of the individual crystallite 2414 more than 5 μm, in particular more than 10 μm and preferably more than 20 μm and particular preferably more than 50 μm and highly preferably up to 300 μm and most preferably up to 500 μm, are inclined to a median direction of extension 2604 of said crystallites 2414 of the inner section 2600 in an angle 2614, 2615, in particular of less than +/−22.5°.

FIG. 26b schematically shows the orientation of crystallites 2414 in the outer section 2602 of SiC carrier wafer 2322.

More than 25% and preferably at least 50% and/or most preferably up to 75% of all crystallites 2414 of the outer section 2602 which are extending in length direction (cf. definition of “length direction” with respect to FIG. 14) of the individual crystallite 2414 more than 5 μm, in particular more than 10 μm and preferably more than 20 μm and particular preferably more than 50 μm and highly preferably up to 300 μm and most preferably up to 500 μm, are inclined to the median direction of extension 2604 of the inner section 2600 in an angle of more than +/−22.5°.

The FIGS. 26a and 26b preferably show an example of one common embodiment, wherein only for explanation two figures are provided. The SiC carrier wafer 2322 according to FIG. 26a/b is beneficial since it comprises crystallites having a length of more than 5 μm, in particular more than 10 μm and preferably more than 20 μm and particular preferably more than 50 μm and highly preferably up to 300 μm and most preferably up to 500 μm, and therefore compensates tensions inside the SiC carrier wafer 2322 and therefore reduces bow and warp and also reduces cracks. The embodiment according to FIG. 26a/b is further beneficial since a SiC growth substrate 2608 is used which is grown in a distance to a center of a SiC solid. Since more than one SiC growth substrate 2608 is grown in a distance to a center of a SiC solid can be removed from the SiC the costs of such a SiC growth substrate 2608 is less compared to the costs of a SiC growth substrate 2606 grown in a center of a SiC solid.

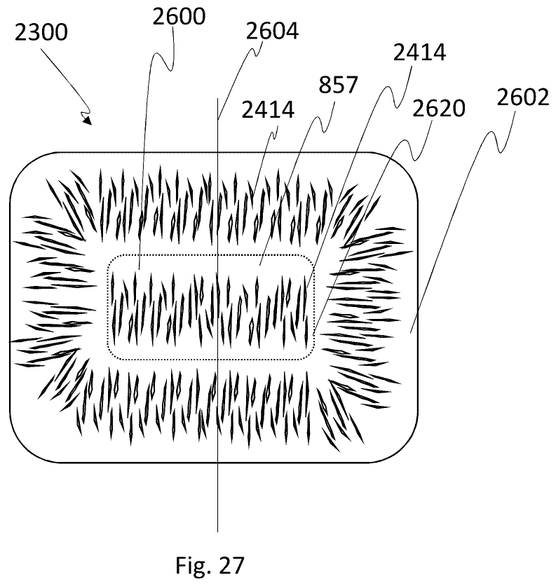

FIG. 27 shows a further example of a SiC solid grown according to the present invention and used to remove SiC growth substrates 857 and/or SiC carrier wafer 2322 therefrom. The dotted line indicates the surface of the SiC growth substrate 857 prior to the deposition of SiC. The surface of the SiC growth substrate 857 is preferably etched.

Etching of the surface of the SiC growth substrate 857 preferably takes place after the SiC growth substrate 857 is provided inside the CVD reactor 850, in particular any herein described CVD reactor 850, in particular any according to FIG. 1, 2, 3 or 4, and before the step of Growing a SiC solid 211 by depositing SiC on the deposition surface of the SiC growth substrate 857 in the CVD reactor 850. The step of etching after the SiC growth substrate 857 is provided inside the CVD reactor 850 is preferably carried out by gas etching, in particular hydrogen etching, and/or plasma etching, in particular hydrogen-plasma etching. The same can apply to FIG. 25a-26b.

FIG. 27 further shows that more than 25% and preferably at least 50% and/or most preferably up to 75% of all crystallites 2414 of the outer section 2602 which are extending in length direction (cf. definition of “length direction” with respect to FIG. 14) of the individual crystallite 2414 more than 5 μm, in particular more than 10 μm and preferably more than 20 μm and particular preferably more than 50 μm and highly preferably up to 300 μm and most preferably up to 500 μm, are inclined to the median direction of extension 2604 of the inner section 2600 in an angle of more than +/−22.5°.

Thus, the present invention preferably provides a beneficial SiC carrier wafer 2322, in particular crack-free SiC carrier wafer 2322. The SiC carrier wafer 2322 preferably has a diameter of at least 7.5 cm. The SiC carrier wafer 2322 has preferably a height between 200 μm and 500 μm. The SiC carrier wafer 2322 preferably comprises at least one or exactly one inner section 2600, in particular one central inner section 2600, and wherein the SiC carrier wafer 2322 preferably comprises an outer section 2602, wherein the outer section 2602 surrounds the inner section 2600, wherein the inner section 2600 consists of a part of a SiC growth substrate 857, wherein the inner section 2600 is predominantly formed by a 3C crystal structure, and wherein the outer section 2602 is predominantly formed by a 3C crystal structure and comprises crystallites 2414 extending in length direction of the individual crystallite 2414 more than 5 μm, in particular more than 10 μm and preferably more than 20 μm and particular preferably more than 50 μm and most preferably up to 500 μm or up to 300 μm, wherein a bow of the SiC carrier wafer 2322 is preferably below 50 μm, in particular below 20 μm, and/or wherein a warp of the SiC carrier wafer 2322 is preferably below 50 μm, in particular below 20 μm. The crystal structure of the inner section and the crystal structure of the outer section, in particular the 3C crystal structure of the inner section 2600 and the 3C crystal structure of the outer section 2602, are preferably doped, in particularly Nitrogen doped, in particular more than 2000 ppba nitrogen, and comprise an electric resistivity <0.03 Ohm cm, preferably <0.02 Ohm cm and most preferably <0.01 Ohm cm.

### LIST OF REFERENCE NUMBERS

18 seed wafer
100 furnace apparatus
102 furnace unit
104 furnace volume
106 crucible unit
107 filter lid or crucible lid
108 furnace housing
110 crucible housing
112 crucible housing outer surface
114 crucible housing inner surface
116 crucible volume
117 bottom surface of receiving space
118 receiving space
120 source material
122 seed holder unit
123 diameter of seed holder unit
124 heating unit
202 Upper housing
203 Cross member
206a first electrode
206b second electrode
208 Chuck
209 Temperature measurement path
211 SiC crust/SiC solid
213 Sight glass
240 furnace housing inner surface
242 furnace housing outer surface
278 source-material-holding-plate
280 gas-guide-gap
282 through holes
296 Vent gas
298 UPSIC rods
300 Comminution unit
370 upper surface of source-material-holding-plate
372 lower surface of source-material-holding-plate
398 UPSiC granules
400 Acid etching unit
496 Scrubber inlet water
497 Flare combustion gas
498 UPSiC etched granules
500 Vent gas treatment unit
502 Vent gas filter unit
504 Filtered vent gas
506 Scrubber unit
512 Scrubbed vent gas
514 Flare unit
596 Flare exhaust gas
598 Scrubber outlet water
600 Vent gas recycling unit
602 Cold distillation unit respectively separator unit
604 Si-bearing liquid mixture
606 HMW distillation unit
608 HMW liquids discharge
610 Cold distillation gas
612 Cryogenic distillation unit or further separator unit
616 H/C-bearing gas mixture
618 H/C detector unit respectively C mass flux measurement unit
620 Si-bearing gas mixture
622 Si detector unit respectively Si mass flux measurement unit
624 first storage and/or conducting element
626 second storage and/or conducting element
628 mixture of chlorosilanes storage and/or conducting element
630 HCl storage and/or conducting element
632 H2 and C storage and/or conducting element
634 first compressor
636 further compressor
696 HCl liquid discharge
698 Recycled vent gas
699 Comminution Unit
700 Precrusher
701 Crusher
702 Screening machine (undersize removal)
703 Screening machine (oversize removal)
704 Annealing furnace
710 precrushed SiC
711 crushed SiC (all particle sizes)
712 crushed SiC w/o undersized particles (1 . . . 30 mm)
713 undersized SiC (0 . . . 1 mm)
714 oversized SiC, return to crushing (>12 mm)
715 SiC product (1 . . . 12 mm)
716 annealed SiC (graphite free; 1 . . . 12 mm)
799 etching unit
800 etching basin
801 water basins (water cascade)
802 drying unit
803 packaging unit
810 etched SiC
811 acid-free SiC
812 dried SiC
813 packed SiC according to specification
850 manufacturing device or CVD unit or CVD reactor respectively SiC production reactor, in particular SiC PVT source material production reactor
851 first feeding device respectively first feed-medium source
852 second feeding device respectively second feed-medium source
853 third feeding device respectively third feed-medium source respectively
carrier gas feed-medium source
854 mixing device
855 evaporator device
856 process chamber
857 SiC growth substrate
858 temperature measuring device or temperature control unit
859 Energy source, especially power supply
859a first power connection
859b second power connection
860 Pressure maintaining device or pressure control unit
861 outer surface of SiC growth substrate or SiC growth surface
862 base plate
864 bell jar
864a side wall section
864b top wall section
865 metal surface
866 gas inlet unit
867 reflective coating
868 cooling element
870 active cooling element
873 fluid forwarding unit
892 cooling fluid temperature sensor
966 reaction space
972 arrow
999 System
1000 feed gas unit
1040 industrial C-bearing gas
1070 N gas discharge
1080 Si-bearing liquid evaporator
1090 C-bearing liquid evaporator
1120 Mass flow meter
1130 C-bearing liquid
1160 Feed gas mixture
1180 C/Si-bearing liquid
1200 C/Si-bearing gas
2040 Lower housing
2120 Vent gas
2140 Feed gas inlet
2200 main body
2299 CVD SiC with physical structure
2300 SiC piece/crack-free SiC piece
2301 SiC piece possibly with cracks
2302 first plane
2304 second plane
2305 crack
2306 first direction
2308 second direction
2314 crack-free sub piece/predefined piece/wafer
2316 surface of wafer/processed surface
2317 first substrate/monocrystalline SiC crystal
2318 monocrystalline SiC wafer/thin substrate
2319 epi-layer
2320 multi-substrate wafer/composite substrate
2322 second substrate/carrier wafer/polycrystalline SiC structure
2324 grain orientation
2326 corners of quarter
2328 rough sawing
2330 wafer slicing
2332 wafer lapping
2334 removing thin layer of mono SiC
2336 wafer polishing
2338 wafer bonding
2400 top surface of first substrate
2402 bottom surface of first substrate
2404 connecting-surface of first substrate
2406 top surface of second substrate
2408 bottom surface of second substrate
2410 connecting-surface of second substrate
2412 band shaped or line shaped or straight element
2414 large crystallite
2415 small crystallite
2416 cutting plane
2418 layer of implanted ions
2420 section
2500 state of the art carrier wafer
2502 growth substrate for epitaxial growth of a state-of-the-art carrier wafer
2504 growth direction of a state-of-the-art carrier wafer
2506 large crystallite of a state-of-the-art carrier wafer
2508 first main surface
2510 second main surface
2600 inner section
2602 outer section
2604 median direction of extension (within the image plane)
2605 SiC solid for removing SiC growth substrates
2606 SiC growth substrate grown in a center of a SiC solid
2608 SiC growth substrate grown in a distance to a center of a SiC solid
2610 SiC solid preferably for the production of SiC carrier wafer
2612 surface of SiC growth substrate 2606
2614 angle preferably of less than +22.5° to a median direction of extension of crystallites of an inner section
2615 angle preferably of less than −22.5° to a median direction of extension of crystallites of an inner section
2616 angle preferably of more than +22.5° to a median direction of extension of crystallites of an inner section
2618 angle preferably of more than −22.5° to a median direction of extension of crystallites of an inner section
2620 Interface between inner section and outer section
H height direction
L length direction of a crystallite
R radial direction of the polycrystalline structure

1. A SiC carrier wafer,
wherein the SiC carrier wafer has a diameter of at least 7.5 cm
wherein the SiC carrier wafer has a height between 200 μm and 500 μm,
wherein the SiC carrier wafer comprises at least one one inner section,
and
wherein the SiC carrier wafer comprises an outer section, wherein the outer section surrounds the inner section,
wherein the inner section consists of a part of a SiC growth substrate,
wherein the inner section is formed by a crystal structure, wherein the crystal structure of the inner section is predominantly formed by a 3C crystal structure, and
wherein the outer section is formed by a crystal structure, wherein the crystal structure of the outer section is predominantly formed by a 3C crystal structure and comprises crystallites extending in length direction of the individual crystallite more than 5 μm,
wherein a bow of the SiC carrier wafer is below 50 μm, and/or wherein a warp of the SiC carrier wafer is below 50 μm,
wherein the crystal structure of the inner section and the crystal structure of the outer section are Nitrogen doped, and comprises an electric resistivity <0.03 Ohm cm.

2. The SiC carrier wafer according to claim 1,
characterized in that
more than 5 crystallites which are extending in length direction of the individual crystallite more than 5 μm are present per 1 mm³ of the outer section.

3. The SiC carrier wafer according to claim 2,
characterized in that
the inner section comprises crystallites extending in length direction of the individual crystallite more than 5 μm.

4. The SiC carrier wafer according to claim 3,
characterized in that
more than 5 crystallites are extending in length direction of the individual crystallite more than 5 μm are present per 1 mm³ of the inner section.

5. The SiC carrier wafer according to claim 4,
characterized in that
more than 50% of all crystallites of the inner section which are extending in length direction of the individual crystallite more than 5 μm are inclined to a median direction of extension of said crystallites of the inner section in an angle of less than +/−22.5°.

6. The SiC carrier wafer according to any of claim 1,
characterized in that
more than 25% of all crystallites of the outer section which are extending in length direction of the individual crystallite more than 5 μm are inclined to the median direction of extension of the inner section in an angle of more than +/−22.5°.

7. The SiC carrier wafer according to any of claim 1,
characterized in that
an interface between the outer section and the inner section comprises the same chemical composition compared to the chemical composition of a part inside the outer section between the interface between the outer section and the inner section and a surrounding surface of the outer section and/or the same chemical composition of a part inside the inner section between the interface between the outer section and the inner section and a center of the inner section.

8. The SiC carrier wafer according to claim 7,
characterized in that
the inner section has a cross-sectional area orthogonal to the circumferential direction of at least 0.5 cm².

9. The SiC carrier wafer according to claim 8,
characterized in that
the cross-sectional area of the SiC growth substrate has a circular or rectangular shape
or
the cross-sectional area of the SiC growth substrate has a band-like shape,
wherein the SiC growth substrate preferably has two large surface section connected via small surface sections, wherein the surface size of the large surface sections is larger compared to the surface size of the small surface section.

10. The SiC carrier wafer according to any of the claim 1,
characterized in that
the SiC carrier wafer comprises a processed surface, wherein the processed surface
is generated by mechanically dividing a crack-free SiC piece having a thickness of at least 1 cm.

11. The SiC carrier wafer according to claim 10,
characterized in that
the processed surface is a mechanically structured surface, wherein the mechanically structured surface is grinded and/or lapped and/or polished, to reduce surface roughness R_{A} below 5 nm.

12. A composite substrate
at least comprising a SiC carrier wafer according to f claim 10 and a monocrystalline SiC wafer,
wherein the monocrystalline SiC wafer is bonded to the processed surface of the SiC carrier wafer.

13. A method for producing at least one SiC carrier wafer comprising the steps:
Providing a CVD reactor,
Providing at least one SiC growth substrate inside the CVD reactor,
wherein the SiC growth substrate forms
a deposition surface surrounding the SiC growth substrate in circumferential direction of the SiC growth substrate
Growing a SiC solid
to a diameter of at least 7.5 cm
or
to a cross-sectional area size orthogonal to the length direction of the SiC growth substrate of at least 44.17 cm²
by depositing SiC on the deposition surface in the CVD reactor, Mechanically removing, by means of sawing, the at least one SiC piece from the SiC solid, and
Mechanically removing the at least one SiC carrier wafer from the SiC piece, by means of sawing.

14. The method according to claim 13,
characterized in that
the step of growing a SiC solid comprises setting up a deposition rate of more than 200 μm/h.

15. The method according to claim 14,
characterized by the step of
Analyzing the SiC solid to determine a crack-free section of the SiC solid, wherein the step of analyzing the SiC solid is carried out prior to the step of mechanically removing, by means of sawing, the at least one SiC piece from the SiC solid.

16. The method according to claim 15,
characterized in that
the at least one SiC piece is removed from the crack-free section of the SiC solid or wherein the crack-free section of the SiC solid is removed as the at least one SiC piece.

17. The method according to claim 16,
characterized in that
the step of analyzing the SiC solid to determine a crack-free section of the SiC solid is carried out by optical inspection, by means of a caliper or threshold detection.

18. The method according to claim 17,
characterized by the step of
Analyzing the SiC piece or the SiC carrier wafer to determine defects cracks.

19. The method according to claim 18,
characterized in that
the step of analyzing the SiC piece or the SiC carrier wafer to determine defects is carried out by means of a bend test, an eddy current testing, and/or optical analyzing methods, in caliper testing, threshold testing, or transmission testing.

20. The method according to claim 13,
characterized by a
Step of heating the SiC growth substrate by conducting electric current from a first power connection to a second power connection or from the second power connection to the first power connection through the SiC growth substrate.

21. The method according to claim 20,
characterized in that,
the SiC growth substrate is heated to a temperature of more than 1400° C.,

22. The method according to claim 21,
characterized in that,
the growth face of the deposited SiC is heated to a temperature of less than 1700° C. and a center of the SiC growth substrate is heated to a temperature above 1400° C.

23. The method according to claim 20,
characterized in that,
the electric current is alternating current.

24. The method according to claim 23,
characterized in that
the frequency of the alternating current is above 5 Hz.

25. The method according to claim 13,
characterized in that
the deposited SiC has a minimal thickness of at least 1 cm and
wherein the at least one SiC piece is formed between a first plane and a second plane, and
wherein the first plane is perpendicular to the main body length and wherein the second plane is perpendicular to the main body length,
wherein the distance between the first plane and the second plane is at least 1% of the main body length, and
wherein the deposited SiC is polycrystalline SiC,
wherein the deposited SiC forms volume sections with different crystal structures,
wherein a 3C crystal structure is predominantly formed, wherein the volume and/or mass of SiC formed in the 3C crystal structure comprises more than 50% of the deposited SiC,
wherein the SiC carrier wafer is crack-free.

26. The method according to claim 25,
characterized in that
the at least one SiC piece has a cross-sectional size of at least 4 cm² and a thickness of at least 0.1 cm,
and/or
wherein the volume of the at least one SiC piece is more than 2 cm³, wherein the at least one SiC piece is crack-free.

27. The method according to claim 13,
wherein the SiC growth substrate comprises
a main body,
a first power connection and
a second power connection,
wherein the main body has a main body length, wherein the main body length extends between the first power connection and the second power connection,
wherein the first power connection is configured to conduct power into the main body for heating the main body and wherein the second power connection is configured to conduct electric power conducted via the first power connection into the main body out of the main body.

28. The method according to claim 13, characterized by the step of
Etching the surface of the SiC growth substrate before the SiC growth substrate is provided inside the CVD reactor, wherein the step of etching is carried out by hydrofluoric acid etching
and/or
Etching the surface of the SiC growth substrate after the SiC growth substrate is provided inside the CVD reactor and before the step of Growing a SiC solid by depositing SiC on the deposition surface of the SiC growth substrate in the CVD reactor.

29. The method according to claim 28,
characterized in that
the step of etching after the SiC growth substrate is provided inside the CVD reactor is carried out by gas etching, hydrogen etching, and/or plasma etching.

30. The method according to claim 13, characterized in that
the step of growing the SiC solid comprises the materialization of crystallites having a length of more than 5 μm.

31-106. (canceled)
